(19) United States
(12) Patent Application Publication
(10) Pub. No.: US 2016/0118605 A1
(43) Pub. Date: Apr. 28, 2016

(54) Light-Emitting Element, Light-Emitting Device, Electronic Device, and Lighting Device

(71) Applicant: Semiconductor Energy Laboratory Co., Ltd., Kanagawa-ken (JP)

(72) Inventors: Sachiko KAWAKAMI, Atsugi (JP); Rina NAKAMURA, Atsugi (JP); Nozomi KOMATSU, Atsugi (JP); Naoaki HASHIMOTO, Atsugi (JP); Toshiki HAMADA, Isehara (JP); Tsunenori SUZUKI, Yokohama (JP); Satoshi SEO, Sagamihara (JP)

(73) Assignee: Semiconductor Energy Laboratory Co., ltd., Kanagawa-ken (JP)

(21) Appl. No.: 14/924,027

(22) Filed: Oct. 27, 2015

(30) Foreign Application Priority Data
Oct. 28, 2014 (JP) 2014-218936

(51) Int. Cl. H01L 51/00; C07F 15/00; C09K 11/06; H01L 51/50

(52) U.S. Cl. CPC H01L 51/0085; H01L 51/5012; C07F 15/0033; C09K 11/06; C09K 2211/1007; C09K 2211/1044; C09K 2211/185

(57) ABSTRACT

A long-life light-emitting element is provided by reducing a specific kind of impurity in the light-emitting element, particularly an impurity originating in an iridium complex. The light-emitting element includes an iridium complex. The iridium complex includes an iridium metal and a ligand coordinated to the iridium metal. In analysis of the light-emitting element by liquid chromatography mass spectrometry using a chromatograph of a photodiode array detector, the proportion of the peak area of a ligand not coordinated to the iridium metal to the peak area of the iridium complex is greater than or equal to 0% and less than or equal to 10%.

### BACKGROUND OF THE INVENTION

1. Field of the Invention

One embodiment of the present invention relates to a light-emitting element in which a light-emitting layer capable of emitting light by application of an electric field is provided between a pair of electrodes. Specifically, one embodiment of the present invention relates to a light-emitting element in which a light-emitting layer includes an iridium complex. One embodiment of the present invention relates to a light-emitting device, a display device, an electronic device, and a lighting device each including the above light-emitting element.

Note that one embodiment of the present invention is not limited to the above technical field. The technical field of one embodiment of the invention disclosed in this specification and the like relates to an object, a method, or a manufacturing method. Alternatively, the technical field of one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a memory device, a method for driving any of them, and a method for manufacturing any of them.

2. Description of the Related Art

A light-emitting element having a structure in which an organic compound that is a light-emitting substance is provided between a pair of electrodes (also referred to as an organic EL element) has attracted attention as a next-generation flat panel display in terms of characteristics such as being thin and light in weight, high-speed response, and low voltage driving. In addition, a display using such an organic EL element is superior in contrast, image quality, and wide viewing angle.

Various organic compounds to be used for an organic EL element have been researched and developed. For example, as an organic compound that is a light-emitting substance, an organometallic complex having iridium (Ir) or the like as a central metal has attracted attention.

In manufacture of an organic EL element, the purity of an organic compound is an important factor. For example, in the case where an organic EL element is fabricated with the use of an organic compound containing an impurity such as a solvent used in synthesis, the characteristics of the organic EL element (e.g., drive voltage characteristics, emission efficiency characteristics, or a lifetime) might be poor. Accordingly, a material with a reduced amount of impurity, which is subjected to purification by sublimation, is generally used as an organic compound for an organic EL element. The purification by sublimation can remove a solvent remaining after synthesis or a small amount of impurity such as a halide (see, for example, Patent Document 1).

However, even when an organic EL element is fabricated with the use of the organic compound subjected to the purification by sublimation, the reliability of the organic EL element might be low.

### REFERENCE

### Patent Document

[Patent Document 1] Japanese Published Patent Application No. 2011-216903

### SUMMARY OF THE INVENTION

In one embodiment of the present invention, a long-life light-emitting element is provided by reducing a specific kind of impurity, particularly an impurity originating in an iridium complex, in the light-emitting element. In one embodiment of the present invention, a novel light-emitting element is provided.

Note that the descriptions of these objects do not disturb the existence of other objects. In one embodiment of the present invention, there is no need to achieve all the objects. Other objects will be apparent from and can be derived from the description of the specification, the drawings, the claims, and the like.

One embodiment of the present invention is a light-emitting element including an iridium complex. The iridium complex includes an iridium metal and a ligand coordinated to the iridium metal. In analysis of the light-emitting element by liquid chromatography mass spectrometry using a chromatograph of a photodiode array detector, the proportion of the peak area of a ligand not coordinated to the iridium metal to the peak area of the iridium complex is greater than or equal to 0% and less than or equal to 10%.

Another embodiment of the present invention is a light-emitting element including an iridium complex. The iridium complex includes an iridium metal and a ligand coordinated to the iridium metal. In analysis of the light-emitting element by liquid chromatography mass spectrometry, a precursor ion of the iridium complex, a first fragment ion of the iridium complex, and a second fragment ion of the iridium complex are detected by a mass spectrometric detector and a photodiode array detector. The first fragment ion detected by the mass spectrometric detector includes the iridium metal. The second fragment ion detected by the mass spectrometric detector does not include the iridium metal. A chromatograph of the photodiode array detector includes a first peak corresponding to the precursor ion, a second peak corresponding to the first fragment ion, and a third peak corresponding to the second fragment ion. The proportion of the area of the third peak to the area of the first peak is greater than or equal to 0% and less than or equal to 10%.

Another embodiment of the present invention is a light-emitting element including an iridium complex. The iridium complex includes an iridium metal and a ligand coordinated to the iridium metal. In analysis of the light-emitting element by liquid chromatography mass spectrometry using a chromatograph of a photodiode array detector, the proportion of the peak area of a ligand not coordinated to the iridium metal to the peak area of the iridium complex is greater than or equal to 0% and less than or equal to 5%.

Another embodiment of the present invention is a light-emitting element including an iridium complex. The iridium complex includes an iridium metal and a ligand coordinated to the iridium metal. In analysis of the light-emitting element by liquid chromatography mass spectrometry, a precursor ion of the iridium complex, a first fragment ion of the iridium complex, and a second fragment ion of the iridium complex are detected by a mass spectrometric detector and a photodiode array detector. The first fragment ion detected by the mass spectrometric detector includes the iridium metal. The second fragment ion detected by the mass spectrometric detector does not include the iridium metal. A chromatograph of the photodiode array detector includes a first peak corresponding to the precursor ion, a second peak corresponding to the first fragment ion, and a third peak corresponding to the second fragment ion. The proportion of the area of the third peak to the area of the first peak is greater than or equal to 0% and less than or equal to 5%.

Another embodiment of the present invention is a light-emitting element including an iridium complex. The iridium complex includes an iridium metal and a ligand coordinated to the iridium metal. In analysis of the light-emitting element by liquid chromatography mass spectrometry using a chromatograph of a photodiode array detector, the proportion of the peak area of a ligand not coordinated to the iridium metal to the peak area of the iridium complex is greater than or equal to 0% and less than or equal to 1%.

Another embodiment of the present invention is a light-emitting element including an iridium complex. The iridium complex includes an iridium metal and a ligand coordinated to the iridium metal. In analysis of the light-emitting element by liquid chromatography mass spectrometry, a precursor ion of the iridium complex, a first fragment ion of the iridium complex, and a second fragment ion of the iridium complex are detected by a mass spectrometric detector and a photodiode array detector. The first fragment ion detected by the mass spectrometric detector includes the iridium metal. The second fragment ion detected by the mass spectrometric detector does not include the iridium metal. A chromatograph of the photodiode array detector includes a first peak corresponding to the precursor ion, a second peak corresponding to the first fragment ion, and a third peak corresponding to the second fragment ion. The proportion of the area of the third peak to the area of the first peak is greater than or equal to 0% and less than or equal to 1%.

Another embodiment of the present invention is a light-emitting device that includes the above-described light-emitting element and a color filter. Another embodiment of the present invention is an electronic device that includes the above-described light-emitting element or the above light-emitting device and a housing or a touch sensor function. Another embodiment of the present invention is a lighting device that includes the above-described light-emitting element or the above light-emitting device and a housing.

One embodiment of the present invention makes it possible to provide a long-life light-emitting element by reducing a specific kind of impurity, particularly an impurity originating in an iridium complex, in the light-emitting element. One embodiment of the present invention makes it possible to provide a novel light-emitting element.

Note that one embodiment of the present invention is not limited to these effects. For example, depending on circumstances or conditions, one embodiment of the present invention might produce an effect other than these effects. Furthermore, depending on circumstances or conditions, one embodiment of the present invention might not produce any of the above effects.

### BRIEF DESCRIPTION OF THE DRAWINGS

FIG. 1 is a schematic cross-sectional view illustrating a light-emitting element.

FIG. 2 shows results of reliability tests of Samples 1 and 2.

FIG. 3 shows LC/MS chromatograms of Samples 1 and 2.

FIG. 4 shows LC/MS chromatograms of Samples 1 and 2.

FIG. 5 is a schematic cross-sectional view illustrating a light-emitting element.

FIGS. 6A and 6B are a block diagram and a circuit diagram illustrating a display device.

FIGS. 7A and 7B are each a circuit diagram illustrating a pixel circuit of a display device.

FIGS. 8A and 8B are each a circuit diagram illustrating a pixel circuit of a display device.

FIGS. 9A and 9B are perspective views illustrating an example of a touch panel.

FIGS. 10A to 10C are cross-sectional views illustrating examples of a display panel and a touch sensor.

FIGS. 11A and 11B are cross-sectional views illustrating an example of a touch panel.

FIGS. 12A and 12B are a block diagram and a timing chart of a touch sensor.

FIG. 13 is a circuit diagram of a touch sensor.

FIG. 14 is a perspective view illustrating a display module.

FIGS. 15A to 15G illustrate electronic devices.

FIGS. 16A to 16C are a perspective view and cross-sectional views illustrating a light-emitting device.

FIGS. 17A to 17D are cross-sectional views illustrating light-emitting devices.

FIGS. 18A to 18C illustrate a lighting device and an electronic device.

FIG. 19 is a cross-sectional view illustrating a structure of a light-emitting element in Example.

FIGS. 20A and 20B show current density-luminance characteristics and voltage-luminance characteristics of light-emitting elements in Example.

FIGS. 21A and 21B show luminance-current efficiency characteristics and emission spectra of light-emitting elements in Example.

FIG. 22 shows results of reliability tests of light-emitting elements in Example.

FIG. 23 shows LC/MS chromatograms of light-emitting elements in Example.

FIG. 24 shows LC/MS chromatograms of light-emitting elements in Example.

FIGS. 25A and 25B show current density-luminance characteristics and voltage-luminance characteristics of light-emitting elements in Example.

FIGS. 26A and 26B show luminance-current efficiency characteristics and emission spectra of light-emitting elements in Example.

FIG. 27 shows results of reliability tests of light-emitting elements in Example.

FIG. 28 shows LC/MS chromatograms of light-emitting elements in Example.

FIG. 29 shows LC/MS chromatograms of light-emitting elements in Example.

FIGS. 30A and 30B show current density-luminance characteristics and voltage-luminance characteristics of light-emitting elements in Example.

FIGS. 31A and 31B show luminance-current efficiency characteristics and emission spectra of light-emitting elements in Example.

FIG. 32 shows results of reliability tests of light-emitting elements in Example.

FIG. 33 shows LC/MS chromatograms of light-emitting elements in Example.

FIG. 34 shows LC/MS chromatograms of light-emitting elements in Example.

### DETAILED DESCRIPTION OF THE INVENTION

Embodiments of the present invention will be explained below with reference to the drawings. Note that one embodiment of the present invention is not limited to the description given below, and various changes and modifications can be made without departing from the spirit and scope of the present invention. Therefore, one embodiment of the present invention should not be construed as being limited to the description in Embodiments or Examples.

Note that the position, the size, the range, or the like of each structure illustrated in drawings and the like is not accurately represented in some cases for simplification. Therefore, one embodiment of the disclosed invention is not necessarily limited to the position, the size, the range, or the like disclosed in the drawings and the like.

Ordinal numbers such as “first” and “second” in this specification and the like are used for convenience and do not denote the order of steps or the stacking order of layers. Therefore, for example, description can be made even when “first” is replaced with “second” or “third”, as appropriate. In addition, the ordinal numbers in this specification and the like are not necessarily the same as those which specify one embodiment of the present invention.

In describing structures of the invention with reference to the drawings in this specification and the like, common reference numerals are used for the same portions in different drawings.

In this specification and the like, the terms “film” and “layer” can be interchanged with each other depending on the case or circumstances. For example, in some cases, the term “conductive film” can be used instead of the term “conductive layer,” and the term “insulating layer” can be used instead of the term “insulating film”.

An iridium complex in this specification and the like might have a structural isomer such as a stereoisomer depending on the kind of its ligand. In the category of the iridium complex described in this specification and the like, the iridium complex and its structural isomer are included.

### Embodiment 1

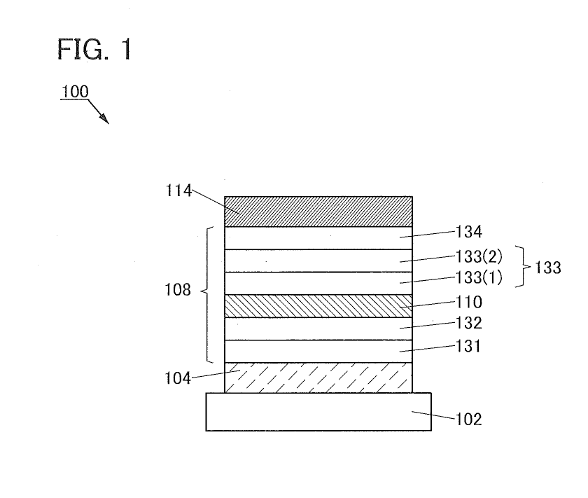

In this embodiment, a light-emitting element of one embodiment of the present invention will be described below with reference to FIGS. 1 to 4.

### <1. Structure of Light-Emitting Element>

FIG. 1 is a cross-sectional view illustrating a light-emitting element of one embodiment of the present invention. The light-emitting element illustrated in FIG. 1 includes an EL layer between a pair of electrodes, and the EL layer contains an iridium complex.

Specifically, a light-emitting element 100 in FIG. 1 includes an EL layer 108 between a pair of electrodes (a lower electrode 104 and an upper electrode 114). The EL layer 108 includes a light-emitting layer 110. The EL layer 108 includes, in addition to the light-emitting layer 110, a hole-injection layer 131, a hole-transport layer 132, an electron-transport layer 133, and an electron-injection layer 134. The electron-transport layer 133 includes an electron-transport layer 133(1) and an electron-transport layer 133(2).

In this embodiment, the lower electrode 104 is used as an anode and the upper electrode 114 is used as a cathode. The lower electrode 104 is formed over a substrate 102. The light-emitting layer 110 contains an iridium complex as a light-emitting substance.

By application of a voltage to the light-emitting element 100, holes injected from the lower electrode 104 side and electrons injected from the upper electrode 114 side recombine in the light-emitting layer 110 to raise the light-emitting substance contained in the light-emitting layer 110 to an excited state. The light-emitting substance in the excited state emits light when the excited light-emitting substance relaxes to the ground state.

It is desirable that the light-emitting element 100 hardly suffer a reduction in emission efficiency due to long preservation or long driving. In other words, it is desirable that the light-emitting element 100 have a long lifetime, or high reliability. To achieve high reliability of the light-emitting element 100, the EL layer 108 is preferably formed using an organic compound containing few impurities. For example, it is preferable that the content of an impurity such as an element contained in a raw material used in synthesis of the organic compound (e.g., a halogen element) be low.

However, the light-emitting element 100 has sometimes low reliability even when including the organic compound in which a halogen element is reduced.

In view of the above, in the light-emitting element 100 of one embodiment of the present invention, an impurity originating in the iridium complex included in the light-emitting layer 110 of the EL layer 108 is reduced. The iridium complex in the light-emitting layer 110 has an iridium metal and a ligand coordinated to the iridium metal. When the light-emitting element 100 is analyzed by liquid chromatography mass spectrometry (LC/MS) using a chromatograph of a photodiode array (PDA) detector, the proportion of the peak area of a ligand not coordinated to the iridium metal to the peak area of the iridium complex is 10% or less, preferably 5% or less, further preferably 1% or less. It is preferable that the ligand not coordinated to the iridium metal not be contained in the light-emitting element 100. In other words, the minimum proportion of the peak area of the ligand not coordinated to the iridium metal to the peak area of the iridium complex is 0%.

The iridium complex contained in the light-emitting layer 110 includes an iridium metal and a ligand coordinated to the iridium metal. In analysis of the light-emitting element 100 by liquid chromatography mass spectrometry, a precursor ion of the iridium complex, a first fragment ion of the iridium complex, and a second fragment ion of the iridium complex are detected by a mass spectrometric (MS) detector and a photodiode array detector. The first fragment ion detected by the MS detector includes the iridium metal. The second fragment ion detected by the MS detector does not include the iridium metal. A chromatograph of the photodiode array detector includes a first peak corresponding to the precursor ion, a second peak corresponding to the first fragment ion, and a third peak corresponding to the second fragment ion. The proportion of the area of the third peak to the area of the first peak is less than or equal to 10%, preferably less than or equal to 5%, further preferably less than or equal to 1%.

The use of the above iridium complex as the iridium complex of the light-emitting layer 110 leads to improved reliability of the light-emitting element 100.

Light-emitting elements (Samples 1 and 2) each corresponding to the light-emitting element 100 illustrated in FIG. 1 were fabricated, and the EL layer 108 and an impurity therein were analyzed. This embodiment focused on, as the impurity in the EL layer 108, an impurity originating in the iridium complex that was the light-emitting substance in the light-emitting layer 110.

Specific element structures of Samples 1 and 2 fabricated in this embodiment are shown in Table 1, and structures and abbreviations of the compounds used are shown below.

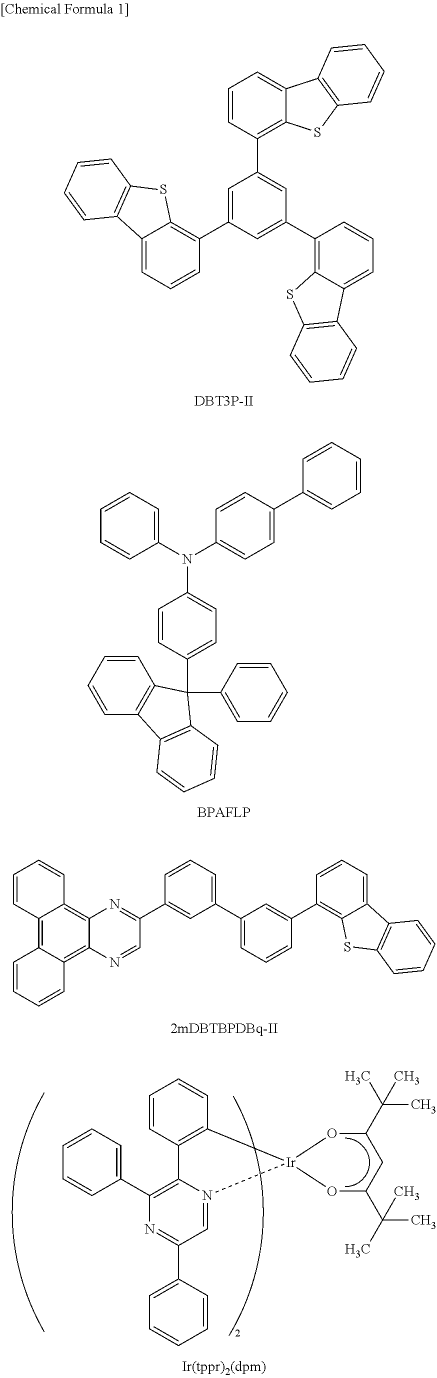

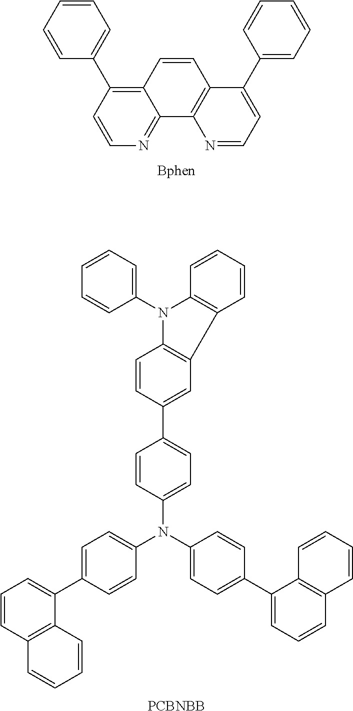

TABLE 1

| | | Reference | Thickness | | |
|---|---|---|---|---|---|
| | Layer | numeral | (nm) | Material | Weight ratio |
| Sample 1 | Upper | 114 | 200 | Al | — |
| | electrode | | | | |
| | Electron- | 134 | 1 | LiF | — |
| | injection layer | | | | |
| | Electron- | 133(2) | 15 | Bphen | — |
| | transport layer | 133(1) | 20 | 2mDBTBPDBq-II | — |
| | Light-emitting | 110 | 40 | 2mDBTBPDBq-II:PCBNBB:Ir(tppr)₂(dpm)*¹ | 0.8:0.2:0.06 |
| | layer | | | | |
| | Hole-transport | 132 | 20 | BPAFLP | — |
| | layer | | | | |
| | Hole-injection | 131 | 20 | DBT3P-II:MoOₓ | 2:1 |
| | layer | | | | |
| | Lower | 104 | 100 | ITSO | — |
| | electrode | | | | |
| Sample 2 | Upper | 114 | 200 | Al | — |
| | electrode | | | | |
| | Electron- | 134 | 1 | LiF | — |
| | injection layer | | | | |
| | Electron- | 133(2) | 15 | Bphen | — |
| | transport layer | 133(1) | 20 | 2mDBTBPDBq-II | — |
| | Light-emitting | 110 | 40 | 2mDBTBPDBq-II:PCBNBB:Ir(tppr)₂(dpm)*¹ | 0.8:0.2:0.06 |
| | layer | | | | |
| | Hole transport | 132 | 20 | BPAFLP | — |
| | layer | | | | |
| | Hole-injection | 131 | 20 | DBT3P-II:MoOₓ | 2:1 |
| | layer | | | | |
| | Lower | 104 | 100 | ITSO | — |
| | electrode | | | | |

*¹Deposited by evaporation using Material X1

### <2. Method for Fabricating Samples 1 and 2>

First, over the substrate 102, indium tin oxide containing silicon oxide (abbreviation: ITSO) was deposited as the lower electrode 104 by a sputtering method. Note that the thickness of the lower electrode 104 was 100 nm and the area of the lower electrode 104 was 4 mm² (2 mm×2 mm).

Then, for pretreatment before deposition of an organic compound layer by evaporation, the lower electrode 104 side of the substrate 102 provided with the lower electrode 104 was washed with water, baking was performed at 200° C. for 1 hour, and then UV ozone treatment was performed on a surface of the lower electrode 104 for 370 seconds.

After that, the substrate 102 was transferred into a vacuum evaporation apparatus where the pressure had been reduced to approximately 10⁻⁴ Pa, and was subjected to vacuum baking at 170° C. for 60 minutes in a heating chamber of the vacuum evaporation apparatus, and then the substrate 102 was cooled down for approximately 30 minutes.

Next, the substrate 102 was fixed to a holder provided in the vacuum evaporation apparatus so that a surface of the substrate over which the lower electrode 104 was formed faced downward. In this embodiment, by a vacuum evaporation method, the hole-injection layer 131, the hole-transport layer 132, the light-emitting layer 110, the electron-transport layer 133(1), the electron-transport layer 133(2), the electron-injection layer 134, and the upper electrode 114 were sequentially formed. The fabrication method will be described in detail below.

First, after reducing the pressure of the vacuum evaporation apparatus to 10⁻⁴ Pa, 4,4′,4″-(benzene-1,3,5-triyl)tri(dibenzothiophene) (abbreviation: DBT3P-II) and molybdenum oxide were deposited by co-evaporation in a weight ratio of 2:1 (=DBT3P-II: molybdenum oxide), whereby the hole-injection layer 131 was formed over the lower electrode 104. Note that the thickness of the hole-injection layer 131 was 20 nm.

Then, the hole-transport layer 132 was formed over the hole-injection layer 131. As the hole-transport layer 132, 4-phenyl-4′-(9-phenylfluoren-9-yl)triphenylamine (abbreviation: BPAFLP) was deposited by evaporation. Note that the thickness of the hole-transport layer 132 was 20 nm.

Next, the light-emitting layer 110 was formed over the hole-transport layer 132. As the light-emitting layer 110, 2-[3′-(dibenzothiophen-4-yl)biphenyl-3-yl]dibenzo[f,h]quinoxaline (abbreviation: 2mDBTBPDBq-II), 4,4′-di(1-naphthyl)-4″-(9-phenyl-9H-carbazol-3-yl)triphenylamine (abbreviation: PCBNBB), and bis(2,3,5-triphenylpyrazinato)(dipivaloylmethanato)iridium(III) (abbreviation: Ir(tppr)₂(dpm)) were deposited by co-evaporation in a weight ratio of 0.7:0.3:0.05 (=2mDBTBPDBq-II: PCBNBB: Ir(tppr)₂(dpm)). Note that the thickness of the light-emitting layer 110 was 40 nm.

In the light-emitting layer 110, 2mDBTBPDBq-II is a host material, PCBNBB is an assist material, and Ir(tppr)₂(dpm) is an iridium complex serving as a guest material. Note that the host material is a carrier-transport material, and an electron-transport material was used as the host material. The assist material is a carrier-transport material, and a hole-transport material was used as the assist material. The guest material was a light-emitting material (a material containing a light-emitting substance). Note that it is preferable that the level of triplet excitation energy (T₁ level) of each of the host material and the assist material be higher than the T₁ level of the guest material. When the T₁ level of each of the host material and the assist material is lower than that of the guest material, the triplet excitation energy of the guest material, which is to contribute to light emission, is quenched by the host material and the assist material and accordingly the emission efficiency is reduced in some cases. Carrier balance can be controlled by changing a mixing ratio of the host material and the assist material.

After that, over the light-emitting layer 110, 2mDBTBPDBq-II was deposited by evaporation to a thickness of 20 nm as the electron-transport layer 133(1). Then, over the electron-transport layer 133(1), bathophenanthroline (abbreviation: Bphen) was deposited by evaporation to a thickness of 15 nm as the electron-transport layer 133(2). Then, over the electron-transport layer 133(2), lithium fluoride (LiF) was deposited by evaporation to a thickness of 1 nm as the electron-injection layer 134.

Then, over the electron-injection layer 134, aluminum (Al) was deposited by evaporation to a thickness of 200 nm as the upper electrode 114.

Next, a sealing substrate (not shown) was prepared, and each of the light-emitting elements over the substrate 102 fabricated as described above was sealed by being bonded to the sealing substrate in a glove box in a nitrogen atmosphere so as not to be exposed to the air (specifically, a sealant was applied to surround the element and irradiated with ultraviolet light having a wavelength of 365 nm at 6 J/cm², and then, heat treatment was performed at 80° C. for 1 hour).

Note that in all the above evaporation steps for Samples 1 and 2, a resistive heating method was used as an evaporation method.

Through the above-described process, Sample 1 and Sample 2 were manufactured.

### <Reliability Test of Samples 1 and 2>

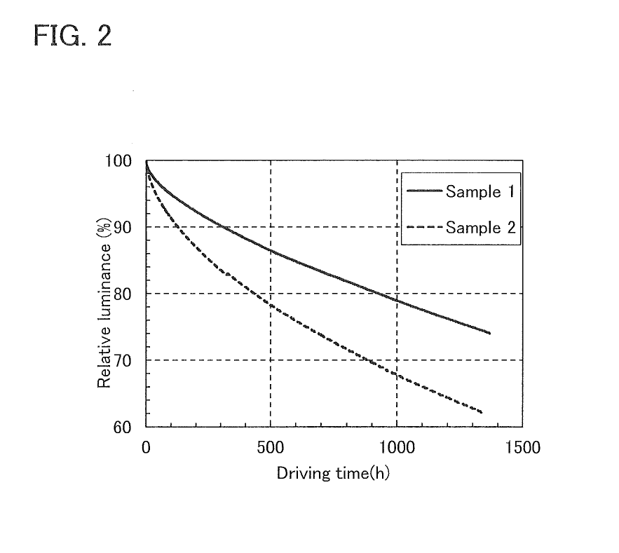

Next, reliability tests were performed on Samples 1 and 2. In the reliability tests, Samples 1 and 2 were driven under the conditions where the initial luminance was 5000 cd/m² and the current density was constant. FIG. 2 shows results of the reliability tests. In FIG. 2, the vertical axis represents relative luminance (%) with the initial luminance of 100%, and the horizontal axis represents driving time (h).

The results in FIG. 2 showed that relative luminance of Sample 1 after 1368 hours was 74.0% and relative luminance of Sample 2 after 1342 hours was 62.2%.

### <3. Analysis of Impurity in EL Layer (Liquid Chromatography Mass Spectrometry)>

Next, an impurity in the EL layer 108 of each of Samples 1 and 2 was analyzed. Note that for analysis of an impurity in Sample 1, a sample that was different from Sample 1 and was formed over the same substrate as Sample 1 was used; for analysis of an impurity in Sample 2, a sample that was different from Sample 2 and was formed over the same substrate as Sample 2 was used. In each of the samples for the impurity analysis, the area of the lower electrode 104 was approximately 12 cm² (3.5 cm×3.3 cm). In other words, the samples for the impurity analysis had the same materials and structures as Samples 1 and 2, but were different from Samples 1 and 2 in the area of the lower electrode 104. The samples for the impurity analysis were not driven; thus, the obtained results were not the analysis results of deteriorated objects produced by driving, but the analysis results of an impurity that had been contained from before driving. Here, the sample for the impurity analysis that was fabricated over the same substrate as Sample 1 is regarded as Sample 1 for convenience. The same applies to Sample 2.

An impurity in Samples 1 and 2 was analyzed by LC/MS.

In the LC/MS analysis, LC separation was performed using ACQUITY UPLC System manufactured by Waters Corporation, and detection was performed using a PDA detector and an MS detector. Note that a PDA eλ detector manufactured by Waters Corporation was used as the PDA detector, and Xevo G2 Tof MS manufactured by Waters Corporation was used as the MS detector. The measurement range of the Xevo G2 Tof MS detector manufactured by Waters Corporation, which used in the analysis, was m/z=100 or more.

ACQUITY UPLC BEH C8 (2.1×100 mm, 1.7 μm) was used as a column for the LC separation, and the column temperature was 40° C. Acetonitrile was used for Mobile Phase A and a 0.1% formic acid aqueous solution was used for Mobile Phase B.

Samples for the LC/MS analysis were obtained in the following manner: aluminum that was the upper electrode 114 of each of Samples 1 and 2 was peeled with the use of a Kapton tape (registered trademark); a substance remaining over the substrate 102 was dissolved in chloroform, so that a chloroform solution was obtained; and the chloroform solution was diluted with acetonitrile to a given concentration. The injection amount of the analysis sample was 5.0 μL in the LC/MS analysis.

### <4. Method of Analysis by Liquid Chromatography Mass Spectrometry>

The LC separation of the analysis samples was performed. In the LC separation, a gradient method in which the ratio between mobile phases is changed was employed. The ratio of Mobile Phase A to Mobile Phase B was 60:40 for 0 to 1 minute after the start of the measurement, and then the ratio of Mobile Phase A to Mobile Phase B was changed linearly such that the ratio in the 15th minute was 95:5. That is, the measurement time was 15 minutes.

With the PDA detector, detection was performed in the range of 210 nm to 800 nm, and the detection interval was 1.2 nm.

In the MS analysis, ionization was carried out by an electrospray ionization (ESI) method. At this time, the capillary voltage and the sample cone voltage were set to 3.0 kV and 30 V, respectively, and detection was performed in a positive mode. The mass range for the measurement was m/z=100 to 1300.

The LC separation was performed under the above conditions, and a component which underwent the ionization was collided with an argon gas in a collision cell. Energy (collision energy) for the collision with argon was 6 eV, which allowed observation of product ions.

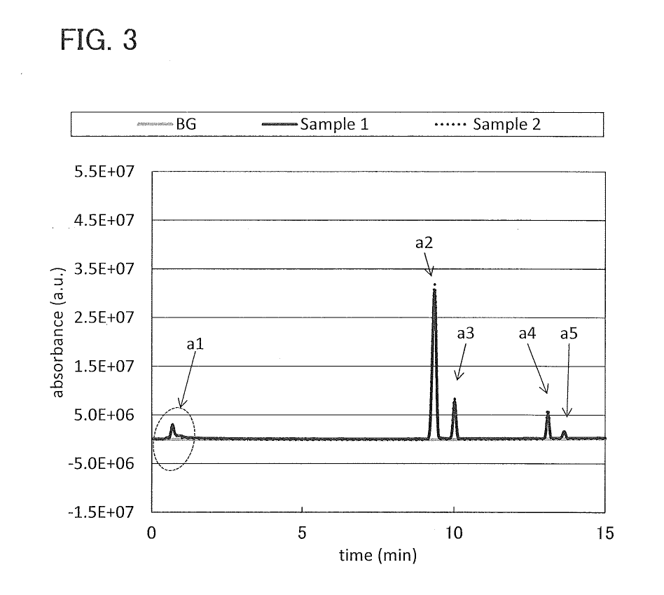

FIG. 3 shows PDA chromatograms obtained by the LC/MS analysis of Samples 1 and 2.

The chloroform used for fabrication of the analysis samples was diluted with acetonitrile to give a solution, and the solution was analyzed to obtain a PDA base-line (or background: BG) chromatogram. In FIG. 3, the obtained base line is denoted as BG.

As shown in FIG. 3, the chromatograms of the EL layers 108 of Samples 1 and 2 exhibited peaks a1 to a5. Analysis of the peaks a1 to a5 using an MS spectrum showed that the peak a2 was assigned to 2mDBTBPDBq-II and BPAFLP; the peak a3, DBT3P-II; the peak a4, PCBNBB; and the peak a5, Ir(tppr)₂(dpm). By comparison with BG, the peak a1 was assigned to the chloroform that was used as a solvent, an impurity contained in the chloroform, and Bphen. As described above, an obvious peak other than the peaks that were assigned to the materials used for forming the EL layer 108 was not observed.

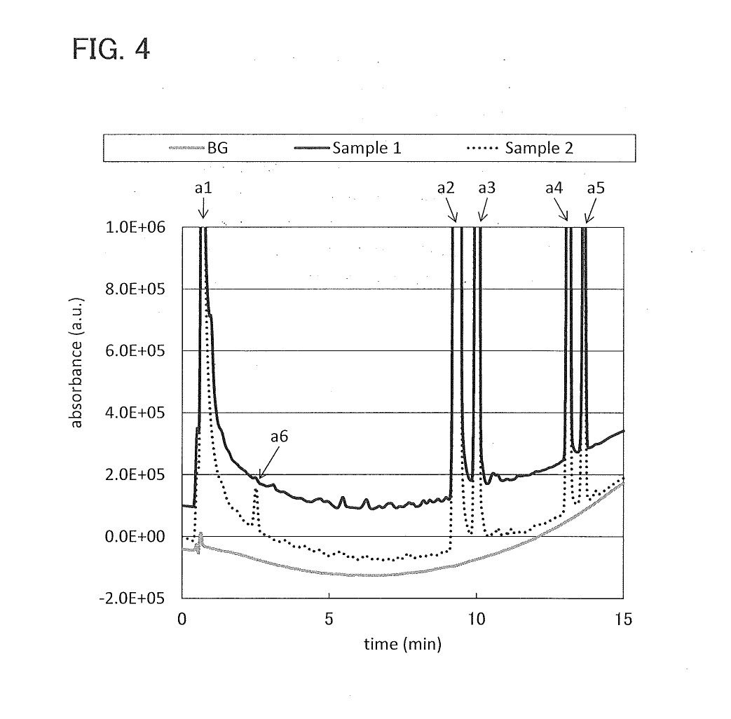

Next, the PDA chromatograms were analyzed with a focus on Ir(tppr)₂(dpm). The base line was subtracted in the analysis of the PDA chromatograms. FIG. 4 shows the LC/MS chromatograms of Samples 1 and 2 in the vicinity of the peak assigned to Ir(tppr)₂(dpm). FIG. 4 is a graph obtained by expanding the scale of the absorbance in FIG. 3.

In FIG. 4, a peak a6 was observed in addition to the peaks a1 to a5 observed in FIG. 3. Analysis using an MS chromatogram shows that the peak a6 is assigned to tppr, which is a ligand of Ir(tppr)₂(dpm). Although many small peaks were observed in addition to the peaks a1 to a6, a peak whose proportion of the peak area is significantly different between Sample 1 and Sample 2 was not observed.

That is, an MS spectrum including a peak derived from an Ir compound was obtained only from the peak a5, and the peak a6 derived from a compound not containing Ir but originating in Ir(tppr)₂(dpm) was observed in FIG. 4. Note that in FIG. 4, the peak a5 corresponds to a precursor ion of the iridium complex, and the peak a6 corresponds to a fragment ion of the iridium complex.

### <5. Analysis of Impurity in Sample Originating in Iridium Complex>

Next, with the use of the results of LC/MS analysis shown in FIG. 4, the concentration of impurities in Samples 1 and 2 originating in the iridium complex was examined. Table 2 shows the concentration of the impurities. Note that the results shown in Table 2 were obtained on the assumption that the peak areas of the peaks a5 and a6 in FIG. 4, i.e., the total peak area of substances originating in the iridium complex, was 100%.

TABLE 2

| | a5 | a6 | |
|---|---|---|---|
| | (990) | (309) | a6/a5 |
| Sample 1 | 99.2% | 0.8% | 0.8% |
| Sample 2 | 90.4% | 9.6% | 10.6% |

Value within parentheses is exact mass or mass of proton adduct

As shown in Table 2, in Sample 1, on the assumption that the total peak area of substances originating in the iridium complex Ir(tppr)₂(dpm) was 100%, the proportion of the peak area (a6) of a ligand not coordinated to the iridium metal to the peak area (a5) of the iridium complex was 0.8%. In Sample 2, on the assumption that the total peak area of substances originating in the iridium complex Ir(tppr)₂(dpm) was 100%, the proportion of the peak area (a6) of a ligand not coordinated to the iridium metal to the peak area (a5) of the iridium complex was 10.6%.

As described above, the content of the ligand not coordinated to the iridium metal, which is an impurity originating in the iridium complex in the light-emitting layer 110, was different between Samples 1 and 2. This difference in the content of the ligand not coordinated to the iridium metal presumably resulted in the difference in reliability between Samples 1 and 2 that is shown in FIG. 2. Accordingly, the light-emitting element can have high reliability by a reduction in concentration of the ligand, which is one of impurities originating in the iridium complex that is the light-emitting substance in the light-emitting layer 110 of the EL layer 108.

### <Analysis of Impurity in Material Originating in Iridium Complex>

The ligand not coordinated to the iridium metal in Samples 1 and 2 might be contained in the iridium complex before deposition by evaporation, or might be produced in the EL layer 108 through decomposition during or after deposition by evaporation. Thus, an impurity in a material originating in the iridium complex before deposition by evaporation was analyzed.

Samples for the LC/MS analysis were obtained in the following manner: the iridium complex (Material X1) before deposition by evaporation was dissolved in chloroform, so that a chloroform solution was obtained; and the chloroform solution was diluted with acetonitrile to a given concentration. The injection amount of the analysis sample was 5.0 μL in the LC/MS analysis. The method of the LC/MS analysis was the same as that employed for Samples 1 and 2 above, except for the conditions of the LC separation. In the LC separation of Material X1, acetonitrile was used for Mobile Phase A and a 0.1% formic acid aqueous solution was used for Mobile Phase B. A gradient method in which the ratio between mobile phases is changed was employed. The ratio of Mobile Phase A to Mobile Phase B was 75:25 for 0 to 1 minute after the start of the measurement; the ratio of Mobile Phase A to Mobile Phase B was changed linearly such that the ratio in the 4th minute was 90:10; and then, the ratio of Mobile Phase A to Mobile Phase B was changed linearly such that the ratio in the 10th minute was 95:5. That is, the total measurement time was 10 minutes.

In an MS spectrum obtained in the LC/MS analysis of Material X1, peaks were observed at m/z=991, m/z=1145, m/z=1023, and m/z=915. With the use of the peak areas, impurities contained in Material X1 were analyzed, and the results are shown in Table 3.

TABLE 3

| | (991) | (1145) | (1023) | (915) |
|---|---|---|---|---|
| Material X1 | 99.6% | 0.1% | 0.1% | 0.2% |

Value within parentheses is exact mass or mass of proton adduct

As shown in Table 3, Material X1, which was the iridium complex used in the light-emitting layer 110 of Samples 1 and 2, had high purity, and the existence of the ligand tppr serving as an impurity, which was confirmed in the light-emitting layer 110, was not confirmed in Material X1.

It was thus suggested that tppr, which was a ligand of Ir(tppr)₂(dpm) and was contained in the light-emitting layer 110 of Sample 2 in a large amount, was produced in the EL layer 108 during or after deposition by evaporation.

Here, the components of the light-emitting element 100 in FIG. 1 are described below in detail.

### <Substrate>

The substrate 102 is used as a support of the light-emitting element 100. For the substrate 102, glass, quartz, plastic, or the like can be used, for example. Alternatively, a flexible substrate can be used. A flexible substrate is a substrate that can be bent; examples of the flexible substrate include a plastic substrate made of a polycarbonate, a polyarylate, or a polyethersulfone. A film (made of polypropylene, a polyester, poly(vinyl fluoride), poly(vinyl chloride), or the like), an inorganic vapor-deposited film, or the like can be used.

The substrate may be formed with any other material that can serve as a support in a fabrication process of the light-emitting element 100. The light-emitting element 100 can be formed using a variety of substrates, for example. The type of the substrate is not limited to a certain type. As the substrate, a semiconductor substrate (e.g., a single crystal substrate or a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, paper including a fibrous material, a base material film, or the like can be used, for example. Examples of a glass substrate include a barium borosilicate glass substrate, an aluminoborosilicate glass substrate, and a soda lime glass substrate. Examples of the flexible substrate, the attachment film, the base film, and the like are substrates of plastics typified by polyethylene terephthalate (PET), polyethylene naphthalate (PEN), polyether sulfone (PES), and polytetrafluoroethylene (PTFE). Another example is a synthetic resin such as acrylic. Furthermore, polypropylene, polyester, polyvinyl fluoride, and polyvinyl chloride can be given as examples. Other examples are polyamide, polyimide, aramid, epoxy, an inorganic vapor deposition film, paper, and the like.

Alternatively, a flexible substrate may be used as the substrate, and the light-emitting element 100 may be provided directly on the flexible substrate. Alternatively, a separation layer may be provided between the substrate and the light-emitting element 100. The separation layer can be used when part or the whole of the light-emitting element 100 formed over the separation layer is completed, separated from the substrate, and transferred to another substrate. In such a case, the light-emitting element 100 can be transferred to a substrate having low heat resistance or a flexible substrate as well. For the above separation layer, a stack including inorganic films, which are a tungsten film and a silicon oxide film, or an organic resin film of polyimide or the like formed over a substrate can be used, for example.

In other words, after the light-emitting element 100 is formed using a substrate, the light-emitting element 100 may be transferred to another substrate. Examples of a substrate to which the light-emitting element 100 is transferred include, in addition to the above-described substrates, a paper substrate, a cellophane substrate, an aramid film substrate, a polyimide substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupra, rayon, or regenerated polyester), or the like), a leather substrate, and a rubber substrate. By using such a substrate, the light-emitting element 100 with high durability, the light-emitting element 100 with high heat resistance, the light-emitting element 100 that is lightweight, or the light-emitting element 100 that is thin can be obtained.

### <Pair of Electrodes>

As the lower electrode 104 and the upper electrode 114, a metal, an alloy, an electrically conductive compound, a mixture thereof, and the like can be used. Specific examples include indium oxide-tin oxide (ITO: indium tin oxide), indium oxide-tin oxide containing silicon or silicon oxide (ITSO), indium oxide-zinc oxide, indium oxide containing tungsten oxide and zinc oxide, gold (Au), platinum (Pt), nickel (Ni), tungsten (W), chromium (Cr), molybdenum (Mo), iron (Fe), cobalt (Co), copper (Cu), palladium (Pd), and titanium (Ti). In addition, any of the following materials can be used: elements that belong to Group 1 or Group 2 of the periodic table, that is, alkali metals such as lithium (Li) and cesium (Cs) or alkaline earth metals such as calcium (Ca) and strontium (Sr), magnesium (Mg), and alloys containing at least one of the metals (e.g., Mg—Ag and Al—Li); rare earth metals such as europium (Eu) and ytterbium (Yb), and alloys containing at least one of the metals; and graphene. The lower electrode 104 and the upper electrode 114 can be formed by, for example, a sputtering method, an evaporation method (including a vacuum evaporation method), or the like.

### <Light-Emitting Layer>

The light-emitting layer 110 contains at least an iridium complex as a light-emitting substance. The light-emitting layer 110 contains either or both of an electron-transport material and a hole-transport material in addition to the light-emitting substance. Although the light-emitting layer 110 included in the light-emitting element 100 in FIG. 1 has a single-layer structure, one embodiment of the present invention is not limited to this example, and a stacked-layer structure including two or more layers may be employed.

An example of the iridium complex included in the light-emitting layer 110 is an iridium complex including two or more ligands each of which includes an aromatic heterocyclic compound containing at least one nitrogen atom.

Examples of the aromatic heterocyclic compound include imidazole, pyrazole, isothiazole, isoxazole, pyrazine, pyridine, pyrimidine, pyridazine, indazole, purine, quinoxaline, quinoline, isoquinoline, phthalazine, naphthyridine, quinazoline, cinnoline, pteridine, phenanthridine, acridine, perimidine, phenanthroline, phenazine, oxadiazole, thiadiazole, triazole, and triazine.

In the iridium complex included in the light-emitting element of one embodiment of the present invention, the nitrogen atom of the aromatic heterocyclic compound in the above ligand is coordinated to the iridium metal. Note that the ligand of the iridium complex does not necessarily include the above aromatic heterocyclic compound.

In the case where an impurity is produced during deposition by evaporation because of thermal decomposition or the like in the iridium complex, which is to be included in the light-emitting element of one embodiment of the present invention, the impurity might be mixed into a film after the deposition by evaporation. In the case where an impurity produced during the deposition by evaporation is mixed into the film after the deposition by evaporation, the iridium complex included in the light-emitting element might have a low purity. As a specific example of the impurity mixed into the light-emitting element, a ligand coordinated to the iridium metal of the iridium complex can be given.

In some cases, the above-described iridium complex is more easily decomposed when the coordinate bond between a nitrogen atom in the ligand and the iridium metal is weak. It can be presumed that when the aromatic heterocyclic compound of the ligand coordinated to the iridium metal contains two or more nitrogen atoms, the basicity of the ring becomes lower and the coordinate bond becomes weaker than when only one nitrogen atom is contained. Thus, an iridium complex whose ligand includes an aromatic heterocyclic compound containing two or more nitrogen atoms might easily suffer a reduction in purity through deposition by evaporation.

In other words, decomposition of a ligand and mixture thereof into the light-emitting element occur more easily in the case of using an iridium complex whose ligand includes an aromatic heterocyclic compound containing two or more nitrogen atoms than in the case of using an iridium complex whose ligand includes an aromatic heterocyclic compound containing one nitrogen atom. Thus, the lifetime of the light-emitting element can be extended by inhibiting mixture of a ligand of an iridium complex that includes an aromatic heterocyclic compound containing two or more nitrogen atoms.

Examples of the aromatic heterocyclic compound containing two or more nitrogen atoms include diazine and triazine. Specific examples of the aromatic heterocyclic compound containing two nitrogen atoms include imidazole, pyrazole, pyrazine, pyrimidine, pyridazine, indazole, purine, quinoxaline, phthalazine, naphthyridine, quinazoline, cinnoline, pteridine, phenanthridine, perimidine, phenanthroline, phenazine, oxadiazole, thiadiazole, triazole, and triazine.

As examples of the iridium complex that can be used in the light-emitting element of one embodiment of the present invention, iridium complexes represented by General Formulae (G1) to (G4) below can be given.

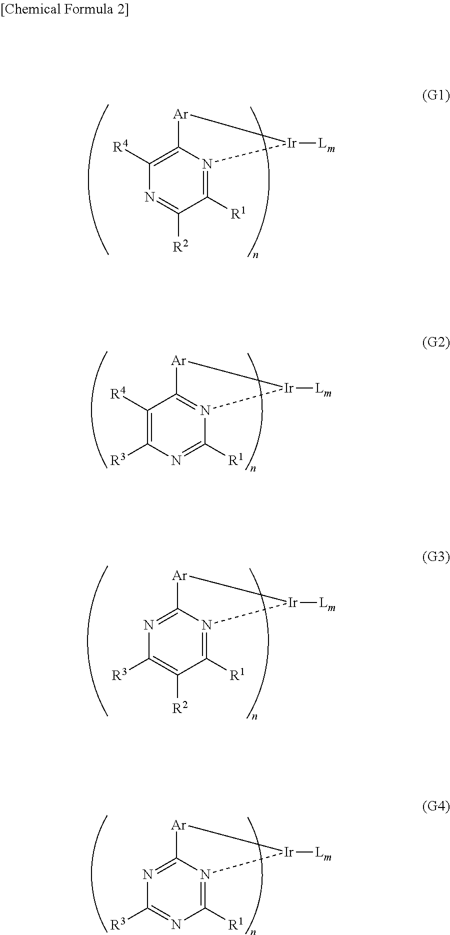

In General Formulae (G1) to (G4), each of R¹ to R⁴ independently represents hydrogen, an alkyl group having 1 to 6 carbon atoms, or a substituted or unsubstituted aryl group having 1 to 10 carbon atoms and forming a ring, Ar represents a substituted or unsubstituted arylene group having 1 to 10 carbon atoms and forming a ring, and L represents a monoanionic ligand. Furthermore, n is 2 or 3, in is 0 or 1, and the sum of n and m is 3.

The monoanionic ligand represented by L in General Formulae (G1) to (G4) is preferably any of a monoanionic bidentate chelate ligand having a β-diketone structure, a monoanionic bidentate chelate ligand having a carboxyl group, a monoanionic bidentate chelate ligand having a phenolic hydroxyl group, and a monoanionic bidentate chelate ligand in which two ligand elements are both nitrogen.

As examples of the monoanionic ligand, ligands represented by General Formulae (L1) to (L7) below can be given.

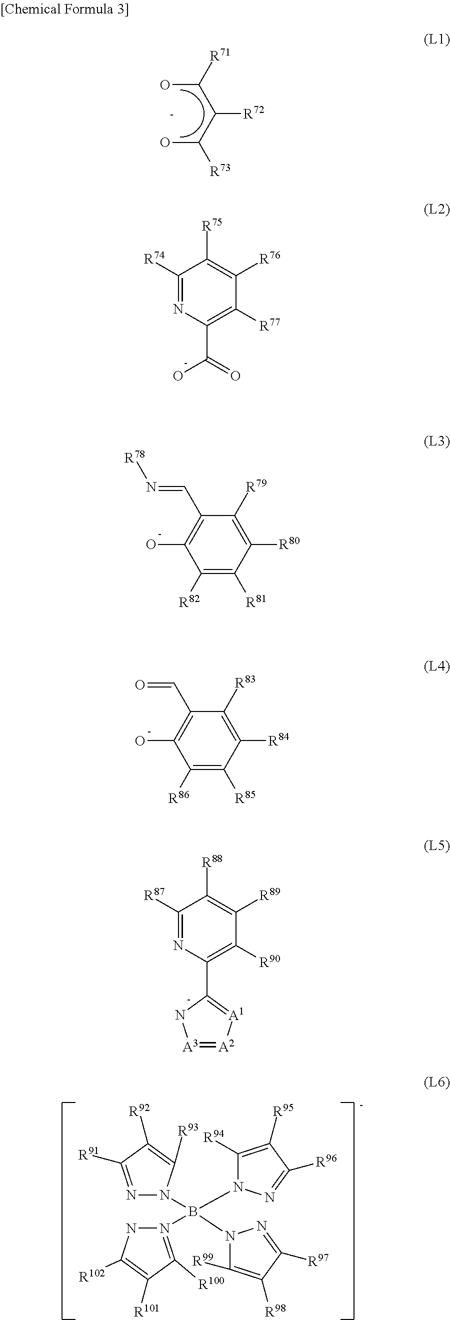

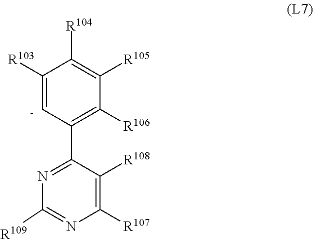

In General Formulae (L1) to (L7), each of R⁷¹ to R¹⁰⁹ independently represents hydrogen, a substituted or unsubstituted alkyl group having 1 to 6 carbon atoms, a halogen group, a vinyl group, a substituted or unsubstituted haloalkyl group having 1 to 6 carbon atoms, a substituted or unsubstituted alkoxy group having 1 to 6 carbon atoms, or a substituted or unsubstituted alkylthio group having 1 to 6 carbon atoms. In addition, each of A¹ to A³ independently represents nitrogen, hydrogen, or carbon bonded to a substituent R. The substituent R represents an alkyl group having 1 to 6 carbon atoms, a halogen group, a haloalkyl group having 1 to 6 carbon atoms, or a phenyl group.

The iridium complex included in the light-emitting element of one embodiment of the present invention is not limited to the iridium complexes represented by General Formulae (G1) to (G4). Examples of the iridium complex included in the light-emitting element of one embodiment of the present invention include organometallic iridium complexes having pyrimidine skeletons, such as tris(4-methyl-6-phenylpyrimidinato)iridium(III) (abbreviation: Ir(mppm)₃), tris(4-t-butyl-6-phenylpyrimidinato)iridium(III) (abbreviation: Ir(tBuppm)₃), (acetylacetonato)bis(6-methyl-4-phenylpyrimidinato)iridium(III) (abbreviation: Ir(mppm)₂(acac)), (acetylacetonato)bis(6-tert-butyl-4-phenylpyrimidinato)iridium(III) (abbreviation: Ir(tBuppm)₂(acac)), (acetylacetonato)bis[4-(2-norbornyl)-6-phenylpyrimidinato]iridium(III) (endo-and exo-mixture) (abbreviation: Ir(nbppm)₂(acac)), (acetylacetonato)bis[5-methyl-6-(2-methylphenyl)-4-phenylpyrimidinato]iridium(III) (abbreviation: Ir(mpmppm)₂(acac)), (acetylacetonato)bis(4,6-diphenylpyrimidinato)iridium(III) (abbreviation: Ir(dppm)₂(acac)), bis{4,6-dimethyl-2-[5-(2,6-dimethylphenyl)-3-(3,5-dimethylphenyl)-2-pyrazinyl-κN]phenyl-κC}(2,4-pentanedionato-κ2O,O′)iridium(III) (abbreviation: Ir(dmdppr-dmp)₂(acac)), and bis{2-[5-(2,6-dimethylphenyl)-3-(3,5-dimethylphenyl)-2-pyrazinyl-κN]-4,6-dimethylphenyl-κC}(2,2,6,6-tetramethyl-3,5-heptanedionato-κ2O,O′)iridium(III) (abbreviation: Ir(dmdppr-dmp)₂(dpm)); organometallic iridium complexes having pyrazine skeletons, such as (acetylacetonato)bis(3,5-dimethyl-2-phenylpyrazinato)iridium(III) (abbreviation: Ir(mppr-Me)₂(acac)), (acetylacetonato)bis(5-isopropyl-3-methyl-2-phenylpyrazinato)iridium(III) (abbreviation: Ir(mppr-iPr)₂(acac)), (acetylacetonato)bis(2,3,5-triphenylpyrazinato)iridium(III) (abbreviation: Ir(tppr)₂(acac)), and bis[2-(3,5-diphenyl-2-pyrazinyl-κN)-phenyl-κC](2,2,6,6-tetramethyl-3,5-heptanedionato-κκ2O,O′)iridium(III) (abbreviation: Ir(tppr)₂(dpm)); and organometallic iridium complexes having pyridine skeletons, such as tris(2-phenylpyridinato-N,C^{2′})iridium(III) (abbreviation: Ir(ppy)₃), bis(2-phenylpyridinato-N,C^{2′})iridium(III) acetylacetonate (abbreviation: Ir(ppy)₂(acac)), bis(benzo[h]quinolinato)iridium(III) acetylacetonate (abbreviation: Ir(bzq)₂(acac)), tris(benzo[h]quinolinato)iridium(III) (abbreviation: Ir(bzq)₃), tris(2-phenylquinolinato-N,C^{2′})iridium(III) (abbreviation: Ir(pq)₃), and bis(2-phenylquinolinato-N,C^{2′})iridium(III) acetylacetonate (abbreviation: Ir(pq)₂(acac)).

The above iridium complexes each have an emission peak at greater than or equal to 480 nm and less than or equal to 650 nm. Among the iridium complexes given above, the iridium complex having a pyrimidine skeleton has distinctively high reliability and emission efficiency and is thus especially preferable. By preventing a reduction in purity of the above iridium complex in a light-emitting element, the light-emitting element can have a long lifetime. An increase in purity of the above iridium complex in a light-emitting element greatly contributes to extension of the lifetime of the light-emitting element.

As the electron-transport material used for the light-emitting layer 110, a π-electron deficient heteroaromatic compound such as a nitrogen-containing heteroaromatic compound is preferable. As the electron-transport material, a π-electron deficient heteroaromatic compound, a metal complex, or the like can be used. Specific examples include a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); a heterocyclic compound having an azole skeleton such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II); a heterocyclic compound having a diazine skeleton such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), or 4,6-bis[3-(4-dibenzothienyl)phenyl]pyrimidine (abbreviation: 4,6mDBTP2Pm-II); a heterocyclic compound having a triazine skeleton such as 2-{4-[3-(N-phenyl-9H-carbazol-3-yl)-9H-carbazol-9-yl]phenyl}-4,6-diphenyl-1,3,5-triazine (abbreviation: PCCzPTzn); and a heterocyclic compound having a pyridine skeleton such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB). Among the above materials, a heterocyclic compound having a diazine skeleton, a heterocyclic compound having a triazine skeleton, and a heterocyclic compound having a pyridine skeleton have high reliability and are thus preferable. Heterocyclic compounds having diazine (pyrimidine or pyrazine) skeletons and triazine skeletons have a high electron-transport property and contribute to a decrease in drive voltage.

As the hole-transport material used for the light-emitting layer 110, a π-electron rich heteroaromatic compound or an aromatic amine compound is preferable. As the hole-transport material, a π-electron rich heteroaromatic compound, an aromatic amine compound, or the like can be favorably used. Specific examples include a compound having an aromatic amine skeleton such as 2-[N-(9-phenylcarbazol-3-yl)-N-phenylamino]spiro-9,9′-bifluorene (abbreviation: PCASF), 4,4′-bis[N-(1-naphthyl)-N-phenylamino]biphenyl (abbreviation: NPB), N,N′-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBAlBP), 4,4′-diphenyl-4″-(9-phenyl-9H-carbazol-3-yl)triphenylamine (abbreviation: PCBBilBP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF); a compound having a carbazole skeleton such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 9-phenyl-9H-3-(9-phenyl-9H-carbazol-3-yl)carbazole (abbreviation: PCCP); a compound having a thiophene skeleton such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, a compound having an aromatic amine skeleton and a compound having a carbazole skeleton are preferable because these compounds are highly reliable and have high hole-transport properties to contribute to a reduction in drive voltage.

Furthermore, as the hole-transport material used for the light-emitting layer 110, a high molecular compound such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), or poly[N,N′-bis(4-butylphenyl)-N,N′-bis(phenyl)benzidine] (abbreviation: Poly-TPD) can be used.

The electron-transport material and the hole-transport material used for the light-emitting layer 110 preferably form an exciplex (also called excited complex). For example, the electron-transport material and the hole-transport material used for the light-emitting layer 110 accept electrons and holes, respectively. At this time, the electron-transport material and the hole-transport material come close to each other, thereby forming an exciplex immediately. Therefore, most excitons in the light-emitting layer 110 exist as the exciplexes. The band gap of the exciplex is smaller than that of the electron-transport material and that of the hole-transport material, which allows the drive voltage of the light-emitting element 100 to be reduced.

It is preferable that energy be transferred from the exciplex to the iridium complex included in the light-emitting element of one embodiment of the present invention. Specifically, light emission is preferably achieved by transfer of both energy of the lowest level (S_{E}) of a singlet excited state of the exciplex and energy of the lowest level (T_{E}) of a triplet excited state of the exciplex to the lowest level of a triplet excited state of the iridium complex, in which case high emission efficiency can be achieved.

### <Hole-Injection Layer and Hole-Transport Layer>

The hole-injection layer 131 is a layer that injects holes into the light-emitting layer 110 through the hole-transport layer 132 with a high hole-transport property and includes a hole-transport material and an acceptor substance. When a hole-transport material and an acceptor substance are included, electrons are extracted from the hole-transport material by the acceptor substance to generate holes, and the holes are injected into the light-emitting layer 110 through the hole-transport layer 132. Note that the hole-transport layer 132 is formed using a hole-transport material.

As a hole-transport material used for the hole-injection layer 131 and the hole-transport layer 132, a material similar to the aforementioned hole-transport material that can be used for the light-emitting layer 110 is used.

Examples of the acceptor substance that is used for the hole-injection layer 131 include oxides of metals belonging to Groups 4 to 8 of the periodic table. Specifically, it is particularly preferable to use molybdenum oxide.

### <Electron-Transport Layer>

For the electron-transport layer 133, a material similar to the aforementioned electron-transport material that can be used for the light-emitting layer 110 is used. Note that in the light-emitting element 100 shown in FIG. 1, the electron-transport layer 133 has a stacked-layer structure including the electron-transport layer 133(1) and the electron-transport layer 133(2); however, one embodiment of the present invention is not limited to this example and a single-layer structure or a stacked-layer structure including three or more layers may be employed.

### <Electron-Injection Layer>

The electron-injection layer 134 is a layer including a substance with a high electron-injection property. For the electron-injection layer 134, an alkali metal, an alkaline earth metal, or a compound thereof, such as lithium fluoride (LiF), cesium fluoride (CsF), calcium fluoride (CaF₂), or lithium oxide (LiOₓ), can be used. Alternatively, a rare earth metal compound such as erbium fluoride (ErF₃) can be used. Electride may also be used for the electron-injection layer 134. Examples of the electride include a substance in which electrons are added at high concentration to calcium oxide-aluminum oxide.

Alternatively, the electron-injection layer 134 may be formed using a composite material in which an organic compound and an electron donor (donor) are mixed. The composite material is superior in an electron-injection property and an electron-transport property, since electrons are generated in the organic compound by the electron donor. The organic compound here is preferably a material excellent in transporting the generated electrons; specifically, for example, the substances for forming the electron-transport layer 133 (e.g., a metal complex or a heteroaromatic compound) can be used. As the electron donor, a substance showing an electron-donating property with respect to the organic compound may be used. Specifically, an alkali metal, an alkaline earth metal, and a rare earth metal are preferable, and lithium, cesium, magnesium, calcium, erbium, ytterbium, and the like are given. Furthermore, an alkali metal oxide or an alkaline earth metal oxide is preferable, and for example, lithium oxide, calcium oxide, barium oxide, and the like can be given. Alternatively, Lewis base such as magnesium oxide can also be used. An organic compound such as tetrathiafulvalene (abbreviation: TTF) can also be used.

The structure described in this embodiment can be used in appropriate combination with any of the structures described in other embodiments or examples.

### Embodiment 2

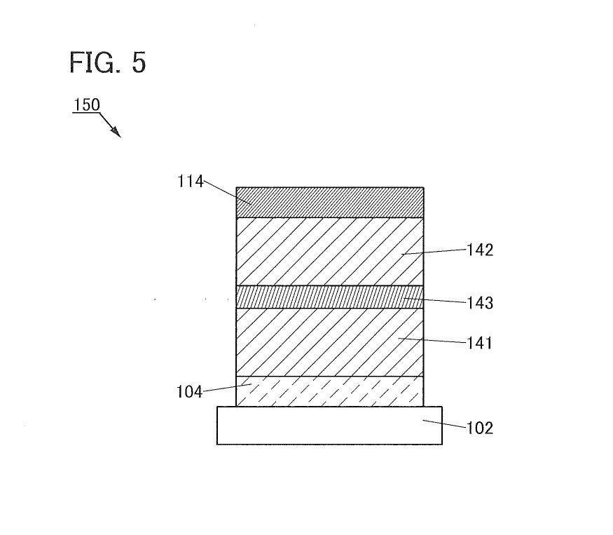

In this embodiment, a light-emitting element of one embodiment of the present invention is described with reference to FIG. 5. FIG. 5 is a schematic cross-sectional view of a light-emitting element 150 of one embodiment of the present invention.

The light-emitting element 150 includes a plurality of light-emitting units (a first light-emitting unit 141 and a second light-emitting unit 142 in FIG. 5) between the lower electrode. 104 and the upper electrode 114. One of both of the first light-emitting unit 141 and the second light-emitting unit 142 has the same structure as the EL layer 108 illustrated in FIG. 1. That is, the light-emitting element 100 in FIG. 1 includes one light-emitting unit while the light-emitting element 150 includes the plurality of light-emitting units.

In the light-emitting element 150 shown in FIG. 5, the first light-emitting unit 141 and the second light-emitting unit 142 are stacked, and a charge generation layer 143 is provided between the first light-emitting unit 141 and the second light-emitting unit 142. Note that the first light-emitting unit 141 and the second light-emitting unit 142 may have the same structure or different structures.

The charge generation layer 143 includes a composite material of an organic compound and a metal oxide. For the composite material, the composite material that can be used for the hole-injection layer 111 described above may be used. As the organic compound, a variety of compounds such as an aromatic amine compound, a carbazole compound, an aromatic hydrocarbon, and a high molecular compound (such as an oligomer, a dendrimer, or a polymer) can be used. An organic compound having a hole mobility of 1×10⁻⁶ cm²/Vs or higher is preferably used. Note that any other substance may be used as long as the substance has a hole-transport property higher than an electron-transport property. Since the composite material of an organic compound and a metal oxide is superior in carrier-injecting property and carrier-transporting property, low-voltage driving or low-current driving can be realized. Note that when a surface of a light-emitting unit on the anode side is in contact with the charge generation layer 143, the charge generation layer 143 can also serve as a hole-transport layer of the light-emitting unit; thus, a hole-transport layer does not need to be formed in the light-emitting unit.

The charge generation layer 143 may have a stacked-layer structure of a layer containing the composite material of an organic compound and a metal oxide and a layer containing another material. For example, the charge generation layer 143 may be formed using a combination of a layer containing the composite material of an organic compound and a metal oxide with a layer containing one compound selected from among electron-donating substances and a compound having a high electron-transporting property. Further, the charge generation layer 143 may be formed using a combination of a layer containing the composite material of an organic compound and a metal oxide with a transparent conductive film.

In any case, as the charge-generation layer 143, which is provided between the first light-emitting unit 141 and the second light-emitting unit 142, acceptable is a layer which injects electrons into the light-emitting unit on one side and injects holes into the light-emitting unit on the other side when voltage is applied to the lower electrode 104 and the upper electrode 114. For example, in FIG. 5, when a voltage is applied such that a potential of the lower electrode 104 is higher than a potential of the upper electrode 114, any structure may be used for the charge generation layer 143, as long as the charge generation layer 143 injects electrons and holes into the first light-emitting unit 141 and the second light-emitting unit 142, respectively.

In FIG. 5, the light-emitting element having two light-emitting units is described; however, one embodiment of the present invention can be similarly applied to a light-emitting element in which three or more light-emitting units are stacked. With a plurality of light-emitting units partitioned by the charge generation layer between a pair of electrodes as in the light-emitting element 150, light high luminance can be obtained while current density is kept low; thus, a light-emitting element having a long lifetime can be obtained. A light-emitting device that can be driven at a low voltage and has low power consumption can be realized.

When the EL layer 108 or the light-emitting layer 110 described in Embodiment 1 is included in at least one of the plurality of units, a highly reliable light-emitting element can be provided.

Any one of the first light-emitting unit 141 and the second light-emitting unit 142 may include a fluorescent material as a light-emitting substance. For example, the light-emitting layer in any one of the first light-emitting unit 141 and the second light-emitting unit 142 includes a host material and a fluorescent material.

In the light-emitting layer of any one of the first light-emitting unit 141 and the second light-emitting unit 142, the host material is present in the highest proportion by weight, and the fluorescent material is dispersed in the host material. It is preferable that the S₁ level of the host material be higher than the S₁ level of the fluorescent material, and the T₁ level of the host material be lower than the T₁ level of the fluorescent material.

An anthracene derivative or a tetracene derivative is preferably used as the host material. This is because these derivatives each have a high S₁ level and a low T₁ level. Specific examples include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), and 9-phenyl-10-{4-(9-phenyl-9H-fluoren-9-yl)biphenyl-4′-yl}anthracene (abbreviation: FLPPA). Besides, 5,12-diphenyltetracene, 5,12-bis(biphenyl-2-yl)tetracene, and the like can be given.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9-phenyl-9H-fluoren-9-yl)phenyl]-N,N′-diphenylpyrene-1,6-diamine (abbreviation: 1,6FLPAPrn), N,N′-bis(dibenzofuran-2-yl)-N,N′-diphenylpyrene-1,6-diamine (abbreviation: 1,6FrAPrn), and N,N′-bis(dibenzothiophen-2-yl)-N,N′-diphenylpyrene-1,6-diamine (abbreviation: 1,6ThAPrn).

The above-described structure can be combined with any of the structures in this embodiment and other embodiments.

### Embodiment 3

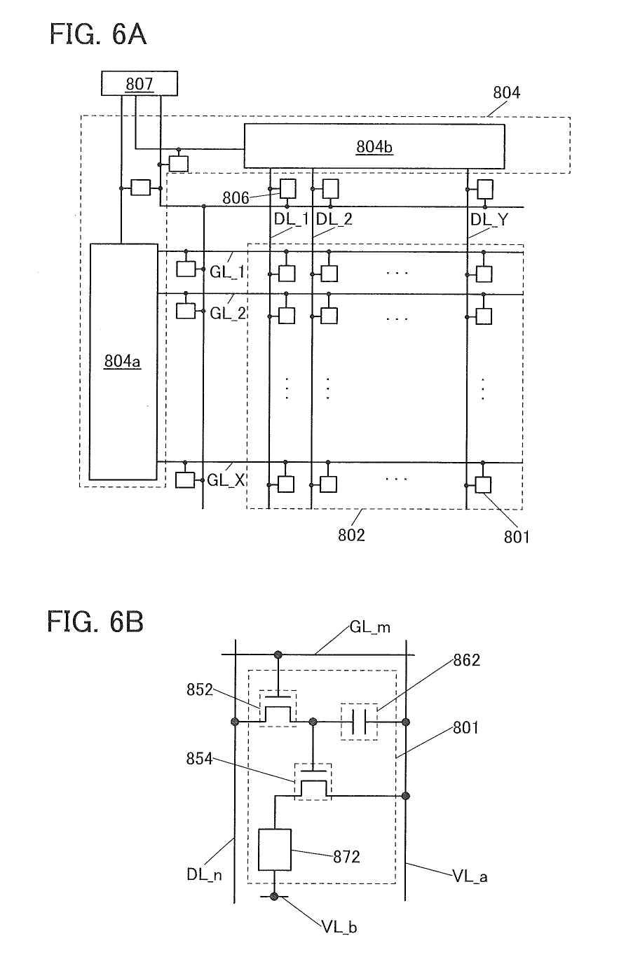

In this embodiment, a display device including a light-emitting device of one embodiment of the present invention will be described with reference to FIGS. 6A and 6B.

FIG. 6A is a block diagram illustrating the display device of one embodiment of the present invention, and FIG. 6B is a circuit diagram illustrating a pixel circuit of the display device of one embodiment of the present invention.

The display device illustrated in FIG. 6A includes a region including pixels of display elements (the region is hereinafter referred to as a, pixel portion 802), a circuit portion provided outside the pixel portion 802 and including circuits for driving the pixels (the portion is hereinafter referred to as a driver circuit portion 804), circuits having a function of protecting elements (the circuits are hereinafter referred to as protection circuits 806), and a terminal portion 807. Note that the protection circuits 806 are not necessarily provided.

A part or the whole of the driver circuit portion 804 is preferably formed over a substrate over which the pixel portion 802 is formed, in which case the number of components and the number of terminals can be reduced. When a part or the whole of the driver circuit portion 804 is not formed over the substrate over which the pixel portion 802 is formed, the part or the whole of the driver circuit portion 804 can be mounted by COG or tape automated bonding (TAB).

The pixel portion 802 includes a plurality of circuits for driving display elements arranged in X rows (X is a natural number of 2 or more) and Y columns (Y is a natural number of 2 or more) (such circuits are hereinafter referred to as pixel circuits 801). The driver circuit portion 804 includes driver circuits such as a circuit for supplying a signal (scan signal) to select a pixel (the circuit is hereinafter referred to as a gate driver 804a) and a circuit for supplying a signal (data signal) to drive a display element in a pixel (the circuit is hereinafter referred to as a source driver 804b).

The gate driver 804a includes a shift register or the like. Through the terminal portion 807, the gate driver 804a receives a signal for driving the shift register and outputs a signal. For example, the gate driver 804a receives a start pulse signal, a clock signal, or the like and outputs a pulse signal. The gate driver 804a has a function of controlling the potentials of wirings supplied with scan signals (such wirings are hereinafter referred to as scan lines GL_1 to GL_X). Note that a plurality of gate drivers 804a may be provided to control the scan lines GL_1 to GL_X separately. Alternatively, the gate driver 804a has a function of supplying an initialization signal. Without being limited thereto, the gate driver 804a can supply another signal.

The source driver 804b includes a shift register or the like. The source driver 804b receives a signal (video signal) from which a data signal is derived, as well as a signal for driving the shift register, through the terminal portion 807. The source driver 804b has a function of generating a data signal to be written to the pixel circuit 801 which is based on the video signal. In addition, the source driver 804b has a function of controlling output of a data signal in response to a pulse signal produced by input of a start pulse signal, a clock signal, or the like. Furthermore, the source driver 804b has a function of controlling the potentials of wirings supplied with data signals (such wirings are hereinafter referred to as data lines DL_1 to DL_Y). Alternatively, the source driver 804b has a function of supplying an initialization signal. Without being limited thereto, the source driver 804b can supply another signal.

The source driver 804b includes a plurality of analog switches or the like, for example. The source driver 804b can output, as the data signals, signals obtained by time-dividing the video signal by sequentially turning on the plurality of analog switches. The source driver 804b may include a shift register or the like.

A pulse signal and a data signal are input to each of the plurality of pixel circuits 801 through one of the plurality of scan lines GL supplied with scan signals and one of the plurality of data lines DL supplied with data signals, respectively. Writing and holding of the data signal to and in each of the plurality of pixel circuits 801 are controlled by the gate driver 804a. For example, to the pixel circuit 801 in the m-th row and the n-th column (in is a natural number of less than or equal to X, and n is a natural number of less than or equal to Y), a pulse signal is input from the gate driver 804a through the scan line GL_m, and a data signal is input from the source driver 804b through the data line DL_n in accordance with the potential of the scan line GL_m.

The protection circuit 806 shown in FIG. 6A is connected to, for example, the scan line GL between the gate driver 804a and the pixel circuit 801. Alternatively, the protection circuit 806 is connected to the data line DL between the source driver 804b and the pixel circuit 801. Alternatively, the protection circuit 806 can be connected to a wiring between the gate driver 804 a and the terminal portion 807. Alternatively, the protection circuit 806 can be connected to a wiring between the source driver 804b and the terminal portion 807. Note that the terminal portion 807 means a portion having terminals for inputting power, control signals, and video signals to the display device from external circuits.

The protection circuit 806 is a circuit that electrically connects a wiring connected to the protection circuit to another wiring when a potential out of a certain range is applied to the wiring connected to the protection circuit.

As illustrated in FIG. 6A, the protection circuits 806 are provided for the pixel portion 802 and the driver circuit portion 804, so that the resistance of the display device to overcurrent generated by electrostatic discharge (ESD) or the like can be improved. Note that the configuration of the protection circuits 806 is not limited to that, and for example, a configuration in which the protection circuits 806 are connected to the gate driver 804a or a configuration in which the protection circuits 806 are connected to the source driver 804b may be employed. Alternatively, the protection circuits 806 may be configured to be connected to the terminal portion 807.

In FIG. 6A, an example in which the driver circuit portion 804 includes the gate driver 804a and the source driver 804b is shown; however, the structure is not limited thereto. For example, only the gate driver 804a may be formed and a separately prepared substrate where a source driver is formed (e.g., a driver circuit substrate formed with a single crystal semiconductor film or a polycrystalline semiconductor film) may be mounted.

Each of the plurality of pixel circuits 801 in FIG. 6A can have a structure illustrated in FIG. 6B, for example.

The pixel circuit 801 illustrated in FIG. 6B includes transistors 852 and 854, a capacitor 862, and a light-emitting element 872.

One of a source electrode and a drain electrode of the transistor 852 is electrically connected to a wiring to which a data signal is supplied (hereinafter referred to as a signal line DL_n). A gate electrode of the transistor 852 is electrically connected to a wiring to which a gate signal is supplied (hereinafter referred to as a scan line GL_m).

The transistor 852 has a function of controlling whether to write a data signal by being turned on or off.

One of a pair of electrodes of the capacitor 862 is electrically connected to a wiring to which a potential is supplied (hereinafter referred to as a potential supply line VL_a), and the other is electrically connected to the other of the source electrode and the drain electrode of the transistor 852.

The capacitor 862 functions as a storage capacitor for storing written data.

One of a source electrode and a drain electrode of the transistor 854 is electrically connected to the potential supply line VL_a. Furthermore, a gate electrode of the transistor 854 is electrically connected to the other of the source electrode and the drain electrode of the transistor 852.

One of an anode and a cathode of the light-emitting element 872 is electrically connected to a potential supply line VL_b, and the other is electrically connected to the other of the source electrode and the drain electrode of the transistor 854.

As the light-emitting element 872, the light-emitting element 100 described in Embodiment 1 can be used.

Note that a high power supply potential VDD is supplied to one of the potential supply line VL_a and the potential supply line VL_b, and a low power supply potential VSS is supplied to the other.

In the display device including the pixel circuits 801 in FIG. 6B, the pixel circuits 801 are sequentially selected row by row by the gate driver 804a in FIG. 6A, for example, whereby the transistors 852 are turned on and a data signal is written.

When the transistors 852 are turned off, the pixel circuits 801 in which the data has been written are brought into a holding state. Furthermore, the amount of current flowing between the source electrode and the drain electrode of the transistor 854 is controlled in accordance with the potential of the written data signal. The light-emitting element 872 emits light with a luminance corresponding to the amount of flowing current. This operation is sequentially performed row by row; thus, an image is displayed.

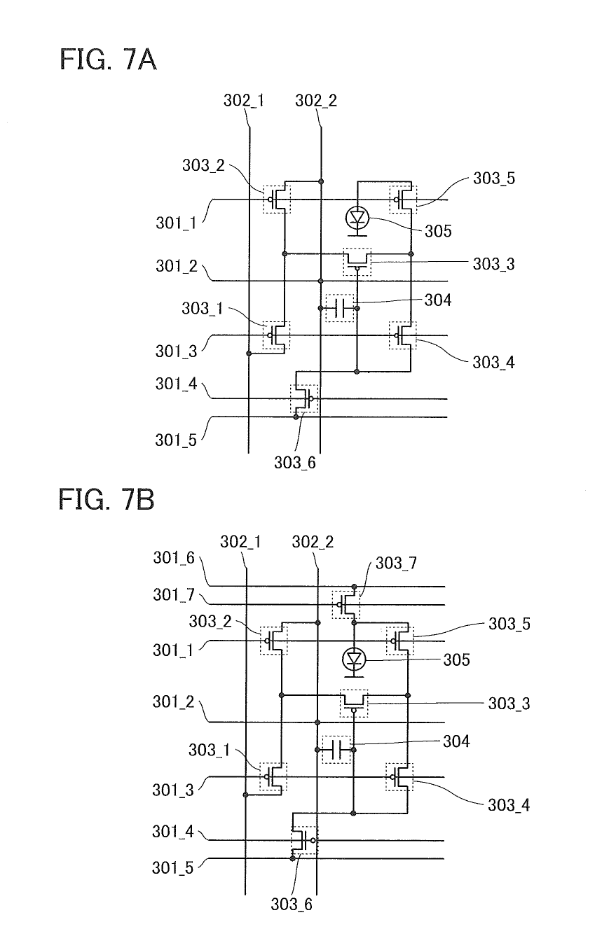

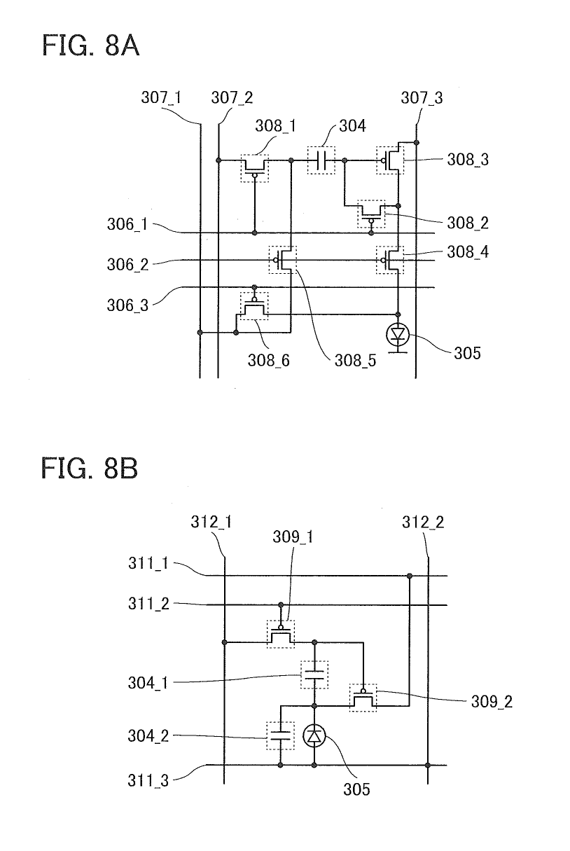

Alternatively, the pixel circuit can have a function of compensating variation in threshold voltages or the like of a transistor. FIGS. 7A and 7B and FIGS. 8A and 8B illustrate examples of the pixel circuit.

The pixel circuit illustrated in FIG. 7A includes six transistors (transistors 303_1 to 303_6), a capacitor 304, and a light-emitting element 305. The pixel circuit illustrated in FIG. 7A is electrically connected to wirings 301_1 to 301_5 and wirings 302_1 and 302_2. Note that as the transistors 303_1 to 303_6, for example, p-channel transistors can be used.

The pixel circuit shown in FIG. 7B has a configuration in which a transistor 303_7 is added to the pixel circuit shown in FIG. 7A. The pixel circuit illustrated in FIG. 7B is electrically connected to wirings 301_6 and 301_7. The wirings 301_5 and 301_6 may be electrically connected to each other. Note that as the transistor 303_7, for example, a p-channel transistor can be used.

The pixel circuit shown in FIG. 8A includes six transistors (transistors 308_1 to 308_6), the capacitor 304, and the light-emitting element 305. The pixel circuit illustrated in FIG. 8A is electrically connected to wirings 306_1 to 306_3 and wirings 307_1 to 307_3. The wirings 306_1 and 306_3 may be electrically connected to each other. Note that as the transistors 308_1 to 308_6, for example, p-channel transistors can be used.

The pixel circuit illustrated in FIG. 8B includes two transistors (transistors 309_1 and 309_2), two capacitors (capacitors 304_1 and 304_2), and the light-emitting element 305. The pixel circuit illustrated in FIG. 8B is electrically connected to wirings 311_1 to 311_3 and wirings 312_1 and 312_2. With the configuration of the pixel circuit illustrated in FIG. 8B, for example, the light-emitting element 305 can be driven by constant voltage constant current (CVCC). Note that as the transistors 309_1 and 309_2, for example, p-channel transistors can be used.

A light-emitting element of one embodiment of the present invention can be used for an active matrix method in which an active element is included in a pixel of a display device or a passive matrix method in which an active element is not included in a pixel of a display device.

In the active matrix method, as an active element (a non-linear element), not only a transistor but also a variety of active elements (non-linear elements) can be used. For example, a metal insulator metal (MIM), a thin film diode (TFD), or the like can also be used. Since these elements can be formed with a smaller number of manufacturing steps, manufacturing cost can be reduced or yield can be improved. Alternatively, since the size of these elements is small, the aperture ratio can be improved, so that power consumption can be reduced or higher luminance can be achieved.

As a method other than the active matrix method, the passive matrix method in which an active element (a non-linear element) is not used can also be used. Since an active element (a non-linear element) is not used, the number of manufacturing steps is small, so that manufacturing cost can be reduced or yield can be improved. Alternatively, since an active element (a non-linear element) is not used, the aperture ratio can be improved, so that power consumption can be reduced or higher luminance can be achieved, for example.

The structure described in this embodiment can be combined with any of the structures described in the other embodiments as appropriate.

### Embodiment 4

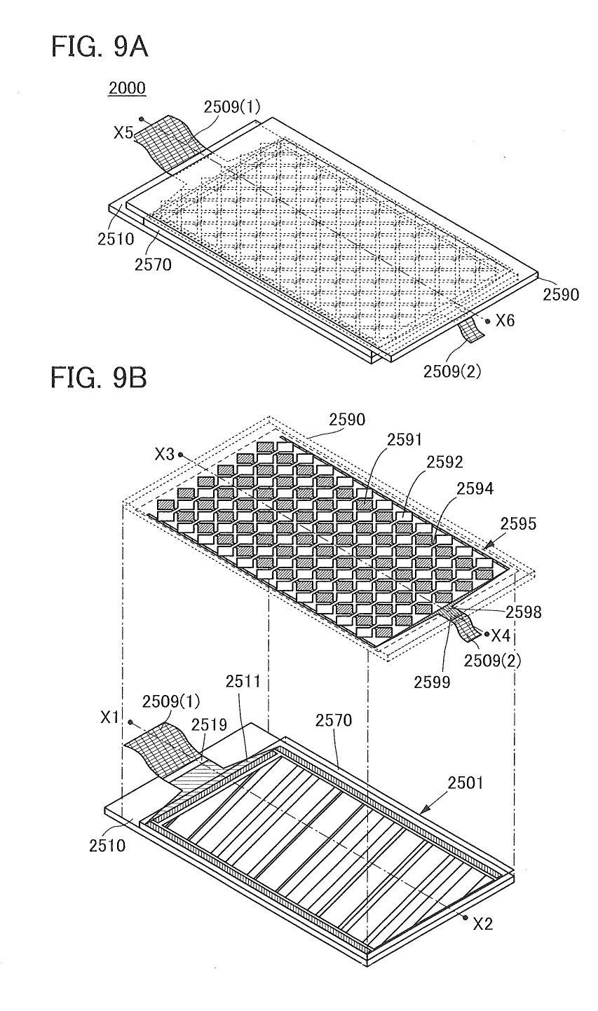

In this embodiment, a display panel including a light-emitting device of one embodiment of the present invention and an electronic device in which the display panel is provided with an input device will be described with reference to FIGS. 9A and 9B, FIGS. 10A to 10C, FIGS. 11A and 11B, FIGS. 12A and 12B, and FIG. 13.

### <Description 1 of Touch Panel>

In this embodiment, a touch panel 2000 including a display panel and an input device will be described as an example of an electronic device. In addition, an example in which a touch sensor is used as an input device will be described. Note that a light-emitting device of one embodiment of the present invention can be used for a pixel of the display panel.

FIGS. 9A and 9B are perspective views of the touch panel 2000. Note that FIGS. 9A and 9B illustrate only main components of the touch panel 2000 for simplicity.

The touch panel 2000 includes a display panel 2501 and a touch sensor 2595 (see FIG. 9B). The touch panel 2000 also includes a substrate 2510, a substrate 2570, and a substrate 2590. The substrate 2510, the substrate 2570, and the substrate 2590 each have flexibility. Note that one or all of the substrates 2510, 2570, and 2590 may be inflexible.

The display panel 2501 includes a plurality of pixels over the substrate 2510 and a plurality of wirings 2511 through which signals are supplied to the pixels. The plurality of wirings 2511 are led to a peripheral portion of the substrate 2510, and parts of the plurality of wirings 2511 form a terminal 2519. The terminal 2519 is electrically connected to an FPC 2509(1).

The substrate 2590 includes the touch sensor 2595 and a plurality of wirings 2598 electrically connected to the touch sensor 2595. The plurality of wirings 2598 are led to a peripheral portion of the substrate 2590, and parts of the plurality of wirings 2598 form a terminal. The terminal is electrically connected to an FPC 2509(2). Note that in FIG. 9B, electrodes, wirings, and the like of the touch sensor 2595 provided on the back side of the substrate 2590 (the side facing the substrate 2510) are indicated by solid lines for clarity.

As the touch sensor 2595, a capacitive touch sensor can be used. Examples of the capacitive touch sensor are a surface capacitive touch sensor and a projected capacitive touch sensor.

Examples of the projected capacitive touch sensor are a self-capacitive touch sensor and a mutual capacitive touch sensor, which differ mainly in the driving method. The use of a mutual capacitive touch sensor is preferable because multiple points can be sensed simultaneously.

Note that the touch sensor 2595 illustrated in FIG. 9B is an example of using a projected capacitive touch sensor.

Note that a variety of sensors that can sense proximity or touch of a sensing target such as a finger can be used as the touch sensor 2595.

The projected capacitive touch sensor 2595 includes electrodes 2591 and electrodes 2592. The electrodes 2591 are electrically connected to any of the plurality of wirings 2598, and the electrodes 2592 are electrically connected to any of the other wirings 2598.

The electrodes 2592 each have a shape of a plurality of quadrangles arranged in one direction with one corner of a quadrangle connected to one corner of another quadrangle as illustrated in FIGS. 9A and 9B.

The electrodes 2591 each have a quadrangular shape and are arranged in a direction intersecting with the direction in which the electrodes 2592 extend.

A wiring 2594 electrically connects two electrodes 2591 between which the electrode 2592 is positioned. The intersecting area of the electrode 2592 and the wiring 2594 is preferably as small as possible. Such a structure allows a reduction in the area of a region where the electrodes are not provided, reducing variation in transmittance. As a result, variation in luminance of light passing through the touch sensor 2595 can be reduced.

Note that the shapes of the electrodes 2591 and the electrodes 2592 are not limited thereto and can be any of a variety of shapes. For example, a structure may be employed in which the plurality of electrodes 2591 are arranged so that gaps between the electrodes 2591 are reduced as much as possible, and the electrodes 2592 are spaced apart from the electrodes 2591 with an insulating layer interposed therebetween to have regions not overlapping with the electrodes 2591. In this case, it is preferable to provide, between two adjacent electrodes 2592, a dummy electrode electrically insulated from these electrodes because the area of regions having different transmittances can be reduced.

Note that for example, a transparent conductive film including indium oxide, tin oxide, zinc oxide, or the like (e.g., a film of ITO) can be given as a material of conductive films used for the electrode 2591, the electrode 2592, and the wiring 2598, i.e., wirings and electrodes in the touch panel. Moreover, for example, a low-resistance material is preferably used as the material of the wiring and the electrode in the touch panel. For example, silver, copper, aluminum, a carbon nanotube, graphene, or a metal halide (such as a silver halide) may be used. Alternatively, a metal nanowire including a plurality of conductors with an extremely small width (e.g., a diameter of several nanometers) may be used. Further alternatively, a net-like metal mesh with a conductor may be used. Examples of such materials include an Ag nanowire, a Cu nanowire, an Al nanowire, an Ag mesh, a Cu mesh, and an Al mesh. For example, in the case of using an Ag nanowire for the wiring and the electrode in the touch panel, a visible light transmittance of 89% or more and a sheet resistance of 40 Ω/cm² or more and 100 Ω/cm² or less can be achieved. A metal nanowire, a metal mesh, a carbon nanotube, graphene, and the like, which are examples of a material that can be used for the above-described wiring and electrode in the touch panel, have a high visible light transmittance; therefore, they may be used for an electrode of a display element (e.g., a pixel electrode or a common electrode).

### <Display Panel>

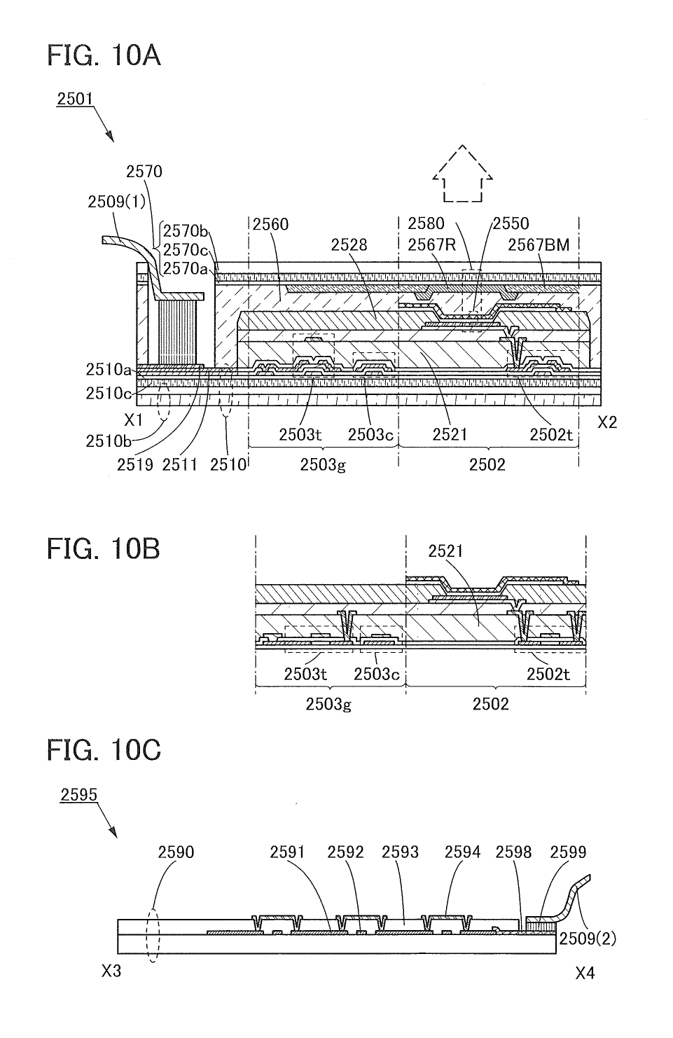

Next, the display panel 2501 will be described in detail with reference to FIG. 10A. FIG. 10A corresponds to a cross-sectional view taken along dashed-dotted line X1-X2 in FIG. 9B.

The display panel 2501 includes a plurality of pixels arranged in a matrix. Each of the pixels includes a display element and a pixel circuit for driving the display element.

For the substrate 2510 and the substrate 2570, for example, a flexible material with a vapor permeability of lower than or equal to 10⁻⁵ g/(m²·day), preferably lower than or equal to 10⁻⁶ g/(m²·day) can be favorably used. Alternatively, materials whose thermal expansion coefficients are substantially equal to each other are preferably used for the substrate 2510 and the substrate 2570. For example, the coefficients of linear expansion of the materials are preferably lower than or equal to 1×10⁻³/K, further preferably lower than or equal to 5×10⁻⁵/K, and still further preferably lower than or equal to 1×10⁻⁵/K.

Note that the substrate 2510 is a stacked body including an insulating layer 2510a for preventing impurity diffusion into the light-emitting element, a flexible substrate 2510b, and an adhesive layer 2510c for attaching the insulating layer 2510a and the flexible substrate 2510b to each other. The substrate 2570 is a stacked body including an insulating layer 2570a for preventing impurity diffusion into the light-emitting element, a flexible substrate 2570b, and an adhesive layer 2570c for attaching the insulating layer 2570a and the flexible substrate 2570b to each other.

For the adhesive layer 2510c and the adhesive layer 2570c, for example, materials that include polyester, polyolefin, polyamide (e.g., nylon, aramid), polyimide, polycarbonate, polyurethane, an acrylic resin, an epoxy resin, or a resin having a siloxane bond can be used.

A sealing layer 2560 is provided between the substrate 2510 and the substrate 2570. The sealing layer 2560 preferably has a refractive index higher than that of air. In the case where light is extracted to the sealing layer 2560 side as illustrated in FIG. 10A, the sealing layer 2560 can also serve as an optical element.

A sealant may be formed in the peripheral portion of the sealing layer 2560. With the use of the sealant, a light-emitting element 2550R can be provided in a region surrounded by the substrate 2510, the substrate 2570, the sealing layer 2560, and the sealant. Note that an inert gas (such as nitrogen or argon) may be used instead of the sealing layer 2560. A drying agent may be provided in the inert gas so as to adsorb moisture or the like. For example, an epoxy-based resin or a glass frit is preferably used as the sealant. As a material used for the sealant, a material which is impermeable to moisture or oxygen is preferably used.

The display panel 2501 includes a pixel 2502. The pixel 2502 includes a light-emitting module 2580.

The pixel 2502 includes the light-emitting element 2550R and a transistor 2502t that can supply electric power to the light-emitting element 2550R. Note that the transistor 2502t functions as part of the pixel circuit. The light-emitting module 2580 includes the light-emitting element 2550R and a coloring layer 2567R.

The light-emitting element 2550 includes a lower electrode, an upper electrode, and an EL layer between the lower electrode and the upper electrode. As the light-emitting element 2550, the light-emitting element 100 described in Embodiment 1 can be used, for example. Note that although only one light-emitting element 2550 is illustrated in FIG. 10A, it is possible to employ the structure including two or more light-emitting elements.

In the case where the sealing layer 2560 is provided on the light extraction side, the sealing layer 2560 is in contact with the light-emitting element 2550 and the coloring layer 2567R.

The coloring layer 2567R is positioned in a region overlapping with the light-emitting element 2550. Accordingly, part of light emitted from the light-emitting element 2550 passes through the coloring layer 2567R and is emitted to the outside of the light-emitting module 2580 as indicated by an arrow in FIG. 10A.

The display panel 2501 includes a light-blocking layer 2567BM on the light extraction side. The light-blocking layer 2567BM is provided so as to surround the coloring layer 2567R.

The coloring layer 2567R is a coloring layer having a function of transmitting light in a particular wavelength region. For example, a color filter for transmitting light in a red wavelength range, a color filter for transmitting light in a green wavelength range, a color filter for transmitting light in a blue wavelength range, a color filter for transmitting light in a yellow wavelength range, or the like can be used. Each color filter can be formed with any of various materials by a printing method, an inkjet method, an etching method using a photolithography technique, or the like.

An insulating layer 2521 is provided in the display panel 2501. The insulating layer 2521 covers the transistor 2502t. Note that the insulating layer 2521 has a function of covering unevenness caused by the pixel circuit to provide a flat surface. The insulating layer 2521 may have a function of suppressing impurity diffusion. This can prevent the reliability of the transistor 2502t or the like from being lowered by impurity diffusion.

The light-emitting element 2550R is formed over the insulating layer 2521. A partition 2528 is provided so as to overlap with an end portion of the lower electrode of the light-emitting element 2550R. Note that a spacer for controlling the distance between the substrate 2510 and the substrate 2570 may be formed over the partition 2528.

A scan line driver circuit 2503g includes a transistor 2503t and a capacitor 2503c. Note that the driver circuit can be formed in the same process and over the same substrate as those of the pixel circuits.

The wirings 2511 through which signals can be supplied are provided over the substrate 2510. The terminal 2519 is provided over the wirings 2511. The FPC 2509(1) is electrically connected to the terminal 2519. The FPC 2509(1) has a function of supplying a video signal, a clock signal, a start signal, a reset signal, or the like. Note that the FPC 2509(1) may be provided with a PWB.

In the display panel 2501, transistors with any of a variety of structures can be used. FIG. 10A illustrates an example of using bottom-gate transistors; however, the present invention is not limited to this example, and top-gate transistors may be used in the display panel 2501 as illustrated in FIG. 10B.

In addition, there is no particular limitation on the polarity of the transistor 2502t and the transistor 2503t. For these transistors, n-channel and p-channel transistors may be used, or either n-channel transistors or p-channel transistors may be used, for example. Furthermore, there is no particular limitation on the crystallinity of a semiconductor film used for the transistors 2502t and 2503t. For example, an amorphous semiconductor film or a crystalline semiconductor film may be used. Examples of semiconductor materials include Group 13 semiconductors (e.g., a semiconductor including gallium), Group 14 semiconductors (e.g., a semiconductor including silicon), compound semiconductors (including oxide semiconductors), organic semiconductors, and the like. An oxide semiconductor that has an energy gap of 2 eV or more, preferably 2.5 eV or more, further preferably 3 eV or more is preferably used for one of the transistors 2502t and 2503t or both, so that the off-state current of the transistors can be reduced. Examples of the oxide semiconductors include an In—Ga oxide, an In-M-Zn oxide (M represents Al, Ga, Y, Zr, La, Ce, Sn, or Nd), and the like.

### <Touch Sensor>

Next, the touch sensor 2595 will be described in detail with reference to FIG. 10C. FIG. 10C corresponds to a cross-sectional view taken along dashed-dotted line X3-X4 in FIG. 9B.

The touch sensor 2595 includes the electrodes 2591 and the electrodes 2592 provided in a staggered arrangement on the substrate 2590, an insulating layer 2593 covering the electrodes 2591 and the electrodes 2592, and the wiring 2594 that electrically connects the adjacent electrodes 2591 to each other.

The electrodes 2591 and the electrodes 2592 are formed using a light-transmitting conductive material. As a light-transmitting conductive material, a conductive oxide such as indium oxide, indium tin oxide, indium zinc oxide, zinc oxide, or zinc oxide to which gallium is added can be used. Note that a film including graphene may be used as well. The film including graphene can be formed, for example, by reducing a film containing graphene oxide. As a reducing method, a method with application of heat or the like can be employed.

The electrodes 2591 and the electrodes 2592 may be formed by, for example, depositing a light-transmitting conductive material on the substrate 2590 by a sputtering method and then removing an unnecessary portion by any of various patterning techniques such as photolithography.

Examples of a material for the insulating layer 2593 are a resin such as an acrylic resin or an epoxy resin, a resin having a siloxane bond, and an inorganic insulating material such as silicon oxide, silicon oxynitride, or aluminum oxide.

Openings reaching the electrodes 2591 are formed in the insulating layer 2593, and the wiring 2594 electrically connects the adjacent electrodes 2591. A light-transmitting conductive material can be favorably used as the wiring 2594 because the aperture ratio of the touch panel can be increased. Moreover, a material with conductivity higher than the conductivities of the electrodes 2591 and 2592 can be favorably used for the wiring 2594 because electric resistance can be reduced.

One electrode 2592 extends in one direction, and the plurality of electrodes 2592 are provided in the form of stripes. The wiring 2594 intersects with the electrode 2592.

Adjacent electrodes 2591 are provided with one electrode 2592 provided therebetween. The wiring 2594 electrically connects the adjacent electrodes 2591.

Note that the plurality of electrodes 2591 are not necessarily arranged in the direction orthogonal to one electrode 2592 and may be arranged to intersect with one electrode 2592 at an angle of more than 0 degrees and less than 90 degrees.

The wiring 2598 is electrically connected to any of the electrodes 2591 and 2592. Part of the wiring 2598 functions as a terminal. For the wiring 2598, a metal material such as aluminum, gold, platinum, silver, nickel, titanium, tungsten, chromium, molybdenum, iron, cobalt, copper, or palladium or an alloy material containing any of these metal materials can be used.

Note that an insulating layer that covers the insulating layer 2593 and the wiring 2594 may be provided to protect the touch sensor 2595.

A connection layer 2599 electrically connects the wiring 2598 to the FPC 2509(2).

As the connection layer 2599, any of various anisotropic conductive films (ACF), anisotropic conductive pastes (ACP), or the like can be used.

### <Description 2 of Touch Panel>

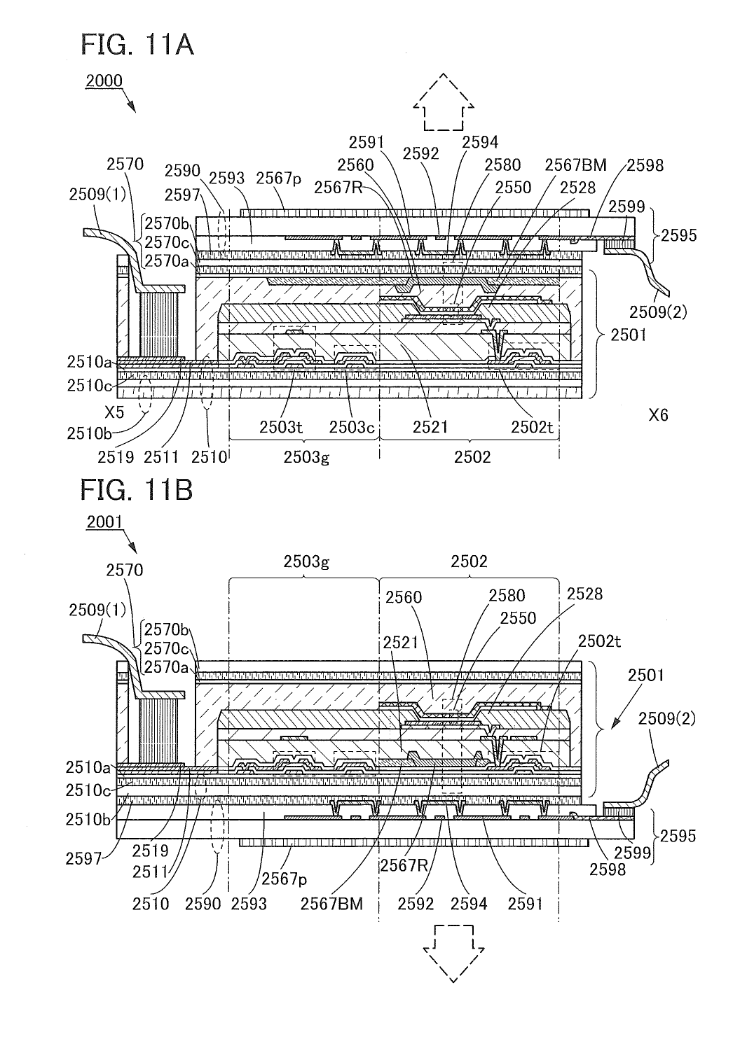

Next, the touch panel 2000 will be described in detail with reference to FIG. 11A. FIG. 11A corresponds to a cross-sectional view taken along dashed-dotted line X5-X6 in FIG. 9A.

In the touch panel 2000 illustrated in FIG. 11A, the display panel 2501 described with reference to FIG. 10A and the touch sensor 2595 described with reference to FIG. 10C are attached to each other.

The touch panel 2000 illustrated in FIG. 11A includes an adhesive layer 2597 and an anti-reflective layer 2567p in addition to the components described with reference to FIGS. 10A and 10C.

The adhesive layer 2597 is provided in contact with the wiring 2594. Note that the adhesive layer 2597 attaches the substrate 2590 to the substrate 2570 so that the touch sensor 2595 overlaps with the display panel 2501. The adhesive layer 2597 preferably has a light-transmitting property. A heat curable resin or an ultraviolet curable resin can be used for the adhesive layer 2597. For example, an acrylic resin, a urethane-based resin, an epoxy-based resin, or a siloxane-based resin can be used.

The anti-reflective layer 2567p is positioned in a region overlapping with pixels. As the anti-reflective layer 2567p, a circularly polarizing plate can be used, for example.

Next, a touch panel having a structure different from that illustrated in FIG. 11A will be described with reference to FIG. 11B.

FIG. 11B is a cross-sectional view of a touch panel 2001. The touch panel 2001 illustrated in FIG. 11B differs from the touch panel 2000 illustrated in FIG. 11A in the position of the touch sensor 2595 relative to the display panel 2501. Different parts are described in detail below, and the above description of the touch panel 2000 is referred to for the other similar parts.

The coloring layer 2567R is positioned in a region overlapping with the light-emitting element 2550R. The light-emitting element 2550R illustrated in FIG. 11B emits light to the side where the transistor 2502t is provided. Accordingly, part of light emitted from the light-emitting element 2550R passes through the coloring layer 2567R and is emitted to the outside of the light-emitting module 2580 as indicated by an arrow in FIG. 11B.

The touch sensor 2595 is provided on the substrate 2510 side of the display panel 2501.

The adhesive layer 2597 is provided between the substrate 2510 and the substrate 2590 and attaches the touch sensor 2595 to the display panel 2501.

As illustrated in FIG. 11A or 11B, light may be emitted from the light-emitting element to one of upper and lower sides, or both, of the substrate.

### <Method for Driving Touch Panel>

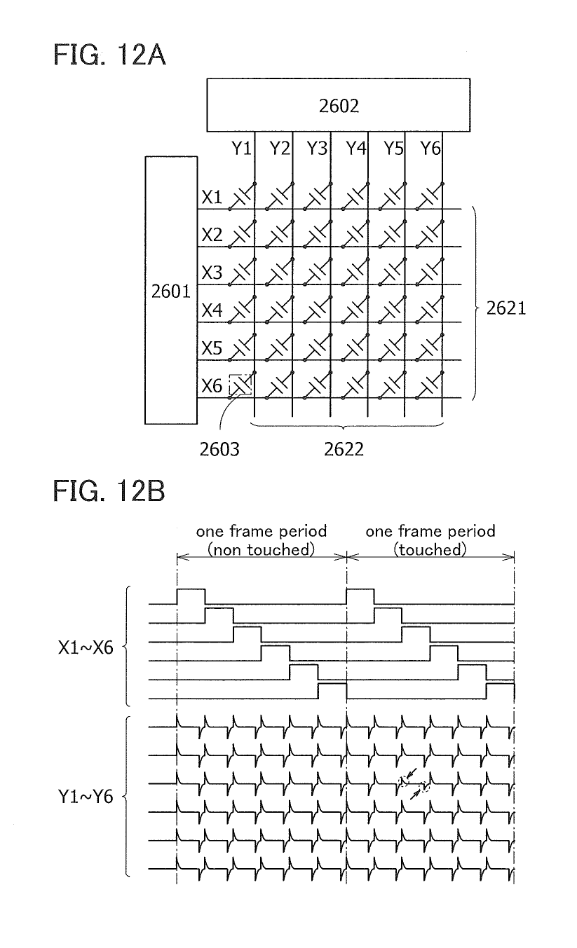

Next, an example of a method for driving a touch panel will be described with reference to FIGS. 12A and 12B.

FIG. 12A is a block diagram illustrating the structure of a mutual capacitive touch sensor. FIG. 12A illustrates a pulse voltage output circuit 2601 and a current sensing circuit 2602. Note that in FIG. 12A, six wirings X1 to X6 represent the electrodes 2621 to which a pulse voltage is applied, and six wirings Y1 to Y6 represent the electrodes 2622 that detect changes in current. FIG. 12A also illustrates capacitors 2603 that are each formed in a region where the electrodes 2621 and 2622 overlap with each other. Note that functional replacement between the electrodes 2621 and 2622 is possible.

The pulse voltage output circuit 2601 is a circuit for sequentially applying a pulse voltage to the wirings X1 to X6. By application of a pulse voltage to the wirings X1 to X6, an electric field is generated between the electrodes 2621 and 2622 of the capacitor 2603. When the electric field between the electrodes is shielded, for example, a change occurs in the capacitor 2603 (mutual capacitance). The approach or contact of a sensing target can be sensed by utilizing this change.

The current sensing circuit 2602 is a circuit for detecting changes in current flowing through the wirings Y1 to Y6 that are caused by the change in mutual capacitance in the capacitor 2603. No change in current value is detected in the wirings Y1 to Y6 when there is no approach or contact of a sensing target, whereas a decrease in current value is detected when mutual capacitance is decreased owing to the approach or contact of a sensing target. Note that an integrator circuit or the like is used for sensing of current values.

FIG. 12B is a timing chart showing input and output waveforms in the mutual capacitive touch sensor illustrated in FIG. 12A. In FIG. 12B, sensing of a sensing target is performed in all the rows and columns in one frame period. FIG. 12B shows a period when a sensing target is not sensed (not touched) and a period when a sensing target is sensed (touched). Sensed current values of the wirings Y1 to Y6 are shown as the waveforms of voltage values.

A pulse voltage is sequentially applied to the wirings X1 to X6, and the waveforms of the wirings Y1 to Y6 change in accordance with the pulse voltage. When there is no approach or contact of a sensing target, the waveforms of the wirings Y1 to Y6 change in accordance with changes in the voltages of the wirings X1 to X6. The current value is decreased at the point of approach or contact of a sensing target and accordingly the waveform of the voltage value changes.

By detecting a change in mutual capacitance in this manner, the approach or contact of a sensing target can be sensed.

### <Sensor Circuit>

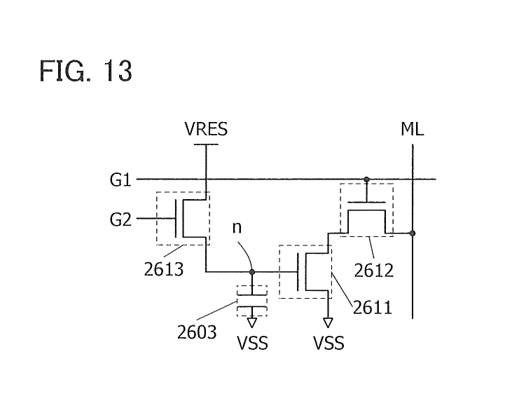

Although FIG. 12A illustrates a passive type touch sensor in which only the capacitor 2603 is provided at the intersection of wirings as a touch sensor, an active type touch sensor including a transistor and a capacitor may be used. FIG. 13 illustrates an example of a sensor circuit included in an active type touch sensor.

The sensor circuit in FIG. 13 includes the capacitor 2603 and transistors 2611, 2612, and 2613.

A signal G2 is input to a gate of the transistor 2613. A voltage VRES is applied to one of a source and a drain of the transistor 2613, and one electrode of the capacitor 2603 and a gate of the transistor 2611 are electrically connected to the other of the source and the drain of the transistor 2613. One of a source and a drain of the transistor 2611 is electrically connected to one of a source and a drain of the transistor 2612, and a voltage VSS is applied to the other of the source and the drain of the transistor 2611. A signal G1 is input to a gate of the transistor 2612, and a wiring ML is electrically connected to the other of the source and the drain of the transistor 2612. The voltage VSS is applied to the other electrode of the capacitor 2603.

Next, the operation of the sensor circuit in FIG. 13 will be described. First, a potential for turning on the transistor 2613 is supplied as the signal G2, and a potential with respect to the voltage VRES is thus applied to the node n connected to the gate of the transistor 2611. Then, a potential for turning off the transistor 2613 is applied as the signal G2, whereby the potential of the node n is maintained.

Then, mutual capacitance of the capacitor 2603 changes owing to the approach or contact of a sensing target such as a finger, and accordingly the potential of the node n is changed from VRES.

In reading operation, a potential for turning on the transistor 2612 is supplied as the signal G1. A current flowing through the transistor 2611, that is, a current flowing through the wiring ML is changed in accordance with the potential of the node n. By sensing this current, the approach or contact of a sensing target can be sensed.

In each of the transistors 2611, 2612, and 2613, an oxide semiconductor layer is preferably used as a semiconductor layer in which a channel region is formed. In particular, such a transistor is preferably used as the transistor 2613 so that the potential of the node n can be held for a long time and the frequency of operation of resupplying VRES to the node n (refresh operation) can be reduced.

The structure described in this embodiment can be combined with any of the structures described in the other embodiments as appropriate.

### Embodiment 5

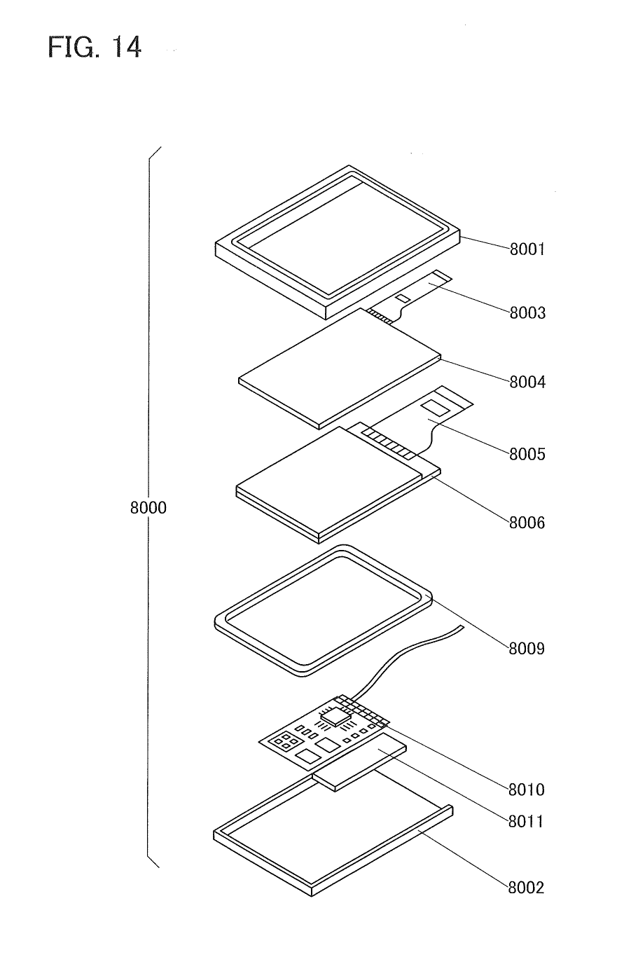

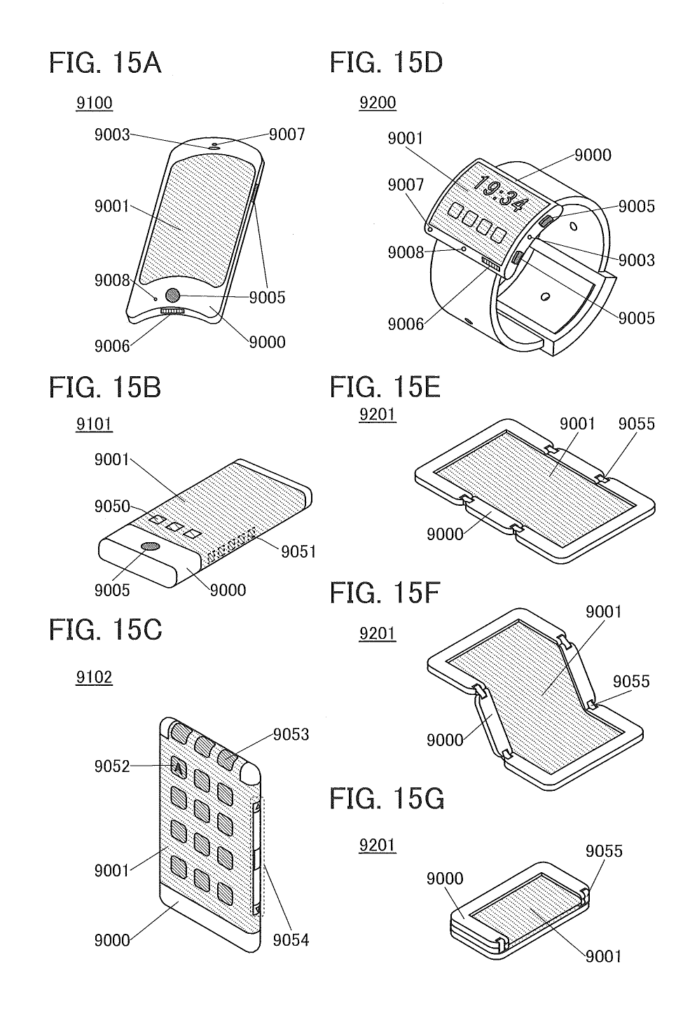

In this embodiment, a display module and electronic devices including a light-emitting device of one embodiment of the present invention will be described with reference to FIG. 14 and FIGS. 15A to 15G.

In a display module 8000 in FIG. 14, a touch sensor 8004 connected to an FPC 8003, a display panel 8006 connected to an FPC 8005, a frame 8009, a printed circuit board 8010, and a battery 8011 are provided between an upper cover 8001 and a lower cover 8002.

The light-emitting device of one embodiment of the present invention can be used for the display panel 8006, for example.

The shapes and sizes of the upper cover 8001 and the lower cover 8002 can be changed as appropriate in accordance with the sizes of the touch sensor 8004 and the display panel 8006.

The touch sensor 8004 can be a resistive touch panel or a capacitive touch panel and may be formed to overlap with the display panel 8006. A counter substrate (sealing substrate) of the display panel 8006 can have a touch sensor function. A photosensor may be provided in each pixel of the display panel 8006 so that an optical touch sensor is obtained.

The frame 8009 protects the display panel 8006 and also serves as an electromagnetic shield for blocking electromagnetic waves generated by the operation of the printed circuit board 8010. The frame 8009 may serve as a radiator plate.

The printed circuit board 8010 has a power supply circuit and a signal processing circuit for outputting a video signal and a clock signal. As a power source for supplying power to the power supply circuit, an external commercial power source or the battery 8011 provided separately may be used. The battery 8011 can be omitted in the case of using a commercial power source.

The display module 8000 can be additionally provided with a member such as a polarizing plate, a retardation plate, or a prism sheet.

FIGS. 15A to 15G illustrate electronic devices. These electronic devices can include a housing 9000, a display portion 9001, a speaker 9003, operation keys 9005, a connection terminal 9006, a sensor 9007, a microphone 9008, and the like.

The electronic devices illustrated in FIGS. 15A to 15G can have a variety of functions, for example, a function of displaying a variety of data (a still image, a moving image, a text image, and the like) on the display portion, a touch sensor function, a function of displaying a calendar, date, time, and the like, a function of controlling a process with a variety of software (programs), a wireless communication function, a function of being connected to a variety of computer networks with a wireless communication function, a function of transmitting and receiving a variety of data with a wireless communication function, a function of reading a program or data stored in a memory medium and displaying the program or data on the display portion, and the like. Note that functions that can be provided for the electronic devices illustrated in FIGS. 15A to 15G are not limited to those described above, and the electronic devices can have a variety of functions. Although not illustrated in FIGS. 15A to 15G, the electronic devices may include a plurality of display portions. The electronic devices may have a camera or the like and a function of taking a still image, a function of taking a moving image, a function of storing the taken image in a memory medium (an external memory medium or a memory medium incorporated in the camera), a function of displaying the taken image on the display portion, or the like.

The electronic devices illustrated in FIGS. 15A to 15G will be described in detail below.

FIG. 15A is a perspective view of a portable information terminal 9100. The display portion 9001 of the portable information terminal 9100 is flexible. Therefore, the display portion 9001 can be incorporated along a bent surface of a bent housing 9000. In addition, the display portion 9001 includes a touch sensor, and operation can be performed by touching the screen with a finger, a stylus, or the like. For example, when an icon displayed on the display portion 9001 is touched, an application can be started.

FIG. 15B is a perspective view of a portable information terminal 9101. The portable information terminal 9101 functions as, for example, one or more of a telephone set, a notebook, and an information browsing system. Specifically, the portable information terminal can be used as a smartphone. Note that the speaker 9003, the connection terminal 9006, the sensor 9007, and the like, which are not shown in FIG. 15B, can be positioned in the portable information terminal 9101 as in the portable information terminal 9100 shown in FIG. 15A. The portable information terminal 9101 can display characters and image information on its plurality of surfaces. For example, three operation buttons 9050 (also referred to as operation icons, or simply, icons) can be displayed on one surface of the display portion 9001. Furthermore, information 9051 indicated by dashed rectangles can be displayed on another surface of the display portion 9001. Examples of the information 9051 include display indicating reception of an incoming email, social networking service (SNS) message, call, and the like; the title and sender of an email and SNS message; the date; the time; remaining battery; and the strength of a received signal. Instead of the information 9051, the operation buttons 9050 or the like may be displayed on the position where the information 9051 is displayed.

FIG. 15C is a perspective view of a portable information terminal 9102. The portable information terminal 9102 has a function of displaying information on three or more surfaces of the display portion 9001. Here, information 9052, information 9053, and information 9054 are displayed on different surfaces. For example, a user of the portable information terminal 9102 can see the display (here, the information 9053 ) with the portable information terminal 9102 put in a breast pocket of his/her clothes. Specifically, a caller's phone number, name, or the like of an incoming call is displayed in a position that can be seen from above the portable information terminal 9102. Thus, the user can see the display without taking out the portable information terminal 9102 from the pocket and decide whether to answer the call.

FIG. 15D is a perspective view of a watch-type portable information terminal 9200. The portable information terminal 9200 is capable of executing a variety of applications such as mobile phone calls, e-mailing, viewing and editing texts, music reproduction, Internet communication, and computer games. The display surface of the display portion 9001 is bent, and images can be displayed on the bent display surface. The portable information terminal 9200 can employ near field communication conformable to a communication standard. In that case, for example, mutual communication between the portable information terminal 9200 and a headset capable of wireless communication can be performed, and thus hands-free calling is possible. The portable information terminal 9200 includes the connection terminal 9006, and data can be directly transmitted to and received from another information terminal via a connector. Power charging through the connection terminal 9006 is possible. Note that the charging operation may be performed by wireless power feeding without using the connection terminal 9006.

FIGS. 15E, 15F, and 15G are perspective views of a foldable portable information terminal 9201. FIG. 15E is a perspective view illustrating the portable information terminal 9201 that is opened. FIG. 15F is a perspective view illustrating the portable information terminal 9201 that is being opened or being folded. FIG. 15G is a perspective view illustrating the portable information terminal 9201 that is folded. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. By folding the portable information terminal 9201 at a connection portion between two housings 9000 with the hinges 9055, the portable information terminal 9201 can be reversibly changed in shape from an opened state to a folded state. For example, the portable information terminal 9201 can be bent with a radius of curvature of greater than or equal to 1 mm and less than or equal to 150 mm.

The electronic devices described in this embodiment each include the display portion for displaying some sort of data. Note that the light-emitting device of one embodiment of the present invention can also be used for an electronic device which does not have a display portion. The structure in which the display portion of the electronic device described in this embodiment is flexible and display can be performed on the bent display surface or the structure in which the display portion of the electronic device is foldable is described as an example; however, the structure is not limited thereto and a structure in which the display portion of the electronic device is not flexible and display is performed on a plane portion may be employed.

The structure described in this embodiment can be combined with any of the structures described in the other embodiments as appropriate.

### Embodiment 6

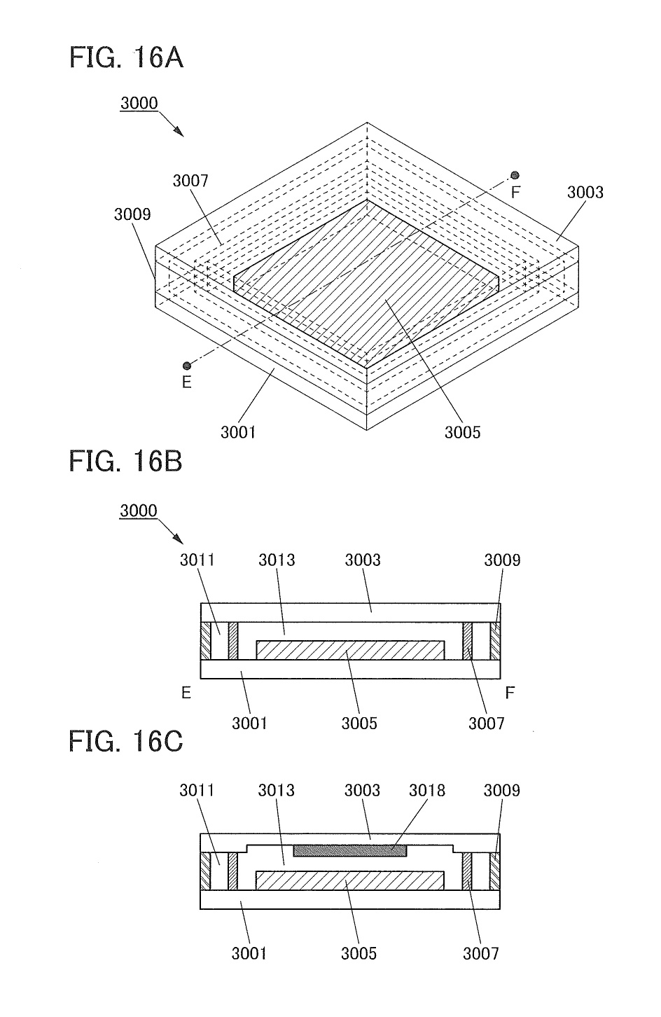

In this embodiment, the light-emitting device of one embodiment of the present invention will be described with reference to FIGS. 16A to 16C.

FIG. 16A is a perspective view of a light-emitting device 3000 shown in this embodiment, and FIG. 16B is a cross-sectional view along dashed-dotted line E-F in FIG. 16A. Note that in FIG. 16A, some components are illustrated by broken lines in order to avoid complexity of the drawing.

The light-emitting device 3000 illustrated in FIGS. 16A and 16B includes a substrate 3001, a light-emitting element 3005 over the substrate 3001, a first sealing region 3007 provided around the light-emitting element 3005, and a second sealing region 3009 provided around the first sealing region 3007.

Light is emitted from the light-emitting element 3005 through one or both of the substrate 3001 and a substrate 3003. In FIGS. 16A and 16B, a structure in which light is emitted from the light-emitting element 3005 to the lower side (the substrate 3001 side) is illustrated.

As illustrated in FIGS. 16A and 16B, the light-emitting device 3000 has a double sealing structure in which the light-emitting element 3005 is surrounded by the first sealing region 3007 and the second sealing region 3009. With the double sealing structure, entry of impurities (e.g., water, oxygen, and the like) from the outside into the light-emitting element 3005 can be favorably suppressed. Note that it is not necessary to provide both the first sealing region 3007 and the second sealing region 3009. For example, only the first sealing region 3007 may be provided.

Note that in FIG. 16B, the first sealing region 3007 and the second sealing region 3009 are each provided in contact with the substrate 3001 and the substrate 3003. However, without limitation to such a structure, for example, one or both of the first sealing region 3007 and the second sealing region 3009 may be provided in contact with an insulating film or a conductive film provided on the substrate 3001. Alternatively, one or both of the first sealing region 3007 and the second sealing region 3009 may be provided in contact with an insulating film or a conductive film provided on the substrate 3003.

The substrate 3001 and the substrate 3003 can have structures similar to those of the substrate 102 and the substrate 152 described in Embodiment 1, respectively. The light-emitting element 3005 can have a structure similar to that of the light-emitting elements described in the above embodiments.

For the first sealing region 3007, a material containing glass (e.g., a glass frit, a glass ribbon, and the like) can be used. For the second sealing region 3009, a material containing a resin can be used. With the use of the material containing glass for the first sealing region 3007, productivity and a sealing property can be improved. Moreover, with the use of the material containing a resin for the second sealing region 3009, impact resistance and heat resistance can be improved. However, the materials used for the first sealing region 3007 and the second sealing region 3009 are not limited to such, and the first sealing region 3007 may be formed using the material containing a resin and the second sealing region 3009 may be formed using the material containing glass.

The glass frit may contain, for example, magnesium oxide, calcium oxide, strontium oxide, barium oxide, cesium oxide, sodium oxide, potassium oxide, boron oxide, vanadium oxide, zinc oxide, tellurium oxide, aluminum oxide, silicon dioxide, lead oxide, tin oxide, phosphorus oxide, ruthenium oxide, rhodium oxide, iron oxide, copper oxide, manganese dioxide, molybdenum oxide, niobium oxide, titanium oxide, tungsten oxide, bismuth oxide, zirconium oxide, lithium oxide, antimony oxide, lead borate glass, tin phosphate glass, vanadate glass, or borosilicate glass. The glass frit preferably contains at least one kind of transition metal to absorb infrared light.

As the above glass frits, for example, a fit paste is applied to a substrate and is subjected to heat treatment, laser light irradiation, or the like. The frit paste contains the glass frit and a resin (also referred to as a binder) diluted by an organic solvent. Note that an absorber which absorbs light having the wavelength of laser light may be added to the glass fit. For example, an Nd:YAG laser or a semiconductor laser is preferably used as the laser. The shape of laser light may be circular or quadrangular.

As the above material containing a resin, for example, materials that include polyester, polyolefin, polyamide (e.g., nylon, aramid), polyimide, polycarbonate, polyurethane, an acrylic resin, an epoxy resin, or a resin having a siloxane bond can be used.

Note that in the case where the material containing glass is used for one or both of the first sealing region 3007 and the second sealing region 3009, the material containing glass preferably has a thermal expansion coefficient close to that of the substrate 3001. With the above structure, generation of a crack in the material containing glass or the substrate 3001 due to thermal stress can be suppressed.

For example, the following advantageous effect can be obtained in the case where the material containing glass is used for the first sealing region 3007 and the material containing a resin is used for the second sealing region 3009.

The second sealing region 3009 is provided closer to an outer portion of the light-emitting device 3000 than the first sealing region 3007 is. In the light-emitting device 3000, distortion due to external force or the like increases toward the outer portion. Thus, the outer portion of the light-emitting device 3000 where a larger amount of distortion is generated, that is, the second sealing region 3009 is sealed using the material containing a resin and the first sealing region 3007 provided on an inner side of the second region 3009 is sealed using the material containing glass, whereby the light-emitting device 3000 is less likely to be damaged even when distortion due to external force or the like is generated.

Furthermore, as illustrated in FIG. 16B, a first region 3011 corresponds to the region surrounded by the substrate 3001, the substrate 3003, the first sealing region 3007, and the second sealing region 3009. A second region 3013 corresponds to the region surrounded by the substrate 3001, the substrate 3003, the light-emitting element 3005, and the first sealing region 3007.

The first region 3011 and the second region 3013 are preferably filled with, for example, an inert gas such as a rare gas or a nitrogen gas. Note that for the first region 3011 and the second region 3013, a reduced pressure state is preferred to an atmospheric pressure state.

FIG. 16C illustrates a modification example of the structure in FIG. 16B. FIG. 16C is a cross-sectional view illustrating the modification example of the light-emitting device 3000.

FIG. 16C illustrates a structure in which a desiccant 3018 is provided in a recessed portion provided in part of the substrate 3003. The other components are the same as those of the structure illustrated in FIG. 16B.

As the desiccant 3018, a substance which adsorbs moisture and the like by chemical adsorption or a substance which adsorbs moisture and the like by physical adsorption can be used. Examples of the substance that can be used as the desiccant 3018 include alkali metal oxides, alkaline earth metal oxide (e.g., calcium oxide, barium oxide, and the like), sulfate, metal halides, perchlorate, zeolite, silica gel, and the like.

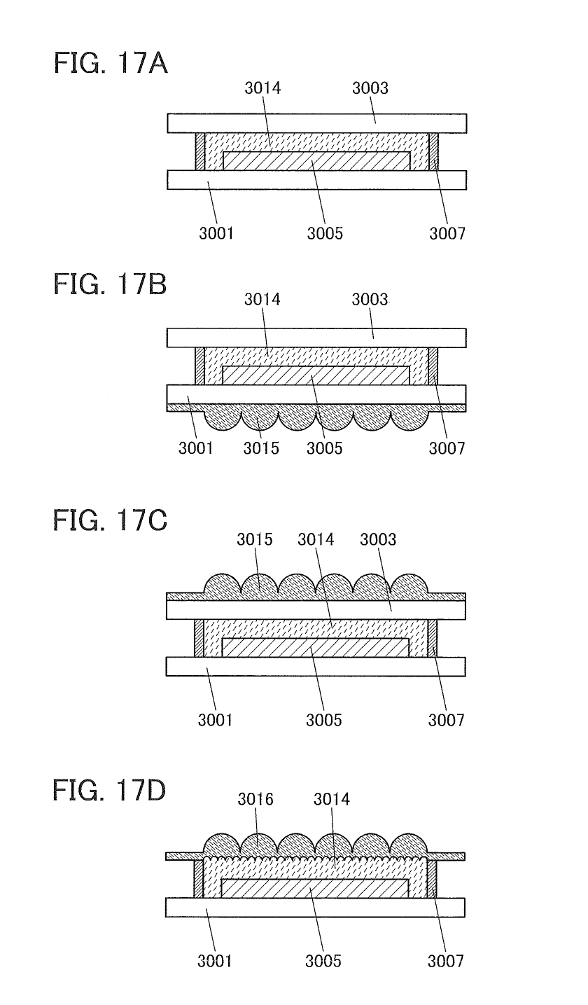

Next, modification examples of the light-emitting device 3000 which is illustrated in FIG. 16B are described with reference to FIGS. 17A to 17D. Note that FIGS. 17A to 17D are cross-sectional views illustrating the modification examples of the light-emitting device 3000 illustrated in FIG. 16B.

In the light-emitting device illustrated in FIG. 17A, the second sealing region 3009 is not provided but only the first sealing region 3007 is provided. Moreover, in the light-emitting device illustrated in FIG. 17A, a region 3014 is provided instead of the second region 3013 illustrated in FIG. 16B.

For the region 3014, for example, materials that include polyester, polyolefin, polyamide (e.g., nylon or aramid), polyimide, polycarbonate, polyurethane, an acrylic resin, an epoxy resin, or a resin having a siloxane bond can be used.

When the above-described material is used for the region 3014, what is called a solid-sealing light-emitting device can be obtained.

In the light-emitting device illustrated in FIG. 17B, a substrate 3015 is provided on the substrate 3001 side of the light-emitting device illustrated in FIG. 17A.

The substrate 3015 has unevenness as illustrated in FIG. 17B. With a structure in which the substrate 3015 having unevenness is provided on the side through which light emitted from the light-emitting element 3005 is extracted, the efficiency of extraction of light from the light-emitting element 3005 can be improved. Note that instead of the structure having unevenness and illustrated in FIG. 17B, a substrate having a function as a diffusion plate may be provided.

In the light-emitting device illustrated in FIG. 17C, light is extracted through the substrate 3003 side, unlike in the light-emitting device illustrated in FIG. 17A, in which light is extracted through the substrate 3001 side.

The light-emitting device illustrated in FIG. 17C includes the substrate 3015 on the substrate 3003 side. The other components are the same as those of the light-emitting device illustrated in FIG. 17B.

In the light-emitting device illustrated in FIG. 17D, the substrate 3003 and the substrate 3015 included in the light-emitting device illustrated in FIG. 17C are not provided but a substrate 3016 is provided.

The substrate 3016 includes first unevenness positioned closer to the light-emitting element 3005 and second unevenness positioned farther from the light-emitting element 3005. With the structure illustrated in FIG. 17D, the efficiency of extraction of light from the light-emitting element 3005 can be further improved.

Thus, the use of the structure described in this embodiment can provide a light-emitting device in which deterioration of a light-emitting element due to impurities such as moisture and oxygen is suppressed. Alternatively, with the structure described in this embodiment, a light-emitting device having high light extraction efficiency can be obtained.

The structure described in this embodiment can be combined with any of the structures described in the other embodiments and examples as appropriate.

### Embodiment 7

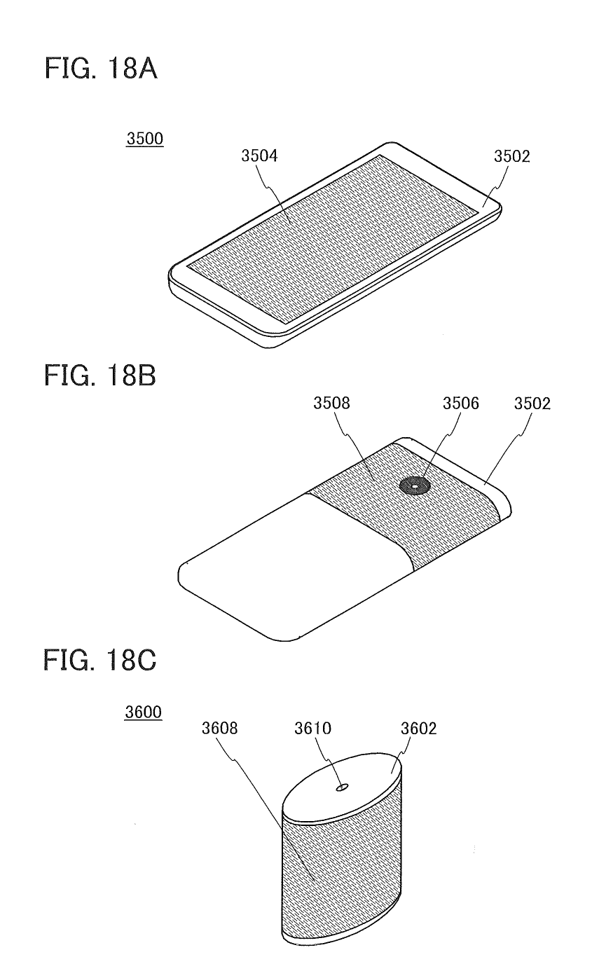

In this embodiment, examples in which the light-emitting device of one embodiment of the present invention is applied to various lighting devices and electronic devices will be described with reference to FIGS. 18A to 18C.

An electronic device or a lighting device that has a light-emitting region with a curved surface can be obtained with the use of the light-emitting device of one embodiment of the present invention which is manufactured over a substrate having flexibility.

Furthermore, a light-emitting device to which one embodiment of the present invention is applied can also be applied to lighting for motor vehicles, examples of which are lighting for a dashboard, a windshield, a ceiling, and the like.

FIG. 18A is a perspective view illustrating one surface of a multifunction terminal 3500, and FIG. 18B is a perspective view illustrating the other surface of the multifunction terminal 3500. In a housing 3502 of the multifunction terminal 3500, a display portion 3504, a camera 3506, lighting 3508, and the like are incorporated. The light-emitting device of one embodiment of the present invention can be used for the lighting 3508.

The lighting 3508 that includes the light-emitting device of one embodiment of the present invention functions as a planar light source. Thus, unlike a point light source typified by an LED, the lighting 3508 can provide light emission with low directivity. When the lighting 3508 and the camera 3506 are used in combination, for example, imaging can be performed by the camera 3506 with the lighting 3508 lighting or flashing. Because the lighting 3508 functions as a planar light source, a photograph as if taken under natural light can be taken.

Note that the multifunction terminal 3500 illustrated in FIGS. 18A and 18 B can have a variety of functions as in the electronic devices illustrated in FIGS. 15A to 15G.

The housing 3502 can include a speaker, a sensor (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone, and the like. When a detection device including a sensor for detecting inclination, such as a gyroscope or an acceleration sensor, is provided inside the multifunction terminal 3500, display on the screen of the display portion 3504 can be automatically switched by determining the orientation of the multifunction terminal 3500 (whether the multifunction terminal is placed horizontally or vertically for a landscape mode or a portrait mode).

The display portion 3504 may function as an image sensor. For example, an image of a palm print, a fingerprint, or the like is taken when the display portion 3504 is touched with the palm or the finger, whereby personal authentication can be performed. Furthermore, by providing a backlight or a sensing light source which emits near-infrared light in the display portion 3504, an image of a finger vein, a palm vein, or the like can be taken. Note that the light-emitting device of one embodiment of the present invention may be used for the display portion 3504.

FIG. 18C is a perspective view of a security light 3600. The security light 3600 includes lighting 3608 on the outside of the housing 3602, and a speaker 3610 and the like are incorporated in the housing 3602. The light-emitting device of one embodiment of the present invention can be used for the lighting 3608.

The security light 3600 emits light when the lighting 3608 is gripped or held, for example. An electronic circuit that can control the manner of light emission from the security light 3600 may be provided in the housing 3602. The electronic circuit may be a circuit that enables light emission once or intermittently plural times or may be a circuit that can adjust the amount of emitted light by controlling the current value for light emission. A circuit with which a loud audible alarm is output from the speaker 3610 at the same time as light emission from the lighting 3608 may be incorporated.

The security light 3600 can emit light in various directions; therefore, it is possible to intimidate a thug or the like with light, or light and sound. Moreover, the security light 3600 may include a camera such as a digital still camera to have a photography function.

As described above, lighting devices and electronic devices can be obtained by application of the light-emitting device of one embodiment of the present invention. Note that the light-emitting device can be used for lighting devices and electronic devices in a variety of fields without being limited to the lighting devices and the electronic devices described in this embodiment.

The structure described in this embodiment can be combined with any of the structures described in the other embodiments and examples as appropriate.

### EXAMPLE 1

In this example, an example of fabricating a light-emitting element of one embodiment of the present invention will be described. Note that in this example, light-emitting elements that were embodiments of the present invention (Light-emitting Element 1 and Light-emitting Element 2) and a comparative light-emitting element (Light-emitting Element 3) were fabricated.

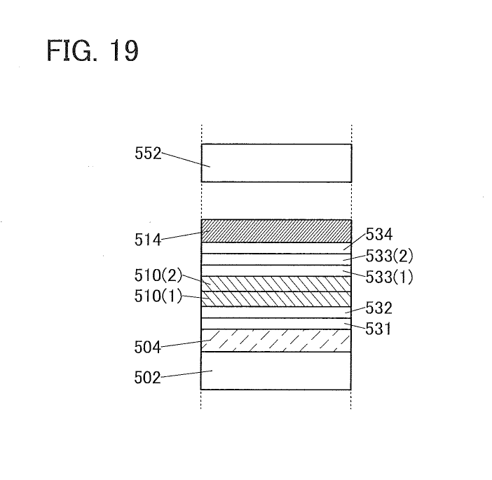

A schematic cross-sectional view of Light-emitting Elements 1 to 3 is shown in FIG. 19, details about element structures of Light-emitting Elements 1 to 3 are shown in Table 4, and structures and abbreviations of compounds that were used are shown below. Note that materials similar to the compounds described in Embodiment 1 were used as compounds other than those shown below.

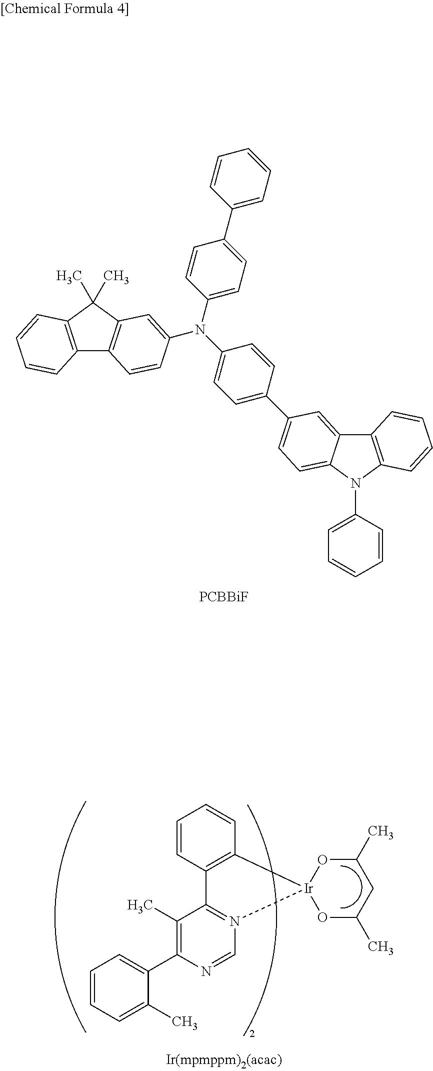

TABLE 4

| | | Reference | Thickness | | |
|---|---|---|---|---|---|
| | Layer | numeral | (nm) | Material | Weight ratio |
| Light- | Upper electrode | 514 | 200 | Al | — |
| emitting | Electron- | 534 | 1 | LiF | — |
| element 1 | injection layer | | | | |
| | Electron- | 533(2) | 10 | Bphen | — |
| | transport layer | 533(1) | 20 | 2mDBTBPDBq-II | — |
| | Light-emitting | 510(2) | 20 | 2mDBTBPDBq-II:PCBBiF:Ir | 0.8:0.2:0.05 |
| | layer | | | (mpmppm)₂(acac)*¹ | |
| | | 510(1) | 20 | 2mDBTBPDBq-II:PCBBiF:Ir | 0.7:0.3:0.05 |
| | | | | (mpmppm)₂(acac)*¹ | |
| | Hole-transport | 532 | 20 | BPAFLP | — |
| | layer | | | | |
| | Hole-injection | 531 | 20 | DBT3P-II:MoOₓ | 2:1 |
| | layer | | | | |
| | Lower electrode | 504 | 100 | ITSO | — |
| Light- | Upper electrode | 514 | 200 | Al | — |
| emitting | Electron- | 534 | 1 | LiF | — |
| element 2 | injection layer | | | | |
| | Electron- | 533(2) | 10 | Bphen | — |
| | transport layer | 533(1) | 20 | 2mDBTBPDBq-II | — |
| | Light-emitting | 510(2) | 20 | 2mDBTBPDBq-II:PCBBiF:Ir | 0.8:0.2:0.05 |
| | layer | | | (mpmppm)₂(acac)*² | |
| | | 510(1) | 20 | 2mDBTBPDBq-II:PCBBiF:Ir | 0.7:0.3:0.05 |
| | | | | (mpmppm)₂(acac)*² | |
| | Hole-transport | 532 | 20 | BPAFLP | — |
| | layer | | | | |
| | Hole-injection | 531 | 20 | DBT3P-II:MoOₓ | 2:1 |
| | layer | | | | |
| | Lower electrode | 504 | 100 | ITSO | — |
| Light- | Upper electrode | 514 | 200 | Al | — |
| emitting | Electron- | 534 | 1 | LiF | — |
| element 3 | injection layer | | | | |
| | Electron- | 533(2) | 10 | Bphen | — |
| | transport layer | 533(1) | 20 | 2mDBTBPDBq-II | — |
| | Light-emitting | 510(2) | 20 | 2mDBTBPDBq-II:PCBBiF:Ir | 0.8:0.2:0.05 |
| | layer | | | (mpmppm)₂(acac)*³ | |
| | | 510(1) | 20 | 2mDBTBPDBq-II:PCBBiF:Ir | 0.7:0.3:0.05 |
| | | | | (mpmppm)₂(acac)*³ | |
| | Hole-transport | 532 | 20 | BPAFLP | — |
| | layer | | | | |
| | Hole-injection | 531 | 20 | DBT3P-II:MoOₓ | 2:1 |
| | layer | | | | |
| | Lower electrode | 504 | 100 | ITSO | — |

*¹Deposited by evaporation using Material Y1
*²Deposited by, evaporation using Material Y2
*³Deposited by evaporation using Material Y3

### <1-1. Method for Fabricating Light-Emitting Elements 1 to 3>

First, over a substrate 502, ITSO was deposited as a lower electrode 504 by a sputtering method. Note that the thickness of the lower electrode 504 was 100 nm and the area of the lower electrode 504 was 4 mm² (2 mm×2 mm).

Then, for pretreatment before deposition of an organic compound layer by evaporation, the lower electrode 504 side of the substrate 502 provided with the lower electrode 504 was washed with water, baking was performed at 200° C. for 1 hour, and then UV ozone treatment was performed on a surface of the lower electrode 504 for 370 seconds.

After that, the substrate 502 was transferred into a vacuum evaporation apparatus where the pressure had been reduced to approximately 10⁻⁴ Pa, and was subjected to vacuum baking at 170° C. for 60 minutes in a heating chamber of the vacuum evaporation apparatus, and then the substrate 502 was cooled down for approximately 30 minutes.

Next, the substrate 502 was fixed to a holder provided in the vacuum evaporation apparatus so that a surface of the substrate over which the lower electrode 504 was formed faced downward. In Example 1, by a vacuum evaporation method, a hole-injection layer 531, a hole-transport layer 532, a light-emitting layer 510(1), a light-emitting layer 510(2), an electron-transport layer 533(1), an electron-transport layer 533(2), an electron-injection layer 534, and an upper electrode 514 were sequentially formed. The fabrication method will be described in detail below.

First, after reducing the pressure of the vacuum evaporation apparatus to 10⁻⁴ Pa, DBT3P-II and molybdenum oxide were deposited by co-evaporation in a weight ratio of 2:1 (=DBT3P-II: molybdenum oxide), whereby the hole-injection layer 531 was formed over the lower electrode 504. Note that the thickness of the hole-injection layer 531 was 20 nm.

Then, the hole-transport layer 532 was formed over the hole-injection layer 531. As the hole-transport layer 532, BPAFLP was deposited by evaporation. Note that the thickness of the hole-transport layer 532 was 20 nm.

Next, the light-emitting layer 510(1) was formed over the hole-transport layer 532. As the light-emitting layer 510(1), 2mDBTBPDBq-II, N-(1,1′-biphenyl-4-yl)-9,9-dimethyl-N-[4-(9-phenyl-9H-carbazol-3-yl)phenyl]-9H-fluoren-2-amine (abbreviation: PCBBiF), and (acetylacetonato)bis[5-methyl-6-(2-methylphenyl)-4-phenylpyrimidinato]iridium(III) (abbreviation: Ir(mpmppm)₂(acac)) were deposited by co-evaporation in a weight ratio of 0.7:0.3:0.05 (=2mDBTBPDBq-II: PCBBiF: Ir(mpmppm)₂(acac)). Note that the thickness of the light-emitting layer 510(1) was 20 nm.

Next, the light-emitting layer 510(2) was formed over the light-emitting layer 510(1). As the light-emitting layer 510(2), 2mDBTBPDBq-II, PCBBiF, and Ir(mpmppm)₂(acac) were deposited by co-evaporation in a weight ratio of 0.8:0.2:0.05 (=2mDBTBPDBq-II: PCBBiF: Ir(mpmppm)₂(acac)). Note that the thickness of the light-emitting layer 510(2) was 20 nm.

In the light-emitting layer 510(1) and the light-emitting layer 510(2), 2mDBTBPDBq-II is a host material, PCBBiF is an assist material, and Ir(mpmppm)₂(acac) is an iridium complex serving as a guest material.

Note that the purity of the iridium complex used in the deposition of the light-emitting layers by evaporation was different between Light-emitting Elements 1 to 3. In the deposition of the light-emitting layers by evaporation, the iridium complex that was represented as Material Y1 was used in Light-emitting Element 1; the iridium complex that was represented as Material Y2 was used in Light-emitting Element 2; and the iridium complex that was represented as Material Y3 was used in Light-emitting Element 3. The purity of the iridium complexes that were represented as Materials Y1 to Y3 is shown in Table 5.

TABLE 5

| | m1 | m2 | m3 | m4 | m5 | m6 | m7 | m8 |
|---|---|---|---|---|---|---|---|---|
| | (811) | (811) | (811) | (797) | (797) | (783) | (711, 752) | (697, 738) |
| Material Y1 | 89.7% | 0.9% | — | 0.7% | — | — | 8.7% | — |
| Material Y2 | 77.1% | 2.1% | — | 13.4% | 0.1% | 0.4% | 6.2% | 0.7% |
| Material Y3 | 64.9% | 6.0% | 0.1% | 20.1% | 0.4% | 1.2% | 6.0% | 1.3% |

Value within parentheses is exact mass or mass of proton adduct

Note that the purity of Materials Y1 to Y3 shown in Table 5 was obtained by LC/MS analysis. The LC/MS analysis was performed by a method similar to that described in Embodiment 1, except for the conditions of the LC separation. In the LC separation for Materials Y1 to Y3, a gradient method in which the ratio between mobile phases is changed was employed. The ratio of Mobile Phase A to Mobile Phase B was 60:40 for 0 to 1 minute after the start of the measurement, and then the ratio of Mobile Phase A to Mobile Phase B was changed linearly such that the ratio in the 30th minute was 95:5. That is, the measurement time was 30 minutes.

As a result of the LC/MS analysis, chromatograms of Materials Y1 to Y3 exhibited peaks m1 to m8 shown in Table 5. Note that the peaks m1 to m3 correspond to m/z=811, the peaks m4 and m5 correspond to m/z=797, the peak m6 corresponds to m/z=783, the peak m7 corresponds to m/z=711 and 752, and the peak m8 corresponds to m/z=697 and 738. As a result of analysis using an MS chromatograph, the peak m1 was assigned to Ir(mpmppm)₂(acac), and the peaks m2 and m3 were assigned to structural isomers of Ir(mpmppm)₂(acac).

As shown in Table 5, the total proportion of peak areas of substances other than the iridium complex to which the peaks m1 to m3 were assigned was 8.7% in Material Y1, 20.8% in Material Y2, and 29% in Material Y3.

After that, over the light-emitting layer 510(2), 2mDBTBPDBq-II was deposited by evaporation to a thickness of 5 nm as the electron-transport layer 533(1). Then, over the electron-transport layer 533(1), Bphen was deposited by evaporation to a thickness of 10 nm as the electron-transport layer 533(2). Then, over the electron-transport layer 533(2), LiF was deposited by evaporation to a thickness of 1 nm as the electron-injection layer 534.

Then, over the electron-injection layer 534, Al was deposited by evaporation to a thickness of 200 nm as the upper electrode 514.

Next, a sealing substrate 552 was prepared.

The light-emitting elements formed over the substrate 502 as described above were sealed by being bonded to the sealing substrate 552 in a glove box in a nitrogen atmosphere so as not to be exposed to the air. For sealing, the sealant was applied to surround the light-emitting element, irradiation with 365-nm ultraviolet light at 6 J/cm² was performed, and heat treatment was then performed at 80° C. for 1 hour.

Through the above process, Light-emitting Elements 1 to 3 were fabricated.

Note that in all the above evaporation steps for Light-emitting Elements 1 to 3, a resistive heating method was used as an evaporation method.

### <1-2. Initial Characteristics of Light-Emitting Elements 1 to 3>

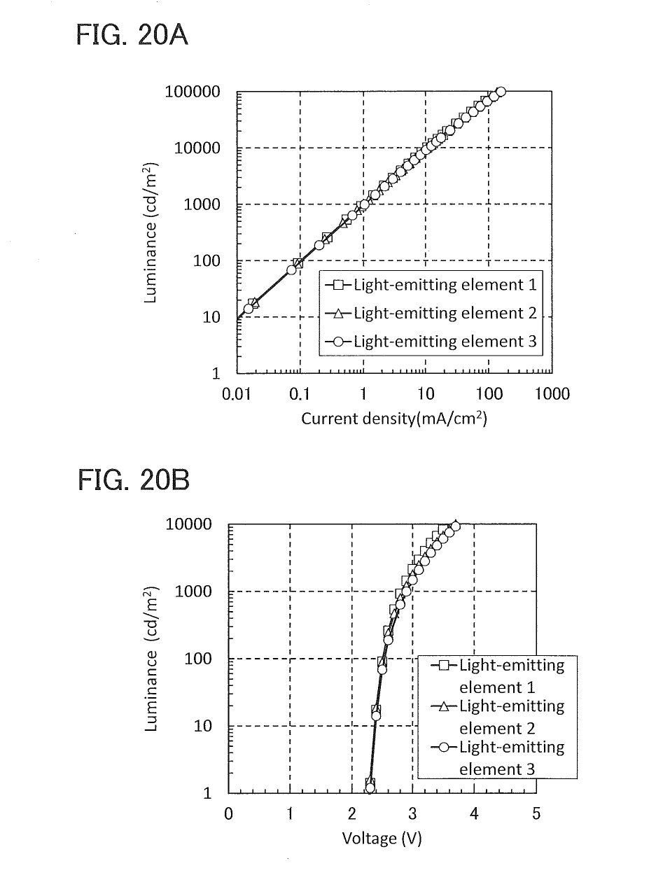

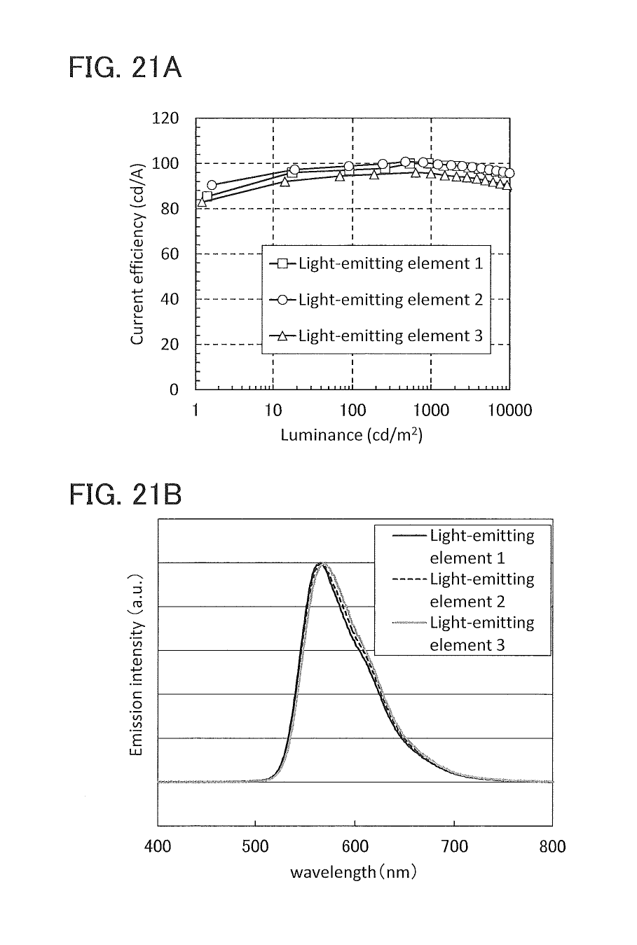

FIG. 20A shows current density-luminance characteristics of Light-emitting Elements 1 to 3, and FIG. 20B shows voltage-luminance characteristics of Light-emitting Elements 1 to 3. FIG. 21A shows luminance-current efficiency characteristics of Light-emitting Elements 1 to 3. Note that the measurement for each light-emitting element was carried out at room temperature (in the atmosphere maintained at 25° C.). Table 6 shows element characteristics of Light-emitting Elements 1 to 3 at around 1000 cd/m².

TABLE 6

| | | | Current | | | Current |
|---|---|---|---|---|---|---|
| | Voltage | Current | density | Chromaticity | Luminance | efficiency |
| | (V) | (mA) | (mA/cm²) | (x, y) | (cd/m²) | (cd/A) |
| Light-emitting | 2.8 | 0.04 | 0.9 | (0.50, 0.50) | 924 | 100.0 |
| element 1 | | | | | | |
| Light-emitting | 2.8 | 0.03 | 0.8 | (0.50, 0.49) | 792 | 100.5 |
| element 2 | | | | | | |
| Light-emitting | 2.9 | 0.04 | 1.0 | (0.51, 0.49) | 996 | 95.6 |
| element 3 | | | | | | |

FIG. 21B shows emission spectra when a current at a current density of 2.5 mA/cm² was supplied to Light-emitting Elements 1 to 3. As shown in FIGS. 20A and 20B, FIGS. 21A and 21B, and Table 6, the initial characteristics of Light-emitting Elements 1 and 2 that were embodiments of the present invention and those of Light-emitting Element 3 that was a comparative light-emitting element were not distinctively different from each other. It is thus suggested that the purity of the iridium complex, which is a phosphorescent material in the light-emitting layer 510(1) and the light-emitting layer 510(2), does not considerably affect the initial characteristics.

### <1-3. Reliability Test of Light-Emitting Elements 1 to 3>

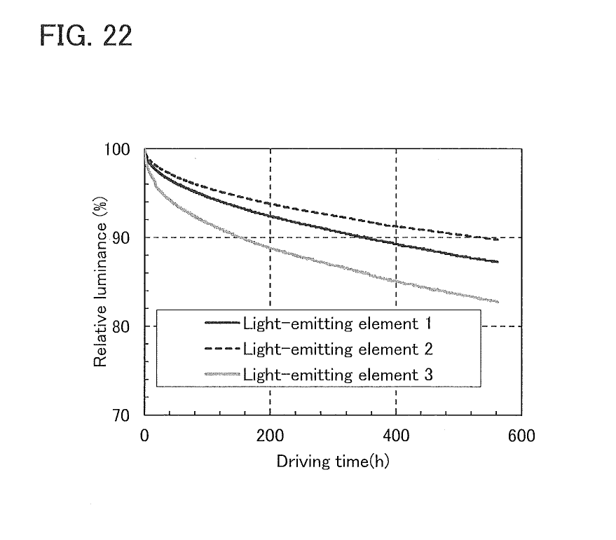

Next, reliability tests were performed on Light-emitting Elements 1 to 3. In the reliability tests, Light-emitting Elements 1 to 3 were driven under the conditions where the initial luminance was 5000 cd/m² and the current density was constant. FIG. 22 shows results of the reliability tests. In FIG. 22, the vertical axis represents relative luminance (%) with the initial luminance of 100%, and the horizontal axis represents driving time (h).

The results in FIG. 22 showed that relative luminance of Light-emitting Element 2 after 562 hours was 89.8%, relative luminance of Light-emitting Element 1 after 562 hours was 87.3%, and relative luminance of Light-emitting Element 3 after 562 hours was 82.8%.

The results in FIG. 22 showed that Light-emitting Elements 1 and 2 that were embodiments of the present invention each had a longer lifetime than Light-emitting Element 3 that was a comparative light-emitting element.

### <1-4. Analysis of Light-Emitting Elements 1 to 3 by Liquid Chromatography Mass Spectrometry>

Then, to find out the reason for the difference in reliability between Light-emitting Element 3 that was a comparative light-emitting element and Light-emitting Elements 1 and 2 that were embodiments of the present invention, Light-emitting Elements 1 to 3 were analyzed by LC/MS to examine impurities contained therein.

Note that for analysis of an impurity in Light-emitting Element 1, a light-emitting element that was different from Light-emitting Element 1 and was formed over the same substrate as Light-emitting Element 1 was used; for analysis of an impurity in Light-emitting Element 2, a light-emitting element that was different from Light-emitting Element 2 and was formed over the same substrate as Light-emitting Element 2 was used; for analysis of an impurity in Light-emitting Element 3, a light-emitting element that was different from Light-emitting Element 3 and was formed over the same substrate as Light-emitting Element 3 was used. In each of the light-emitting elements for the impurity analysis, the area of the lower electrode 504 was approximately 12 cm² (3.5 cm×3.3 cm). In other words, the light-emitting elements for the impurity analysis had the same materials and structures as Light-emitting Elements 1 to 3, but were different from Light-emitting Elements 1 to 3 in the area of the lower electrode 504. The samples for the impurity analysis were not driven; thus, the obtained results were not the analysis results of deteriorated objects produced by driving, but the analysis results of an impurity that had been contained from before driving. Here, the light-emitting element for the impurity analysis that was fabricated over the same substrate as Light-emitting Element 1 is regarded as Light-emitting Element 1 for convenience. The same applies to Light-emitting Elements 2 and 3.

Samples for the LC/MS analysis were obtained in the following manner: aluminum that was the upper electrode 514 of each of Light-emitting Elements 1 to 3 was peeled with the use of a Kapton tape (registered trademark); a substance remaining over the substrate 502 was dissolved in chloroform, so that a chloroform solution was obtained; and the chloroform solution was diluted with acetonitrile to a given concentration. The injection amount of the analysis sample was 5.0 μL in the LC/MS analysis.

The LC/MS analysis was performed by a method similar to that described in Embodiment 1. However, 15 minutes further elapsed after the ratio of Mobile Phase A to Mobile Phase B became 95:5. That is, the measurement time was 30 minutes.

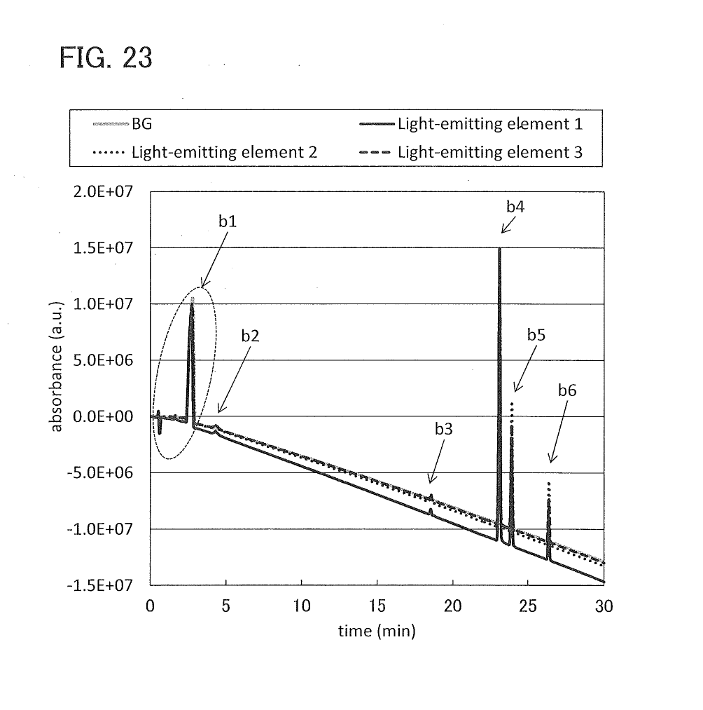

FIG. 23 shows analysis results of Light-emitting Elements 1 to 3. Note that FIG. 23 shows PDA chromatograms obtained by the LC/MS analysis of Light-emitting Elements 1 to 3.

In a manner similar to that of the analysis sample, the chloroform used for fabrication of the samples was diluted with acetonitrile to give a solution, and the solution was analyzed to obtain a base-line (or background: BG) chromatogram. In FIG. 23, the obtained base line is denoted as BG.

As shown in FIG. 23, the chromatograms of Light-emitting Elements 1 to 3 exhibited peaks b1 to b6. The peaks b1 to b6 were analyzed using an MS spectrum, so that the peak b2 was assigned to Bphen; the peak b3, Ir(mpmppm)₂(acac); the peak b4, BPAFLP and 2mDBTBPDBq-II; the peak b5, DBT3P-II; and the peak b6, PCBBiF. By comparison with BG, the peak b1 was assigned to the chloroform that was used as a solvent and an impurity contained in the chloroform.

As can be seen in FIG. 23, the peaks that were assigned to the substances used for forming the elements were observed but an obvious peak assigned to an impurity was not observed.

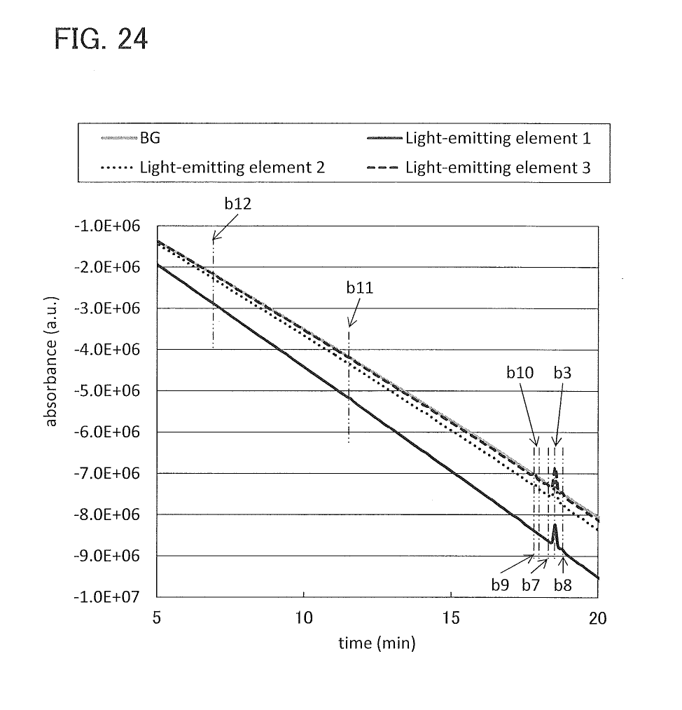

Next, the PDA chromatograms were analyzed with a focus on Ir(mpmppm)₂(acac). The base line was subtracted in the analysis of the PDA chromatograms. FIG. 24 shows analysis results of Light-emitting Elements 1 to 3 obtained with a focus on Ir(mpmppm)₂(acac). FIG. 24 is a graph in the vicinity of the peak b3 in FIG. 23 and was obtained by expanding the scale of the analysis time between the 5th minute and the 20th minute.

As shown in FIG. 24, the chromatograms of Light-emitting Elements 1 to 3 exhibited peaks b7 to b12 and a peak b3. The peak b3 is the same as that in FIG. 23 and was assigned to Ir(mpmppm)₂(acac). Note that in FIG. 24, the peaks b3, b7, and b8 correspond to precursor ions of the iridium complex, and the peaks b9 to b12 correspond to fragment ions of the iridium complex.

The peaks b7 to b12 were analyzed using an MS chromatograph, which showed that the peak b7 was assigned to a structural isomer (referred to as Structural Isomer 1, for convenience) of Ir(mpmppm)₂(acac); the peak b8, a structural isomer (referred to as Structural Isomer 2, for convenience) of Ir(mpmppm)₂(acac); the peak b9, a substance with a structure of an mpmppm skeleton (a ligand of Ir(mpmppm)₂(acac)) from which one Me group was dissociated; the peak b10, a structural isomer of a structure of an mpmppm skeleton (a ligand of Ir(mpmppm)₂(acac)) from which one Me group was dissociated; the peak b11, a substance with a structure of Ir(mpmppm)₂, that is, a structure of Ir(mpmppm)₂(acac) from which the ligand acac was dissociated; and the peak b12, mpmppm that was a ligand of Ir(mpmppm)₂(acac).

In LC/MS analysis, the substance with the structure of Ir(mpmppm)₂produced an MS spectrum with a mass-to-charge ratio (m/z) of 753. The mass number of a proton adduct of a structure in which acetonitrile is coordinated to Ir(mpmppm)₂ is 753. Thus, it was suggested that acetonitrile was coordinated to Ir(mpmppm)₂ during the LC separation.

The measurement range of a Xevo G2 Tof MS detector manufactured by Waters Corporation, which was used in the analysis, was m/z=100 or more. That is why the ligand acac, which is out of the measurement range of the MS detector, was not detected. The ligand acac was not detected with a PDA detector, either.

Next, with the use of the results of LC/MS analysis shown in FIG. 24, the purity of Ir(mpmppm)₂(acac) contained in Light-emitting Elements 1 to 3 was examined. Table 7 shows the analysis results. Note that the results shown in Table 7 were obtained on the assumption that the peak areas of seven peaks of the peaks b3 and b7 to b12 in FIG. 24, i.e., the total peak area of substances originating in the iridium complex, was 100%. Thus, materials included in Light-emitting Elements 1 to 3 other than Ir(mpmppm)₂(acac) were not subjected to the purity examination.

TABLE 7

| | b3 | b7 | b8 | b9 | b10 | b11 | b12 | |
|---|---|---|---|---|---|---|---|---|
| | (811) | (811) | (811) | (797) | (797) | (711, 752) | (261) | b12/(b3 + b7 + b8) |
| Light-emitting | 87.8% | 6.4% | 0.3% | 0.5% | — | 4.1% | 0.9% | 1.0% |
| element 1 | | | | | | | | |
| Light-emitting | 78.1% | 5.6% | 1.6% | 10.7% | 0.6% | 2.7% | 0.7% | 0.8% |
| element 2 | | | | | | | | |
| Light-emitting | 67.4% | 6.9% | 3.6% | 13.4% | 0.4% | 3.1% | 5.2% | 6.7% |
| element 3 | | | | | | | | |

Value within parentheses is exact mass or mass of proton adduct

As shown in Table 7, in Light-emitting Element 1, on the assumption that the total peak area of substances originating in the iridium complex Ir(mpmppm)₂(acac) was 100%, the proportion of the peak area (b12) of a ligand not coordinated to the iridium metal to the peak area (b3, b7, and b8) of the iridium complex was 1.0%. In Light-emitting Element 2, on the assumption that the total peak area of substances originating in the iridium complex Ir(mpmppm)₂(acac) was 100%, the proportion of the peak area (b12) of a ligand not coordinated to the iridium metal to the peak area (b3, b7, and b8) of the iridium complex was 0.8%. In Light-emitting Element 3, on the assumption that the total peak area of substances originating in the iridium complex Ir(mpmppm)₂(acac) was 100%, the proportion of the peak area (b12) of a ligand not coordinated to the iridium metal to the peak area (b3, b7, and b8) of the iridium complex was 6.7%.

On the assumption that the total peak area of substances originating in the iridium complex was 100%, the proportion of the peak area of the ligand not coordinated to the iridium metal was 5% or less in Light-emitting Elements 1 and 2 that were embodiments of the present invention. Therefore, Light-emitting Elements 1 and 2 had a longer lifetime than Light-emitting Element 3 that was a comparative light-emitting element.

On the assumption that the total peak area of substances originating in the iridium complex was 100%, the proportion of the peak area of the ligand not coordinated to the iridium metal was 1% or less in Light-emitting Elements 1 and 2 that were embodiments of the present invention. Note that comparison between Light-emitting Element 1 and Light-emitting Element 2 shows that on the assumption that the total peak area of substances originating in the iridium complex is 100%, the proportion of the peak area of the ligand not coordinated to the iridium metal is smaller in Light-emitting Element 2 than in Light-emitting Element 1, which made the lifetime of Light-emitting Element 2 longer than that of Light-emitting Element 1. Therefore, it is suggested that on the assumption that the total peak area of substances originating in the iridium complex is 100%, a smaller proportion of the peak area of the ligand not coordinated to the iridium metal leads to higher reliability.

As described above, the reliability of the light-emitting elements of embodiments of the present invention was increased by reducing the concentration of an impurity originating in the iridium complex, which was the light-emitting substance in the light-emitting layers 510(1) and 510(2).

The results in Table 7 suggested that Ir(mpmppm)₂(acac) was decomposed during the deposition by evaporation and a substance from which the ligand acac was dissociated was deposited by evaporation. The film deposited by evaporation contained Ir(mpmppm)₂(acac) most as a main component, and also contained Structural Isomer 1 and Structural Isomer 2, which are presumably different from Ir(mpmppm)₂(acac) in the direction of the ligand mpmppm. Since the proportion of an impurity from which a Me group was dissociated did not increase after the deposition by evaporation, a Me group is less likely to have been decomposed during the deposition by evaporation to be dissociated. As decomposition products that increased after the deposition by evaporation, the ligand mpmppm and Ir(mpmppm)₂, from which the ligand acac was dissociated, were observed.

According to the results of the reliability tests shown in FIG. 22 and the results of the examination of purity in Table 7 which were obtained using only the substances originating in Ir(mpmppm)₂(acac) in the light-emitting elements, the larger the content of the ligand mpmppm in the light-emitting element was, the more the deterioration of the luminance was accelerated in the reliability test. There was no correlation between the results of the reliability tests and the content of each of Structural Isomer 1, Structural Isomer 2, an impurity from which a Me group was dissociated, and a decomposition product Ir(mpmppm)₂; therefore, it is suggested that these substances are not the main cause of the accelerated deterioration of luminance. Note that in the case where the content of the ligand mpmppm is extremely small, these substances might be the main cause of acceleration of deterioration of luminance.

The structures described in this example can be used in an appropriate combination with any of other examples and embodiments.

### EXAMPLE 2

In this example, an example of fabricating a light-emitting element of one embodiment of the present invention will be described. Note that in this example, light-emitting elements that were embodiments of the present invention (Light-emitting Element 4 and Light-emitting Element 5) were fabricated.

A schematic cross-sectional view of Light-emitting Elements 4 and 5 is shown in FIG. 19, and details about element structures of Light-emitting Elements 4 and 5 are shown in Table 8. Note that the compounds used here are the same as those used in Example 1.

TABLE 8

| | | Reference | Thickness | | |
|---|---|---|---|---|---|
| | Layer | numeral | (nm) | Material | Weight ratio |
| Light- | Upper electrode | 514 | 200 | Al | — |
| emitting | Electron-injection | 534 | 1 | LiF | — |
| element 4 | layer | | | | |
| | Electron- | 533(2) | 10 | Bphen | — |
| | transport layer | 533(1) | 20 | 2mDBTBPDBq-II | — |
| | Light-emitting | 510(2) | 20 | 2mDBTBPDBq-II:PCBBiF:Ir | 0.80.2:0.05 |
| | layer | | | (mpmppm)₂(acac)*¹ | |
| | | 510(1) | 20 | 2mDBTBPDBq-II:PCBBiF:Ir | 0.7:0.3:0.05 |
| | | | | (mpmppm)₂(acac)*¹ | |
| | Hole-transport | 532 | 20 | BPAFLP | — |
| | layer | | | | |
| | Hole-injection | 531 | 20 | DBT3P-II:MoOₓ | 2:1 |
| | layer | | | | |
| | Lower electrode | 504 | 100 | ITSO | — |
| Light- | Upper electrode | 514 | 200 | Al | — |
| emitting | Electron-injection | 534 | 1 | LiF | — |
| element 5 | layer | | | | |
| | Electron- | 533(2) | 10 | Bphen | — |
| | transport layer | 533(1) | 20 | 2mDBTBPDBq-II | — |
| | Light-emitting | 510(2) | 20 | 2mDBTBPDBq-II:PCBBiF:Ir | 0.8:0.2:0.05 |
| | layer | | | (mpmppm)₂(acae)*² | |
| | | 510(1) | 20 | 2mDBTBPDBq-II:PCBBiF:Ir | 0.7:0.3:0.05 |
| | | | | (mpmppm)₂(acac)*² | |
| | Hole-transport | 532 | 20 | BPAFLP | — |
| | layer | | | | |
| | Hole-injection | 531 | 20 | DBT3P-II:MoOₓ | 2:1 |
| | layer | | | | |
| | Lower electrode | 504 | 100 | ITSO | — |

*¹Deposited by evaporation using Material Z1
*²Deposited by evaporation using Material Z2

### <2-1. Method for Fabricating Light-Emitting Elements 4 and 5>

First, over the substrate 502, ITSO was deposited as the lower electrode 504 by a sputtering method. Note that the thickness of the lower electrode 504 was 100 nm and the area of the lower electrode 504 was 4 mm² (2 mm×2 mm).

Then, for pretreatment before deposition of an organic compound layer by evaporation, the lower electrode 504 side of the substrate 502 provided with the lower electrode 504 was washed with water, baking was performed at 200° C. for 1 hour, and then UV ozone treatment was performed on a surface of the lower electrode 504 for 370 seconds.

After that, the substrate 502 was transferred into a vacuum evaporation apparatus where the pressure had been reduced to approximately 10⁻⁴ Pa, and was subjected to vacuum baking at 170° C. for 60 minutes in a heating chamber of the vacuum evaporation apparatus, and then the substrate 502 was cooled down for approximately 30 minutes.

Next, the substrate 502 was fixed to a holder provided in the vacuum evaporation apparatus so that a surface of the substrate over which the lower electrode 504 was formed faced downward. In Example 2, by a vacuum evaporation method, the hole-injection layer 531, the hole-transport layer 532, the light-emitting layer 510(1), the light-emitting layer 510(2), the electron-transport layer 533(1), the electron-transport layer 533(2), the electron-injection layer 534, and the upper electrode 514 were sequentially formed. The fabrication method will be described in detail below.

First, after reducing the pressure of the vacuum evaporation apparatus to 10⁻⁴ Pa, DBT3P-II and molybdenum oxide were deposited by co-evaporation in a weight ratio of 2:1 (=DBT3P-II: molybdenum oxide), whereby the hole-injection layer 531 was formed over the lower electrode 504. Note that the thickness of the hole-injection layer 531 was 20 nm.

Then, as the hole-transport layer 532, BPAFLP was deposited by evaporation over the hole-injection layer 531. Note that the thickness of the hole-transport layer 532 was 20 nm.

Next, the light-emitting layer 510(1) was formed over the hole-transport layer 532. As the light-emitting layer 510(1), 2mDBTBPDBq-II, PCBBiF, and Ir(mpmppm)₂(acac) were deposited by co-evaporation in a weight ratio of 0.7:0.3:0.05 (=2mDBTBPDBq-II: PCBBiF: Ir(mpmppm)₂(acac)). Note that the thickness of the light-emitting layer 510(1) was 20 nm.

Next, the light-emitting layer 510(2) was formed over the light-emitting layer 510(1). As the light-emitting layer 510(2), 2mDBTBPDBq-II, PCBBiF, and Ir(mpmppm)₂(acac) were deposited by co-evaporation in a weight ratio of 0.8:0.2:0.05 (=2mDBTBPDBq-II: PCBBiF: Ir(mpmppm)₂(acac)). Note that the thickness of the light-emitting layer 510(2) was 20 nm.

In the light-emitting layer 510(1) and the light-emitting layer 510(2), 2mDBTBPDBq-II is a host material, PCBBiF is an assist material, and Ir(mpmppm)₂(acac) is a phosphorescent material (a guest material).

Note that the purity of the iridium complex used in the deposition of the light-emitting layers by evaporation was different between Light-emitting Elements 4 and 5. In the deposition of the light-emitting layers by evaporation, the iridium complex that was represented as Material Z1 was used in Light-emitting Element 4, and the iridium complex that was represented as Material Z2 was used in Light-emitting Element 5. The purity of the iridium complexes that were represented as Materials Z1 and Z2 is shown in Table 9.

TABLE 9

| | m1 | m2 | m3 | m4 | m5 | m6 | m7 | m8 |
|---|---|---|---|---|---|---|---|---|
| | (811) | (811) | (811) | (797) | (797) | (783) | (711, 752) | (697, 738) |
| Material Z1 | 77.1% | 2.1% | — | 13.4% | 0.1% | 0.4% | 6.2% | 0.7% |
| Material Z2 | 88.3% | 3.9% | — | 0.4% | — | — | 7.4% | — |

Value within parentheses is exact mass or mass of proton adduct

Note that the purity of Materials Z1 and Z2 was obtained by LC/MS analysis. The LC/MS analysis was performed by a method similar to that described in Example 1. As a result of the LC/MS analysis, chromatograms of Materials Z1 and Z2 exhibited peaks m1, m2, and m4 to m8 shown in Table 9. The peaks m1 to m8 are the same as those exhibited by the chromatograms of Materials Y1 to Y3 in Example 1.

As shown in Table 9, the total proportion of peak areas of substances other than the iridium complex to which the peaks m1 and m2 were assigned was 20.8% in Material Z1, and 7.8% in Material Z2.

After that, over the light-emitting layer 510(2), 2mDBTBPDBq-II was deposited by evaporation to a thickness of 5 nm as the electron-transport layer 533(1). Then, over the electron-transport layer 533(1), Bphen was deposited by evaporation to a thickness of 10 nm as the electron-transport layer 533(2). Then, over the electron-transport layer 533(2), LiF was deposited by evaporation to a thickness of 1 nm as the electron-injection layer 534.

Then, over the electron-injection layer 534, Al was deposited by evaporation to a thickness of 200 nm as the upper electrode 514.

Next, the sealing substrate 552 was prepared.

The light-emitting elements formed over the substrate 502 as described above were sealed by being bonded to the sealing substrate 552 in a glove box in a nitrogen atmosphere so as not to be exposed to the air. The sealing method was the same as that used for Light-emitting Elements 1 to 3 in Example 1.

Through the above process, Light-emitting Elements 4 and 5 were fabricated.

Note that in all the above evaporation steps for Light-emitting Elements 4 and 5, a resistive heating method was used as an evaporation method.

### <2-2. Initial Characteristics of Light-Emitting Elements 4 and 5>

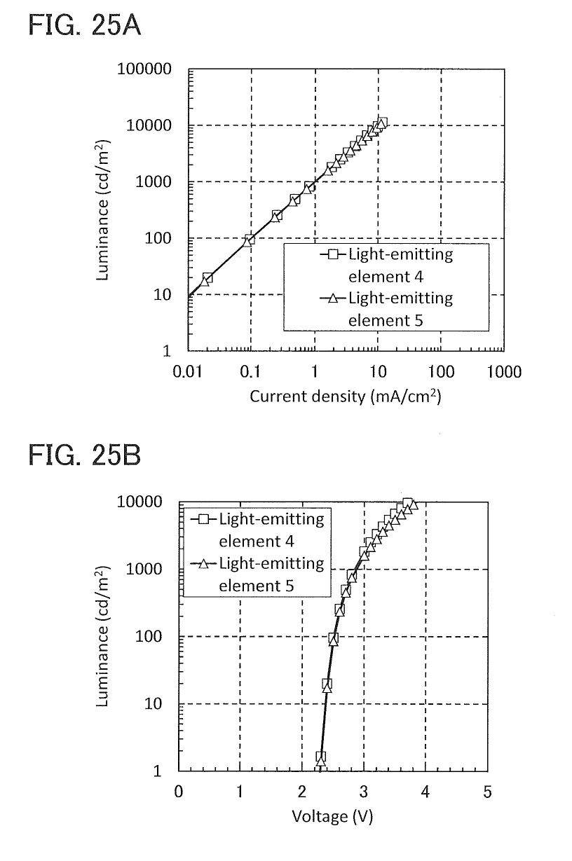

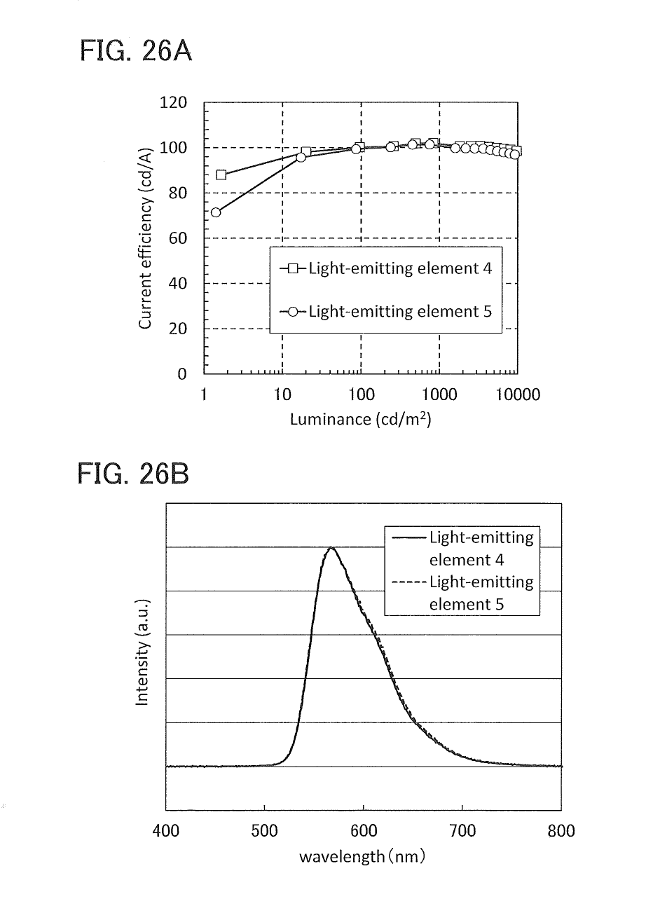

FIG. 25A shows current density-luminance characteristics of Light-emitting Elements 4 and 5, and FIG. 25B shows voltage-luminance characteristics of Light-emitting Elements 4 and 5. FIG. 26A shows luminance-current efficiency characteristics of Light-emitting Elements 4 and 5. Note that the measurement for each light-emitting element was carried out at room temperature (in the atmosphere maintained at 25° C.). Table 10 shows element characteristics of Light-emitting Elements 4 and 5 at around 1000 cd/m².

TABLE 10

| | | | Current | | | Current |
|---|---|---|---|---|---|---|
| | Voltage | Current | density | Chromaticity | Luminance | efficiency |
| | (V) | (mA) | (mA/cm²) | (x, y) | (cd/m²) | (cd/A) |
| Light- | 2.8 | 0.03 | 0.8 | (0.51, 0.49) | 830.5 | 102.0 |
| emitting | | | | | | |
| element 4 | | | | | | |
| Light- | 2.9 | 0.04 | 1.1 | (0.51, 0.49) | 1109 | 99.7 |
| emitting | | | | | | |
| element 5 | | | | | | |

FIG. 26B shows emission spectra when a current at a current density of 2.5 mA/cm² was supplied to Light-emitting Elements 4 and 5. As shown in FIGS. 25A and 25B, FIGS. 26A and 26B, and Table 10, the initial characteristics of Light-emitting Element 4 and those of Light-emitting Element 5 were not distinctively different from each other. It is thus suggested that the purity of the iridium complex, which is used as the phosphorescent material in the light-emitting layer 510(1) and the light-emitting layer 510(2), does not considerably affect the initial characteristics.

### <2-3. Reliability Test of Light-Emitting Elements 4 and 5>

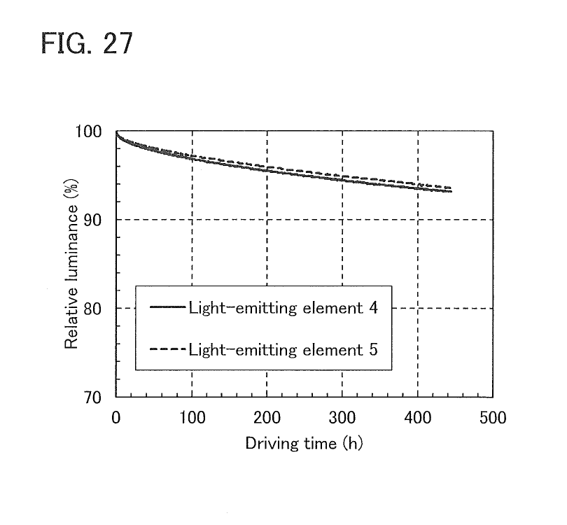

Next, reliability tests were performed on Light-emitting Elements 4 and 5. In the reliability tests, Light-emitting Elements 4 and 5 were driven under the conditions where the initial luminance was 5000 cd/m² and the current density was constant. FIG. 27 shows results of the reliability tests. In FIG. 27, the vertical axis represents relative luminance (%) with the initial luminance of 100%, and the horizontal axis represents driving time (h).

The results in FIG. 27 showed that relative luminance of Light-emitting Element 4 after 444 hours was 93.2%, and relative luminance of Light-emitting Element 5 after 444 hours was 87.3%.

The results in FIG. 27 show that deterioration curves of Light-emitting Elements 4 and 5 are substantially the same and these light-emitting elements are highly reliable.

### <2-4. Analysis of Light-Emitting Elements 4 and 5 by Liquid Chromatography Mass Spectrometry>

Then, Light-emitting Elements 4 and 5 were analyzed by LC/MS to examine impurities contained in the light-emitting elements.

Note that for analysis of an impurity in Light-emitting Element 4, a light-emitting element that was different from Light-emitting Element 4 and was formed over the same substrate as Light-emitting Element 4 was used; and for analysis of an impurity in Light-emitting Element 5, a light-emitting element that was different from Light-emitting Element 5 and was formed over the same substrate as Light-emitting Element 5 was used. In each of the light-emitting elements for the impurity analysis, the area of the lower electrode 504 was approximately 12 cm² (3.5 cm×3.3 cm). In other words, the light-emitting elements for the impurity analysis had the same materials and structures as Light-emitting Elements 4 and 5, but were different from Light-emitting Elements 4 and 5 in the area of the lower electrode 504. The samples for the impurity analysis were not driven; thus, the obtained results were not the analysis results of deteriorated objects produced by driving, but the analysis results of an impurity that had been contained from before driving. Here, the light-emitting element for the impurity analysis that was fabricated over the same substrate as Light-emitting Element 4 is regarded as Light-emitting Element 4 for convenience. The same applies to Light-emitting Element 5.

The LC/MS analysis was performed by a method similar to that described in Example 1.

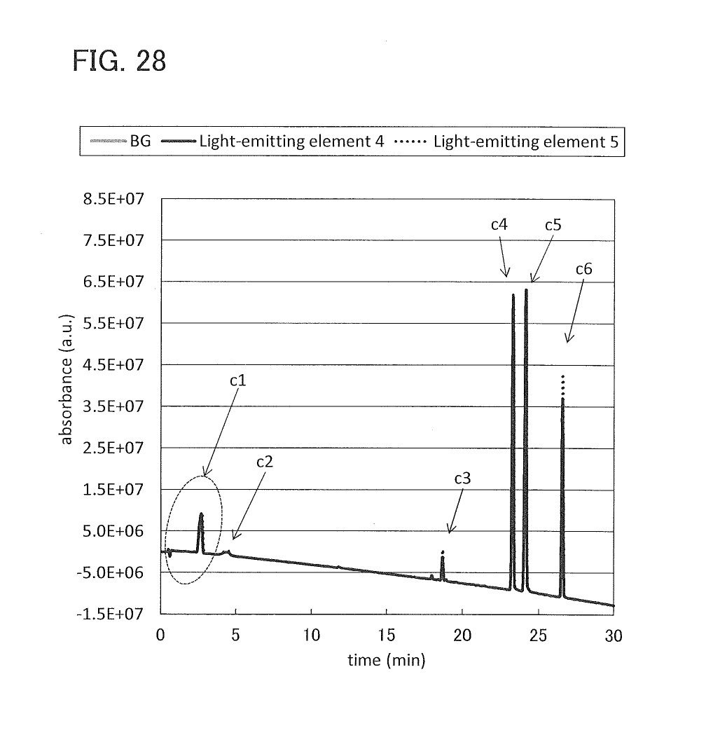

FIG. 28 shows analysis results of Light-emitting Elements 4 and 5. Note that FIG. 28 shows PDA chromatograms obtained by the LC/MS analysis of Light-emitting Elements 4 and 5.

In a manner similar to that of the analysis sample, the chloroform used for fabrication of the analysis sample was diluted with acetonitrile to give a solution, and the solution was analyzed to obtain a base-line (or background: BG) chromatogram. In FIG. 28, the obtained base line is denoted as BG.

As shown in FIG. 28, the chromatograms of Light-emitting Elements 4 and 5 exhibited peaks c1 to c6. The peaks c1 to c6 were analyzed using an MS spectrum, which showed that the peak c2 was assigned to Bphen; the peak c3, Ir(mpmppm)₂(acac); the peak c4, BPAFLP and 2mDBTBPDBq-II; the peak c5, DBT3P-II; and the peak c6, PCBBiF. By comparison with BG, the peak c1 was assigned to the chloroform that was used as a solvent and an impurity contained in the chloroform.

As can be seen in FIG. 28, the peaks that were assigned to the substances used for forming the elements was observed but an obvious peak assigned to an impurity was not observed.

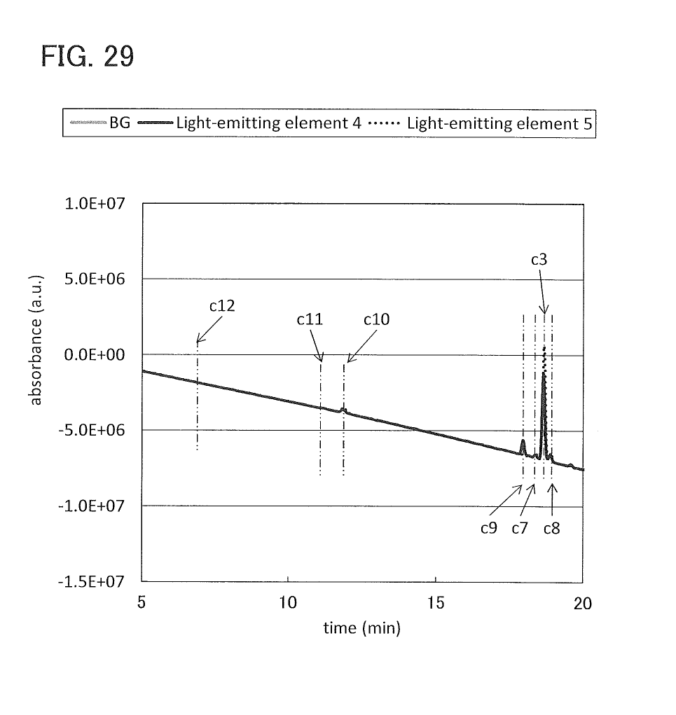

Next, the PDA chromatograms were analyzed with a focus on Ir(mpmppm)₂(acac). The base line was subtracted in the analysis of the PDA chromatograms. FIG. 29 shows analysis results of Light-emitting Elements 4 and 5 obtained with a focus on Ir(mpmppm)₂(acac). FIG. 29 is a graph in the vicinity of the peak c3 in FIG. 28 and was obtained by expanding the scale of the analysis time between the 5th minute and the 20th minute.

As shown in FIG. 29, the chromatograms of Light-emitting Elements 4 and 5 exhibited a peak c3 and peaks c7 to c12. The peak c3 is the same as that in FIG. 28 and was assigned to Ir(mpmppm)₂(acac). Note that in FIG. 29, the peaks c3, c7, and c8 correspond to precursor ions of the iridium complex, and the peaks c9 to c12 correspond to fragment ions of the iridium complex.

The peaks c7 to c12 were analyzed using an MS chromatograph, which showed that the peak c7 was assigned to a structural isomer (referred to as Structural Isomer 1, for convenience) of Ir(mpmppm)₂(acac); the peak c8, a structural isomer (referred to as Structural Isomer 2, for convenience) of Ir(mpmppm)₂(acac); the peak c9, a substance with a structure of an mpmppm skeleton (a ligand of Ir(mpmppm)₂(acac)) from which one Me group was dissociated; the peak c10, a substance with a structure of Ir(mpmppm)₂, that is, a structure of Ir(mpmppm)₂(acac) from which the ligand acac was dissociated; the peak c11, a substance with a structure of Ir(mpmppm)₂(acac) from which the ligand acac and a Me group were dissociated; and the peak c12, mpmppm that was a ligand of Ir(mpmppm)₂(acac).

In LC/MS analysis, the substance with the structure of Ir(mpmppm)₂ produced an MS spectrum with a mass-to-charge ratio (m/z) of 753. The mass number of a proton adduct of a structure in which acetonitrile is coordinated to Ir(mpmppm)₂ is 753. Thus, it was suggested that acetonitrile was coordinated to Ir(mpmppm)₂ during the LC separation.

The measurement range of a Xevo G2 Tof MS detector manufactured by Waters Corporation, which was used in the analysis, was m/z=100 or more. That is why the ligand acac, which is out of the measurement range of the MS detector, was not detected. The ligand acac was not detected with a PDA detector, either.

Next, with the use of the results of LC/MS analysis shown in FIG. 29, the concentration of impurities contained in Light-emitting Elements 4 and 5 was examined. Table 11 shows the analysis results. Note that the results shown in Table 11 were obtained on the assumption that the peak areas of seven peaks of the peaks c3 and c7 to c12 in FIG. 29, i.e., the total peak area of substances originating in the iridium complex, was 100%. Thus, materials included in Light-emitting Elements 4 and 5 other than Ir(mpmppm)₂(acac) were not subjected to the purity examination. For convenience, Table 11 includes a peak c13 corresponding to m/z=261, which was not exhibited in FIG. 29.

TABLE 11

| | c3 | c7 | c8 | c9 | c10 | c11 | c12 | c13 | |
|---|---|---|---|---|---|---|---|---|---|
| | (811) | (811) | (811) | (797) | (797) | (711, 752) | (697, 738) | (261) | c13/(c3 + c7 + c8) |
| Light- | 75.2% | 2.4% | 4.7% | 12.5% | 0.1% | 4.5% | 0.6% | — | — |
| emitting | | | | | | | | | |
| element 4 | | | | | | | | | |
| Light- | 85.5% | 2.9% | 4.7% | 0.5% | — | 6.2% | 0.2% | — | — |
| emitting | | | | | | | | | |
| element 5 | | | | | | | | | |

Value within parentheses is exact mass or mass of proton adduct

As shown in Table 11, in Light-emitting Elements 4 and 5, the proportion of the peak area (c13) of a ligand not coordinated to the iridium metal was less than 0.1%, under the lower detection limit (shown in Table 11 as “-”).

On the assumption that the total peak area of substances originating in the iridium complex was 100%, the proportion of the peak area of the ligand not coordinated to the iridium metal was 1% or less in Light-emitting Elements 4 and 5 that were embodiments of the present invention. Therefore, Light-emitting Elements 4 and 5 had a long lifetime.

As described above, the reliability of the light-emitting elements of embodiments of the present invention was increased by reducing the concentration of the ligand mpmppm that was an impurity originating in the iridium complex, which was the light-emitting substance in the light-emitting layers 510(1) and 510(2).

The results in Table 11 suggested that Ir(mpmppm)₂(acac) was decomposed during the deposition by evaporation and a substance from which the ligand acac was dissociated was deposited by evaporation. The film deposited by evaporation contained Ir(mpmppm)₂(acac) most as a main component, and also contained Structural isomer 1 and Structural Isomer 2, which are presumably different from Ir(mpmppm)₂(acac) in the direction of the ligand mpmppm. Since the proportion of an impurity from which a Me group was dissociated did not increase after the deposition by evaporation, a Me group is less likely to have been decomposed during the deposition by evaporation to be dissociated. As a decomposition product that increased after the deposition by evaporation, Ir(mpmppm)₂, from which the ligand acac was dissociated, was observed. The ligand acac was not detected.

According to the results of the reliability tests shown in FIG. 27 and the results of the examination of purity in Table 11 which were obtained using only the substances originating in Ir(mpmppm)₂(acac) in the light-emitting elements, Light-emitting Elements 4 and 5 had substantially the same driving lifetime in spite of being different in the purity of Ir(mpmppm)₂(acac). As can be seen from the results in Table 11, Light-emitting Elements 4 and 5 did not contain the ligand mpmppm. Therefore, it was shown that the absence of mpmppm led to long lifetimes of the light-emitting elements. There was no correlation between the results of the reliability tests and the content of each of Structural Isomer 1, Structural Isomer 2, an impurity from which a Me group was dissociated, and a decomposition product Ir(mpmppm)₂, therefore, it is suggested that these substances are not the main cause of the accelerated deterioration of luminance.

The structures described in this example can be used in an appropriate combination with any of other examples and embodiments.

### EXAMPLE 3

In this example, an example of fabricating a light-emitting element of one embodiment of the present invention will be described. Note that in this example, light-emitting elements that were embodiments of the present invention (Light-emitting Element 6 and Light-emitting Element 7) were fabricated.

A schematic cross-sectional view of Light-emitting Elements 6 and 7 is shown in FIG. 19, and details about element structures of Light-emitting Elements 6 and 7 are shown in Table 12. Note that the compounds used here are the same as those used in Examples 1 and 2.

TABLE 12

| | | Reference | Thickness | | |
|---|---|---|---|---|---|
| | Layer | numeral | (nm) | Material | Weight ratio |
| Light- | Upper | 114 | 200 | Al | — |
| emitting | electrode | | | | |
| element 6 | Electron- | 134 | 1 | LiF | — |
| | injection | | | | |
| | layer | | | | |
| | Electron- | 133(2) | 10 | Bphen | — |
| | transport | 133(1) | 20 | 2mDBTBPDBq-II | — |
| | Light- | 110(2) | 20 | 2mDBTBPDBq-II:PCBBiF:Ir | 0.8:02:0.05 |
| | emitting | | | (mpmppm)₂(acac)*¹ | |
| | layer | 110(1) | 20 | 2mDBTBPDBq-II:PCBBiF:Ir | 0.7:0.3:0.05 |
| | | | | (mpmppm)₂(acac)*¹ | |
| | Hole- | 132 | 20 | BPAFLP | — |
| | transport | | | | |
| | layer | | | | |
| | Hole- | 131 | 20 | DBT3P-II:MoOₓ | 2:1 |
| | injection | | | | |
| | layer | | | | |
| | Lower | 104 | 100 | ITSO | — |
| | electrode | | | | |
| Light- | Upper | 114 | 200 | Al | — |
| emitting | electrode | | | | |
| element 7 | Electron- | 134 | 1 | LiF | — |
| | injection | | | | |
| | layer | | | | |
| | Electron- | 133(2) | 10 | Bphen | — |
| | transport | 133(1) | 20 | 2mDBTBPDBq-II | — |
| | Light- | 110(2) | 20 | 2mDBTBPDBq-II:PCBBiF:Ir | 0.8:0.2:0.05 |
| | emitting | | | (mpmppm)₂(acac)*² | |
| | layer | 110(1) | 20 | 2mDBTBPDBq-II:PCBBiF:Ir | 0.7:0.3:0.05 |
| | | | | (mpmppm)₂(acac)*² | |
| | Hole- | 132 | 20 | BPAFLP | — |
| | transport | | | | |
| | layer | | | | |
| | Hole- | 131 | 20 | DBT3P-II:MoOₓ | 2:1 |
| | injection | | | | |
| | layer | | | | |
| | Lower | 104 | 100 | ITSO | — |
| | electrode | | | | |

*¹Deposited by evaporation using Material Z1
*²Deposited by evaporation using Material Z3

### <3-1. Method for Fabricating Light-Emitting Elements 6 and 7>

First, over the substrate 502, ITSO was deposited as the lower electrode 504 by a sputtering method. Note that the thickness of the lower electrode 504 was 100 nm and the area of the lower electrode 504 was 4 mm² (2 mm×2 mm).

Then, for pretreatment before deposition of an organic compound layer by evaporation, the lower electrode 504 side of the substrate 502 provided with the lower electrode 504 was washed with water, baking was performed at 200° C. for 1 hour, and then UV ozone treatment was performed on a surface of the lower electrode 504 for 370 seconds.

After that, the substrate 502 was transferred into a vacuum evaporation apparatus where the pressure had been reduced to approximately 10⁻⁴ Pa, and was subjected to vacuum baking at 170° C. for 60 minutes in a heating chamber of the vacuum evaporation apparatus, and then the substrate 502 was cooled down for approximately 30 minutes.

Next, the substrate 502 was fixed to a holder provided in the vacuum evaporation apparatus so that a surface of the substrate over which the lower electrode 504 was formed faced downward. In Example 3, by a vacuum evaporation method, the hole-injection layer 531, the hole-transport layer 532, the light-emitting layer 510(1), the light-emitting layer 510(2), the electron-transport layer 533(1), the electron-transport layer 533(2), the electron-injection layer 534, and the upper electrode 514 were sequentially formed. The fabrication method will be described in detail below.

First, after reducing the pressure of the vacuum evaporation apparatus to 10⁻⁴ Pa, DBT3P-II and molybdenum oxide were deposited by co-evaporation in a weight ratio of 2:1 (=DBT3P-II: molybdenum oxide), whereby the hole-injection layer 531 was formed over the lower electrode 504. Note that the thickness of the hole-injection layer 531 was 20 nm.

Then, as the hole-transport layer 532, BPAFLP was deposited by evaporation over the hole-injection layer 531. Note that the thickness of the hole-transport layer 532 was 20 nm.

Next, the light-emitting layer 510(1) was formed over the hole-transport layer 532. As the light-emitting layer 510(1), 2mDBTBPDBq-II, PCBBiF, and Ir(mpmppm)₂(acac) were deposited by co-evaporation in a weight ratio of 0.7:0.3:0.05 (=2mDBTBPDBq-II: PCBBiF: Ir(mpmppm)₂(acac)). Note that the thickness of the light-emitting layer 510(1) was 20 nm.

Next, the light-emitting layer 510(2) was formed over the light-emitting layer 510(1). As the light-emitting layer 510(2), 2mDBTBPDBq-II, PCBBiF, and Ir(mpmppm)₂(acac) were deposited by co-evaporation in a weight ratio of 0.8:0.2:0.05 (=2mDBTBPDBq-II: PCBBiF: Ir(mpmppm)₂(acac)). Note that the thickness of the light-emitting layer 510(2) was 20 nm.

In the light-emitting layer 510(1) and the light-emitting layer 510(2), 2mDBTBPDBq-II is a host material, PCBBiF is an assist material, and Ir(mpmppm)₂(acac) is a phosphorescent material (a guest material).

Note that the purity of the iridium complex used in the deposition of the light-emitting layers by evaporation was different between Light-emitting Elements 6 and 7. In the deposition of the light-emitting layers by evaporation, the iridium complex that was represented as Material Z1 was used in Light-emitting Element 6, and the iridium complex that was represented as Material Z3 was used in Light-emitting Element 7. The purity of the iridium complexes that were represented as Materials Z1 and Z3 is shown in Table 13. Note that Material Z1 is the same as that used in Example 2.

TABLE 13

| | m1 | m2 | m3 | m4 | m5 | m6 | m7 | m8 |
|---|---|---|---|---|---|---|---|---|
| | (811) | (811) | (811) | (797) | (797) | (783) | (711, 752) | (697, 738) |
| Material Z1 | 77.1% | 2.1% | — | 13.4% | 0.1% | 0.4% | 6.2% | 0.7% |
| Material Z3 | 64.9% | 6.0% | 0.1% | 20.1% | 0.4% | 1.2% | 6.0% | 1.3% |

Value within parentheses is exact mass or mass of proton adduct

Note that the purity of Materials Z1 and Z3 shown in Table 13 was obtained by LC/MS analysis. The LC/MS analysis was performed by a method similar to that described in Example 1. As a result of the LC/MS analysis, chromatograms of Materials Z1 and Z3 exhibited peaks m1 to m8 shown in Table 13. The peaks m1 to m8 are the same as those exhibited by the chromatograms of Materials Y1 to Y3 in Example 1.

As shown in Table 13, the total proportion of peak areas of substances other than the iridium complex to which the peaks m1 to m2 were assigned was 20.8% in Material Z1, and the total proportion of peak areas of substances other than the iridium complex to which the peaks m1 to m3 were assigned was 29% in Material Z3.

After that, over the light-emitting layer 510(2), 2mDBTBPDBq-II was deposited by evaporation to a thickness of 5 nm as the electron-transport layer 533(1). Then, over the electron-transport layer 533(1), Bphen was deposited by evaporation to a thickness of 10 nm as the electron-transport layer 533(2). Then, over the electron-transport layer 533(2), LiF was deposited by evaporation to a thickness of 1 nm as the electron-injection layer 534.

Then, over the electron-injection layer 534, Al was deposited by evaporation to a thickness of 200 nm as the upper electrode 514.

Next, the sealing substrate 552 was prepared.

The light-emitting elements formed over the substrate 502 as described above were sealed by being bonded to the sealing substrate 552 in a glove box in a nitrogen atmosphere so as not to be exposed to the air. The sealing method was the same as that in Example 1.

Through the above process, Light-emitting Elements 6 and 7 were fabricated.

Note that in all the above evaporation steps for Light-emitting Elements 6 and 7, a resistive heating method was used as an evaporation method.

### <3-2. Initial Characteristics of Light-Emitting Elements 6 and 7>

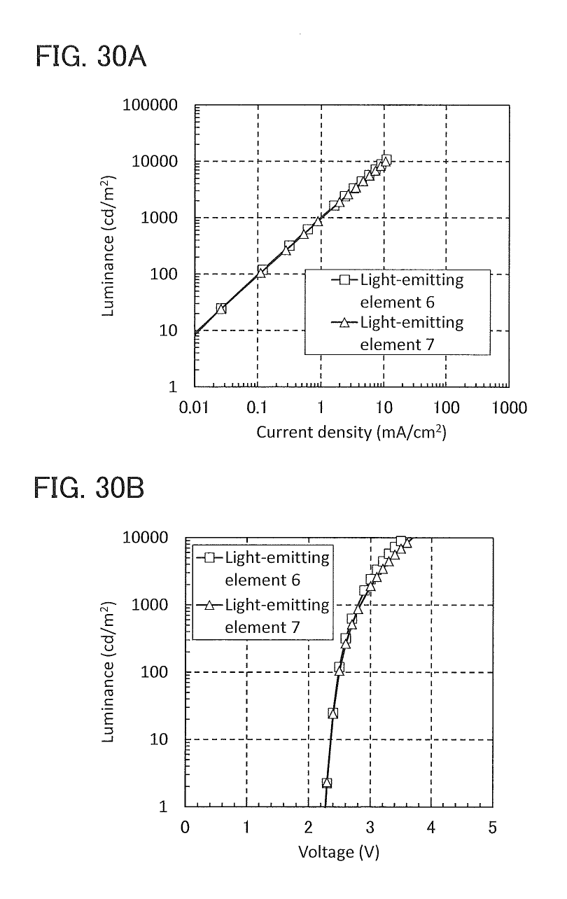

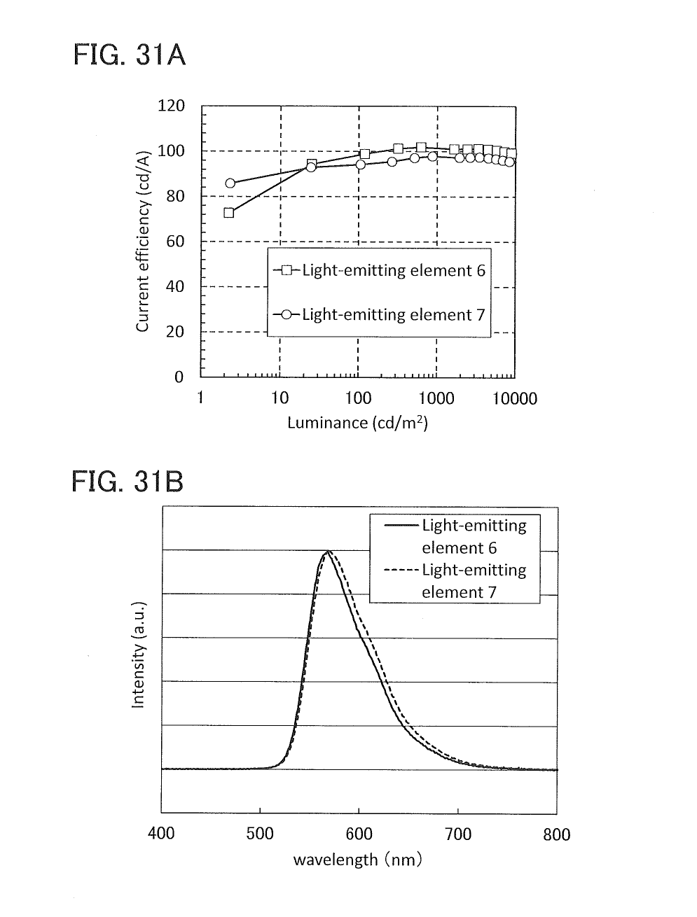

FIG. 30A shows current density-luminance characteristics of Light-emitting Elements 6 and 7, and FIG. 30B shows voltage-luminance characteristics of Light-emitting Elements 6 and 7. FIG. 31A shows luminance-current efficiency characteristics of Light-emitting Elements 6 and 7. Note that the measurement for each light-emitting element was carried out at room temperature (in the atmosphere maintained at 25° C.). Table 14 shows element characteristics of Light-emitting Elements 6 and 7 at around 1000 cd/m².

TABLE 14

| | | | Current | | | Current |
|---|---|---|---|---|---|---|
| | Voltage | Current | density | Chromaticity | Luminance | efficiency |
| | (V) | (mA) | (mA/cm²) | (x, y) | (cd/m²) | (cd/A) |
| Light-emitting | 2.8 | 0.04 | 1.0 | (0.50, 0.49) | 1053 | 100.9 |
| element 6 | | | | | | |
| Light-emitting | 2.8 | 0.04 | 0.9 | (0.52, 0.48) | 872 | 97.9 |
| element 7 | | | | | | |

FIG. 31B shows emission spectra when a current at a current density of 2.5 mA/cm² was supplied to Light-emitting Elements 6 and 7. As shown in FIGS. 30A and 30B, FIGS. 31A and 31B, and Table 14, the initial characteristics of Light-emitting Element 6 and those of Light-emitting Element 7 were not distinctively different from each other. It is thus suggested that the purity of the iridium complex, which is used as the phosphorescent material in the light-emitting layer 510(1) and the light-emitting layer 510(2), does not considerably affect the initial characteristics.

### <3-3. Reliability Test of Light-Emitting Elements 6 and 7>

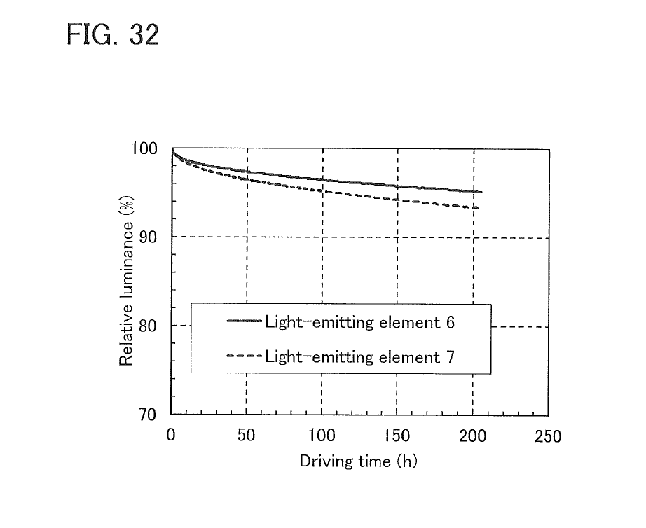

Next, reliability tests were performed on Light-emitting Elements 6 and 7. In the reliability tests, Light-emitting Elements 6 and 7 were driven under the conditions where the initial luminance was 5000 cd/m² and the current density was constant. FIG. 32 shows results of the reliability tests. In FIG. 32, the vertical axis represents relative luminance (%) with the initial luminance of 100%, and the horizontal axis represents driving time (h).

The results in FIG. 32 showed that relative luminance of Light-emitting Element 6 after 205 hours was 95.1%, and relative luminance of Light-emitting Element 7 after 205 hours was 93.3%.

The results in FIG. 32 show that deterioration curves of Light-emitting Elements 6 and 7 are substantially the same and these light-emitting elements are highly reliable.

### <3-4. Analysis of Light-Emitting Elements 6 and 7 by Liquid Chromatography Mass Spectrometry>

Then, Light-emitting Elements 6 and 7 were analyzed by LC/MS to examine impurities contained in the light-emitting elements.

Note that for analysis of an impurity in Light-emitting Element 6, a light-emitting element that was different from Light-emitting Element 6 and was formed over the same substrate as Light-emitting Element 6 was used; and for analysis of an impurity in Light-emitting Element 7, a light-emitting element that was different from Light-emitting Element 7 and was formed over the same substrate as Light-emitting Element 7 was used. In each of the light-emitting elements for the impurity analysis, the area of the lower electrode 504 was approximately 12 cm² (3.5 cm×3.3 cm). In other words, the light-emitting elements for the impurity analysis had the same materials and structures as Light-emitting Elements 6 and 7, but were different from Light-emitting Elements 6 and 7 in the area of the lower electrode 504. The samples for the impurity analysis were not driven; thus, the obtained results were not the analysis results of deteriorated objects produced by driving, but the analysis results of an impurity that had been contained from before driving. Here, the light-emitting element for the impurity analysis that was fabricated over the same substrate as Light-emitting Element 6 is regarded as Light-emitting Element 6 for convenience. The same applies to Light-emitting Element 7.

The LC/MS analysis was performed by a method similar to that described in Example 1.

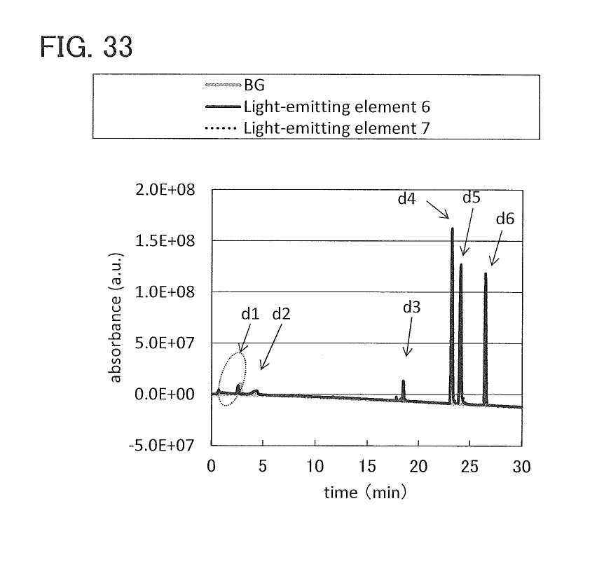

FIG. 33 shows analysis results of Light-emitting Elements 6 and 7. Note that FIG. 33 shows PDA chromatograms obtained by the LC/MS analysis of Light-emitting Elements 6 and 7.

In a manner similar to that of the analysis sample, the chloroform used for fabrication of the analysis sample was diluted with acetonitrile to give a solution, and the solution was analyzed to obtain a base-line (or background: BG) chromatogram. In FIG. 33, the obtained base line is denoted as BG.

As shown in FIG. 33, the chromatograms of Light-emitting Elements 6 and 7 exhibited peaks d1 to d6. The peaks d1 to d6 were analyzed using an MS spectrum, so that the peak d2 was assigned to Bphen; the peak d3, Ir(mpmppm)₂(acac); the peak d4, BPAFLP and 2mDBTBPDBq-II; the peak d5, DBT3P-II; and the peak d6, PCBBiF. By comparison with BG, the peak d1 was assigned to the chloroform that was used as a solvent and an impurity contained in the chloroform.

As can be seen in FIG. 33, the peaks that were assigned to the substances used for forming the elements was observed but an obvious peak assigned to an impurity was not observed.

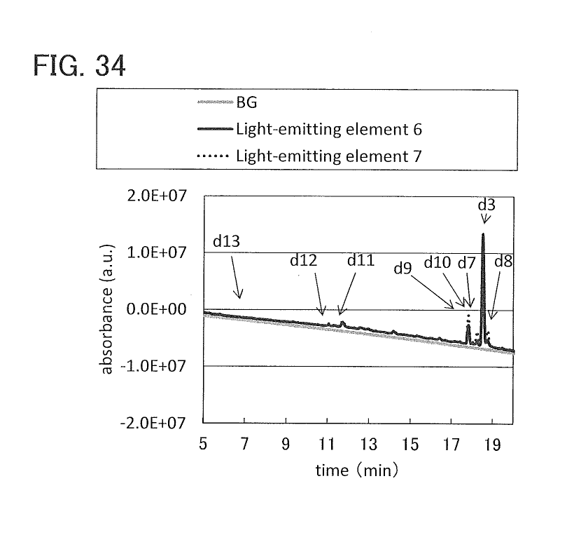

Next, the PDA chromatograms were analyzed with a focus on Ir(mpmppm)₂(acac). The base line was subtracted in the analysis of the PDA chromatograms. FIG. 34 shows analysis results of Light-emitting Elements 6 and 7 obtained with a focus on Ir(mpmppm)₂(acac). FIG. 34 is a graph in the vicinity of the peak d3 in FIG. 33 and was obtained by expanding the scale of the analysis time between the 5th minute and the 20th minute.

As shown in FIG. 34, the chromatograms of Light-emitting Elements 6 and 7 exhibited a peak d3 and peaks d7 to d13. The peak d3 is the same as that in FIG. 33 and was assigned to Ir(mpmppm)₂(acac). Note that in FIG. 34, the peaks d3, d7, and d8 correspond to precursor ions of the iridium complex, and the peaks d9 to d13 correspond to fragment ions of the iridium complex.

The peaks d7 to d13 were analyzed using an MS chromatograph, which showed that the peak d7 was assigned to a structural isomer (referred to as Structural Isomer 1, for convenience) of Ir(mpmppm)₂(acac); the peak d8, a structural isomer (referred to as Structural Isomer 2, for convenience) of Ir(mpmppm)₂(acac); the peaks d9 and d10, a substance with a structure of an mpmppm skeleton (a ligand of Ir(mpmppm)₂(acac)) from which one Me group was dissociated; the peak d11, a substance with a structure of Ir(mpmppm)₂, that is, a structure of Ir(mpmppm)₂(acac) from which the ligand acac was dissociated; the peak d12, a substance with a structure of Ir(mpmppm)₂(acac) from which the ligand acac and a Me group were dissociated; and the peak d13, mpmppm that was a ligand of Ir(mpmppm)₂(acac).

In LC/MS analysis, the substance with the structure of Ir(mpmppm)₂ produced an MS spectrum with a mass-to-charge ratio (m/z) of 753. The mass number of a proton adduct of a structure in which acetonitrile is coordinated to Ir(mpmppm)_{2 is} 753. Thus, it was suggested that acetonitrile was coordinated to Ir(mpmppm)₂ during the LC separation.

The measurement range of a Xevo G2 Tof MS detector manufactured by Waters Corporation, which was used in the analysis, was m/z=100 or more. That is why the ligand acac, which is out of the measurement range of the MS detector, was not detected. The ligand acac was not detected with a PDA detector, either.

Next, with the use of the results of LC/MS analysis shown in FIG. 34, the concentration of impurities contained in Light-emitting Elements 6 and 7 was examined. Table 15 shows the analysis results. Note that the results shown in Table 15 were obtained on the assumption that the peak areas of eight peaks of the peaks d3 and d7 to d13 in FIG. 34, i.e., the total peak area of substances originating in the iridium complex, was 100%. Thus, materials included in Light-emitting Elements 6 and 7 other than Ir(mpmppm)₂(acac) were not subjected to the purity examination.

TABLE 15

| | d3 | d7 | d8 | d9 | d10 | d11 | d12 | d13 | |
|---|---|---|---|---|---|---|---|---|---|
| | (811) | (811) | (811) | (797) | (797) | (711, 752) | (697, 738) | (261) | d13/(d3 + d7 + d8) |
| Light- | 76.6% | 2.2% | 2.2% | 13.0% | — | 5.2% | 0.8% | — | — |
| emitting | | | | | | | | | |
| element 6 | | | | | | | | | |
| Light- | 61.6% | 7.4% | 7.0% | 16.6% | 0.3% | 5.6% | 1.2% | 0.3% | 0.4% |
| emitting | | | | | | | | | |
| element 7 | | | | | | | | | |

Value within parentheses is exact mass or mass of proton adduct

As shown in Table 15, in Light-emitting Element 6, the peak area (d13) of a ligand not coordinated to the iridium metal was not detected. In Light-emitting Element 7, on the assumption that the total peak area of substances originating in the iridium complex Ir(mpmppm)₂(acac) was 100%, the proportion of the peak area (d13) of a ligand not coordinated to the iridium metal to the peak area (d3, d7, and d8) of the iridium complex was 0.4%.

Therefore, Light-emitting Elements 6 and 7 that were embodiments of the present invention had a long lifetime because on the assumption that the total peak area of substances originating in the iridium complex was 100%, the proportion of the peak area of the ligand not coordinated to the iridium metal was 1% or less. In Light-emitting Element 6, the proportion of the peak area (d13) of a ligand not coordinated to the iridium metal was less than 0.1%, under the lower detection limit, indicating that Light-emitting Element 6 had higher reliability than Light-emitting Element 7 as shown in FIG. 32. It is thus preferable that in the light-emitting layer 510(1) and the light-emitting layer 510(2), a ligand that is not coordinated to the iridium metal not be contained or the proportion of the peak area thereof be smaller than the lower detection limit.

As described above, the reliability of the light-emitting elements of embodiments of the present invention was increased by reducing the concentration of an impurity originating in the iridium complex, which was the light-emitting substance in the light-emitting layers 510(1) and 510(2).

The results in Table 15 suggested that Ir(mpmppm)₂(acac) was decomposed during the deposition by evaporation and a substance from which the ligand acac was dissociated was deposited by evaporation. The film deposited by evaporation contained Ir(mpmppm)₂(acac) most as a main component, and also contained Structural Isomer 1 and Structural Isomer 2, which are presumably different from Ir(mpmppm)₂(acac) in the direction of the ligand mpmppm. Since the proportion of an impurity from which a Me group was dissociated did not increase after the deposition by evaporation, a Me group is less likely to have been decomposed during the deposition by evaporation to be dissociated. As a decomposition product that increased after the deposition by evaporation, Ir(mpmppm)₂, from which the ligand acac was dissociated, was observed. The ligand acac was not detected.

According to the results of the reliability tests shown in FIG. 32 and the results of the examination of purity in Table 15 which were obtained using only the substances originating in Ir(mpmppm)₂(acac) in the light-emitting elements, Light-emitting Elements 6 and 7 were only slightly different in driving lifetime in spite of being different in the purity of Ir(mpmppm)₂(acac). As can be seen from the results in Table 15, the proportion of the peak area of the ligand mpmppm to the peak area of Ir(mpmppm)₂(acac) was less than 1% in Light-emitting Elements 6 and 7. Therefore, it was shown that because the proportion of the peak area of the ligand mpmppm to the peak area of Ir(mpmppm)₂(acac) was less than 1%, the light-emitting elements had a long lifetime. Note that the slight difference in the reliability between Light-emitting Elements 6 and 7 resulted from the slight difference in the content of the ligand. It is thus preferable that in the light-emitting element, a ligand that is not coordinated to the iridium metal not be contained or the proportion of the peak area thereof be smaller than the lower detection limit.

The structures described in this example can be used in an appropriate combination with any of other examples and embodiments.

This application is based on Japanese Patent Application serial no. 2014-218936 filed with Japan Patent Office on Oct. 28, 2014, the entire contents of which are hereby incorporated by reference.

What is claimed is:

1. A light-emitting element comprising:
an iridium complex comprising an iridium metal and a ligand coordinated to the iridium metal,
wherein in analysis of the light-emitting element by liquid chromatography mass spectrometry using a chromatograph of a photodiode array detector, a proportion of a peak area of a ligand not coordinated to the iridium metal to a peak area of the iridium complex is greater than or equal to 0% and less than or equal to 10%.

2. The light-emitting element according to claim 1,
wherein the proportion of the peak area of the ligand not coordinated to the iridium metal to the peak area of the iridium complex is greater than or equal to 0% and less than or equal to 5%.

3. The light-emitting element according to claim 1,
wherein the ligand coordinated to the iridium metal is a monoanionic ligand.

4. The light-emitting element according to claim 1, further comprising:
an aromatic heterocyclic compound coordinated to the iridium metal,
wherein the aromatic heterocyclic compound contains two or more nitrogen atoms.

5. A light-emitting device comprising:
the light-emitting element according to claim 1; and
a color filter.

6. An electronic device comprising:
the light-emitting element according to claim 1; and
a housing or a touch sensor function.

7. A lighting device comprising:
the light-emitting element according to claim 1; and
a housing.

8. A light-emitting element comprising:
an iridium complex comprising an iridium metal and a ligand coordinated to the iridium metal,
wherein in analysis of the light-emitting element by liquid chromatography mass spectrometry, a precursor ion of the iridium complex, a first fragment ion of the iridium complex, and a second fragment ion of the iridium complex are detected by a mass spectrometric detector and a photodiode array detector,
wherein the first fragment ion detected by the mass spectrometric detector comprises the iridium metal,
wherein the second fragment ion detected by the mass spectrometric detector does not comprise the iridium metal,
wherein a chromatograph of the photodiode array detector comprises a first peak corresponding to the precursor ion, a second peak corresponding to the first fragment ion, and a third peak corresponding to the second fragment ion, and
wherein a proportion of an area of the third peak to an area of the first peak is greater than or equal to 0% and less than or equal to 10%.

9. The light-emitting element according to claim 8;
wherein the proportion of the area of the third peak to the area of the first peak is greater than or equal to 0% and less than or equal to 5%.

10. The light-emitting element according to claim 8,
wherein the ligand coordinated to the iridium metal is a monoanionic ligand.

11. The light-emitting element according to claim 8, further comprising:
an aromatic heterocyclic compound coordinated to the iridium metal,
wherein the aromatic heterocyclic compound contains two or more nitrogen atoms.

12. A light-emitting device comprising:
the light-emitting element according to claim 8; and
a color filter.

13. An electronic device comprising:
the light-emitting element according to claim 8; and
a housing or a touch sensor function.

14. A lighting device comprising:
the light-emitting element according to claim 8; and
a housing.

15. A light-emitting element comprising:
an iridium complex comprising an iridium metal and a ligand coordinated to the iridium metal, and
a ligand not coordinated to the iridium metal,
wherein in analysis of the light-emitting element by liquid chromatography mass spectrometry using a chromatograph of a photodiode array detector, a peak area of the ligand not coordinated to the iridium metal is smaller than a lower detection limit.

16. The light-emitting element according to claim 15,
wherein the ligand coordinated to the iridium metal is a monoanionic ligand.

17. The light-emitting element according to claim 15, further comprising:
an aromatic heterocyclic compound coordinated to the iridium metal,
wherein the aromatic heterocyclic compound contains two or more nitrogen atoms.

18. A light-emitting device comprising:
the light-emitting element according to claim 15; and
a color filter.

19. An electronic device comprising:
the light-emitting element according to claim 15; and
a housing or a touch sensor function.

20. A lighting device comprising:
the light-emitting element according to claim 15; and
a housing.
